(19) United States
(12) Patent Application Publication
(10) Pub. No.: US 2010/0075117 A1
(43) Pub. Date: Mar. 25, 2010

(54) RELIEF PRINTING PLATE PRECURSOR FOR LASER ENGRAVING, METHOD OF PRODUCING THE SAME, RELIEF PRINTING PLATE OBTAINABLE THEREFROM, AND METHOD OF PRODUCING RELIEF PRINTING PLATE

(75) Inventors: Takashi KAWASHIMA, Shizuoka-ken (JP); Atsushi SUGASAKI, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/561,280

(22) Filed: Sep. 17, 2009

(30) Foreign Application Priority Data
Sep. 24, 2008 (JP) 2008-244605

(51) Int. Cl. B32B 3/10; G03F 7/20; G03F 7/004

(52) U.S. Cl. 428/195.1; 430/306; 430/270.1

(57) ABSTRACT

A relief printing plate precursor for laser engraving, including a relief forming layer that includes a peroxide and a binder polymer, and includes a crosslinked structure.

### CROSS-REFERENCE TO RELATED APPLICATION

This application claims priority under 35 USC 119 from Japanese Patent Application No. 2008-244605 filed on Sep. 24, 2008, the disclosure of which is incorporated by reference herein.

### BACKGROUND OF THE INVENTION

1. Field of the Invention

The present invention relates to a relief printing plate precursor for laser engraving, a method of producing the relief printing plate precursor, a relief printing plate obtained by laser engraving a relief printing plate precursor, and a method of producing a relief printing plate.

2. Description of the Related Art

As a method of forming a printing plate by forming concavities and convexities on a photosensitive resin layer laminated on the surface of a support, a method called “analogue plate making” is well known in which a relief forming layer that is formed using a photosensitive composition is exposed to UV-light through an original image film so as to cure selectively image portions, and then uncured portions are removed with a liquid developer.

The relief printing plate is a printing plate with a relief layer having concavities and convexities. Such a relief layer having concavities and convexities is obtained by patterning a relief forming layer containing a photosensitive composition containing as a main component an elastic polymer such as synthetic rubber, a resin such as thermoplastic resin, or a mixture of resin and plasticizer, to form concavities and convexities thereon. Among these relief printing plates, a printing plate having a soft relief layer is referred to as a flexographic printing plate in some cases.

A relief forming layer which is made of an elastic polymer such as synthetic rubber or a soft thermoplastic resin and is used for a so-called flexographic printing plate is suitable for an aqueous ink, an alcohol ink, an ester ink, or a solvent-free UV ink in which an ink vehicle not corrosive to a rubber is used. A soft relief forming layer made of such a material is, due to its softness, suitable for printing on a printing medium having a large surface unevenness or on a wrapping material having a low strength, but a printing pressure should be lowered because a formed relief layer tends to be deformed by a stress.

In contrast, a relief forming layer obtained using a normal thermoplastic resin (plastic) is usually hard, and a printing plate having a relief layer prepared using such a relief forming layer is called a letterpress printing plate, which is distinguished from a flexographic printing plate having a soft relief layer. Since a letterpress printing plate has a hard relief layer, a high printing pressure may be applied, and a clear and sharp image can be printed by thickening an ink layer on the printing plate.

A commercially available resin composition used for obtaining such a hard relief forming layer is subjected to imagewise exposure and subsequent development to make a printing plate, and includes a water soluble resin or an alcohol soluble resin for water development or alcohol development. Accordingly, an ink used when printing is carried out using such a printing plate is an oil-based ink or a solvent-free UV ink using an ink vehicle not corrosive to these resins.

When the relief printing plate is produced by the analogue plate making, an original image film using a silver salt material is usually required, so that cost and time for the production of the original image film are also required. Further, a chemical treatment is required for the development of the original image film, and disposal of the waste liquid of the development process is also needed. Therefore, a still simpler method of producing the printing plate such as, for example, a method using no original image film or a method requiring no development process has been studied.

In recent years, a method of plate making by scanning light exposure of a relief forming layer, in which no original image film is required, has been studied.

As a technique that does not require an original image film, a relief printing plate precursor having a laser sensitive mask layer element that is capable of forming an image mask on a relief forming layer has been proposed (for example, see Japanese Patent No. 2773847 and Japanese Patent Application Laid-Open (JP-A) No. 9-171247). According to these methods of plate making of a plate precursor, an image mask having a function similar to that of an original image film is formed from the mask layer element by laser beam irradiation in accordance with image data, so that the method is called a “Mask CTP method”, in which no original image film is needed, but in subsequent processes of plate making, light exposure using UV-light through the image mask is carried out, and uncured portions are removed by development. In view of the fact that a development process is still needed, there is room for improvement.

As a method of producing a printing plate that does not need a development process, there are many proposals about a so-called “direct engraving CTP method” in which a relief forming layer is engraved directly with a laser beam to produce a printing plate. In the direct engraving CTP method, engraving is carried out literally with a laser beam so as to form concavities and convexities that provide relief. The method has an advantage of controlling freely the shape of the relief as opposed to a method of forming relief using an original image film. Owing to this advantage, when an image like a cutout character is formed, the area thereof is engraved deeply as compared with the other areas, or in the case of a fine halftone dot image, engraving so as to form shoulders can be carried out considering the resistance to printing pressure.

However, when a relief having concavities and convexities that are resistant to printing pressure is formed on a relief forming layer that has a predetermined thickness, a high energy is required, and also, the speed of laser engraving is slow. Therefore, a problem of lower productivity as compared with a method of forming an image with a mask is brought about.

For this reason, improvement in the sensitivity of a relief printing plate precursor has been tried. For example, a flexo printing plate precursor for laser engraving that contains an elastomer foam has been proposed (see JP-A No. 2002-357907, for example). In this proposed technology, improvement in the engraving sensitivity is tried by using a low density foam for a relief forming layer. However, the resulting printing plate lacks strength because a low density material is used, thereby bringing about a problem of largely lowering the printing durability.

Further, for example, in Japanese Patent No. 2846954, and JP-A Nos. 11-338139 and 11-170718, a flexo printing plate precursor capable of being engraved with a laser beam or a flexo printing plate obtained by laser engraving is disclosed. In these documents, a flexo printing plate is obtained by mixing a monomer with an elastomer rubber as a binder, curing the resulting mixture by a heat-polymerization mechanism or a photo-polymerization mechanism, and then performing laser engraving.

As a problem of the direct engraving CTP method, slow speed in laser engraving may be mentioned. This is because the engraving depth is required to be at least 100 μm in the direct engraving CTP method in order to directly form relief, as opposed to the mask CTP method in which the thickness of the mask layer element to be ablated is about 1 μm to 10 μm.

For this reason, there are some proposals for improving the laser engraving sensitivity as described below.

For example, a flexo printing plate precursor for laser engraving that contains an elastomer foam has been proposed (for example, see JP-A No. 2000-318330). In this proposed technology, improvement in the engraving sensitivity is tried by using a low density foam. However, the resulting printing plate lacks strength because a low density material is used, thereby bringing about a problem of largely lowering the printing durability.

For example, a flexo printing plate precursor for laser engraving that contains microspheres encapsulating a hydrocarbon gas has been proposed (for example, see U.S. Patent Application Publication No. 2003/180636). In this proposed technology, improvement in the engraving sensitivity is tried by applying a system in which the gas encapsulated in the microspheres is expanded by heat generated with a laser beam and the material to be engraved is collapsed. However, a material containing gas bubbles is used, so that the strength as a printing plate is likely to be insufficient. In addition, since gas has a property of easily expanding by heat as compared with a solid, even if microspheres having a high thermal deformation initiation temperature are selected, changes in volume caused by changes in atmospheric temperature are unavoidable. For this reason, the material containing gas bubbles is not appropriate for a printing plate in which stable accuracy in thickness is required.

For example, a resin relief printing plate precursor for laser engraving that contains a polymer filler having a ceiling temperature lower than 600 K has been proposed (for example, see JP-A No. 2000-168253). In this proposed technology, improvement in the engraving sensitivity is tried by adding a polymer filler having a low depolymerization temperature. However, the polymer filler brings about unevenness on the surface of a resulting printing plate precursor, thereby providing a problem of having a significant influence on the printing quality.

As mentioned above, regarding a resin composition that can be appropriately applied to a relief forming layer of a relief printing plate precursor for laser engraving, various technologies have been proposed, but a technology having a high engraving sensitivity upon laser engraving has not yet been proposed.

### SUMMARY OF THE INVENTION

According to an aspect of the invention, there is provided a relief printing plate precursor for laser engraving, comprising a relief forming layer that comprises a peroxide and a binder polymer, and comprises a crosslinked structure.

### DETAILED DESCRIPTION OF THE INVENTION

Hereinafter, the present invention will be described in detail.

[Relief Printing Plate Precursor for Laser Engraving]

The relief printing plate precursor for laser engraving of the present invention comprises a relief forming layer that comprises a peroxide and a binder polymer, and comprises a crosslinked structure. Such a relief forming layer may be formed on an appropriate support or directly on a surface of a member of a printing apparatus, but is preferably formed on a support from the viewpoint of easy handling.

Hereinafter, components of the relief printing plate precursor for laser engraving will be explained. The relief printing plate precursor for laser engraving of the present invention is sometimes called a printing plate precursor of the present invention.

<(A) Peroxide>

The relief forming layer according to the present invention includes a crosslinked structure in the layer, and includes a peroxide, whereby the engraving sensitivity is significantly improved.

The mechanism of the improvement on engraving sensitivity by using (A) a peroxide in the relief forming layer is not clear, but may be presumed as discussed below.

It is thought that laser engraving to form an image on the printing plate precursor of the present invention, particularly engraving with a near-infrared laser, is performed through the following processes (i) to (v).

(i) Light absorption by a compound having a maximum absorption wavelength in a range of from 700 to 1,300 nm or by carbon black.
(ii) Photothermal conversion by the compound having a maximum absorption wavelength in a range of from 700 to 1,300 nm or by the carbon black.
(iii) Heat transfer from the compound having a maximum absorption wavelength in a range of from 700 to 1,300 nm or the carbon black to an adjacent film forming component such as a binder or a polymerized monomer and (A) a peroxide included therein.
(iv) Thermal decomposition of the film forming component such as a binder or a polymerized monomer and the (A) peroxide.
(v) Dissipation or scattering of the decomposed film forming component such as a binder or a polymerized monomer.

(A) a peroxide included in the relief forming layer generates a large amount of decomposition heat when it is decomposed by heat. It is thought that since (A) a peroxide having such a property is included in the film, decomposition heat of the peroxide is added in addition to the heat generated by the photothermal conversion of the laser in the process (iv), so that the thermal decomposition in the process (iv) is accelerated and the laser engraving sensitivity is very high.

As the (A) peroxide, an organic peroxide having good dispersibility in an organic solvent is preferably used because the (A) peroxide having a decomposition accelerating function is uniformly dispersed in the relief forming layer, and a greater effect thereof can be obtained. Examples of an organic peroxide exerting such an effect include a ketone peroxide, a diacyl peroxide, a dialkyl peroxide, a hydroperoxide, a peroxy ketal, a peroxy ester, and a peroxy dicarbonate. When using such an organic peroxide, the effect is particularly great.

Hereinafter, examples of the (A) peroxide which may be used in the present invention are shown, but the present invention is not limited by them.

As an inorganic peroxide, lithium peroxide, potassium peroxide, sodium peroxide, magnesium peroxide, calcium peroxide, barium peroxide, and the like may be exemplified.

As an organic peroxide, almost all of the organic peroxides having one or more oxygen-oxygen bonds in the molecular may be used in the present invention. Examples thereof include methylethylketone peroxide, cyclohexanone peroxide, acetylacetone peroxide, acetone peroxide, 1,1-di(tert-hexyl peroxy)-3,3,5-trimethylcyclohexane, 1,1-di(tert-hexyl peroxy)cyclohexane, 1,1-di(tert-butyl peroxy)-2-methylcyclohexane, 1,1-di(tert-butyl peroxy)cyclohexane, 2,2-di(tert-butyl peroxy)butane, n-butyl-4,4-di(tert-butyl peroxy)valerate, 2,2-di[4,4-di(tert-butyl peroxy)cyclohexyl]propane, p-menthane hydroperoxide, diisopropyl benzene hydroperoxide, 1,1,3,3-tetramethyl butyl hydroperoxide, cumene hydroperoxide, tert-butylhydroperoxide, di(2-tert-butyl peroxy isopropyl)benzene, dicumyl peroxide, 2,5-dimethyl-2,5-di(tert-butyl peroxy)hexane, tert-butyl cumyl peroxide, di-tert-hexyl peroxide, di-tert-butyl peroxide, 2,5-dimethyl-2,5-di(tert-butyl peroxy)hexyne-3, diisobutyryl peroxide, di(3,3,5-trimethyl hexanoyl)peroxide, dilauroylperoxide, disuccinic acid peroxide, dibenzoyl peroxide, di(3-methylbenzoyl)peroxide, di(4-methyl benzoyl)peroxide, benzoyl (3-methylbenzoyl)peroxide,

di-n-propyl peroxy dicarbonate, di-isopropyl peroxy dicarbonate, di(4-tert-butyl cyclohexyl)peroxy dicarbonate, di(2-ethylhexyl)peroxy dicarbonate, di-sec-butyl peroxy dicarbonate, cumyl peroxy neodecanoate, 1,1,3,3-tetramethylbutyl peroxy neodecanoate, tert-hexyl peroxy neodecanoate, tert-butyl peroxy neodecanoate, tert-butyl peroxy neoheptanoate, tert-hexyl peroxy pivalate, tert-butyl peroxy pivalate, 1,1,3,3-tetramethylbutyl peroxy-2-ethylhexanoate, 2,5-dimethyl-2,5-di(2-ethyl hexanoyl peroxy)hexane, tert-hexyl peroxy-2-ethylhexanoate, tert-butyl peroxy-2-ethylhexanoate, tert-hexyl peroxy isopropyl monocarbonate, tert-butyl peroxy maleic acid, tert-butyl peroxy-3,5,5-trimethylhexanoate, tert-butyl peroxy laurate, tert-butyl peroxy isopropyl monocarbonate, tert-butyl peroxy-2-ethylhexyl monocarbonate, tert-hexyl peroxy benzoate, 2,5-dimethyl-2,5-di(benzoyl peroxy)hexane, tert-butyl peroxy acetate, tert-butyl peroxy benzoate, tert-butyl peroxy-3-methyl benzoate, tert-butyl peroxy allyl monocarbonate, 3,3′,4,4′-tetra(tert-butyl peroxy carbonyl)benzophenone.

As the (A) peroxide, an organic peroxide is preferable from the viewpoint of the dispersibility in the film, and a ketone peroxide, a diacyl peroxide, a dialkyl peroxide, a hydroperoxide, a peroxy ketal, a peroxy ester, and a peroxy dicarbonate are more preferable among the above exemplified compounds.

The relief forming layer according to the present invention includes a crosslinked structure. A preferable (A) peroxide for forming such a crosslinked structure in the relief forming layer will be described. When forming a crosslinked structure in the relief forming layer, a coating film of a resin composition for forming a relief forming layer, which includes a polymerizable compound and a polymerization initiator in addition to a peroxide and a binder polymer, is subjected to light exposure or heating to form a crosslinked structure, and the crosslinked structure is preferably formed by heating from the viewpoint of formation efficiency. In this case, an effective amount of (A) a peroxide should be remain without decomposition in the relief forming layer after the heat crosslinking. From such a viewpoint, the 10-hour half-life temperature of the (A) peroxide is higher, preferably by 5° C. or more, more preferably 10° C. or more, and further preferably 20° C. or more, than the heating temperature for the heat crosslinking.

Further, the 10-hour half-life temperature of the (A) peroxide to be used is preferably 100° C. or more, regardless of the type of the crosslinked structure formation method (such as light and/or heat crosslinking method). This is because if the 10-hour half-life temperature of the peroxide is too low, when the printing plate precursor is stored at room temperature for a long time, the peroxide gradually decomposes, so that the sensitivity improving effect of the peroxide is gradually lowered than immediately after the production of the printing plate precursor.

In the present invention, the 10-hour half-life temperature of the (A) peroxide is a value obtained by the following measurement method.

Using a solvent that is inert to radicals (benzene is used in the present invention), a peroxide solution having a concentration of 0.1 mol/L is prepared and sealed in a glass tube in which nitrogen gas replacement has been carried out. This is allowed to thermally decompose in a constant-temperature bath with a predetermined temperature. In a commonely used measurement method, this concentration may be adjusted to be 0.5 mol/L.

In general, decomposition of peroxide in a dilute solution may be approximately addressed as a first-order reaction. Accordingly, the following formulae are established in which x represents an amount of decomposed peroxide, k represents a decomposition rate constant, t represents a time, and a represents a initial concentration of peroxide.

dx/dt=k(a−x) Formula (1):

ln {a/(a−x)}=kx Formula (2):

A half life is a period of time in which the peroxide concentration decreases from an initial concentration to half of the initial concentration due to decomposition of the peroxide. Accordingly, the following formula (3) can be obtained by representing the half life as t1/2 and substituting “a/2” for “x” in formula (2).

kt1/2=ln 2 Formula (3):

Accordingly, when thermal decomposition is carried out at a constant temperature, a relationship between time t and ln {a/(a−c)} is plotted, and k is determined by the gradient of the straight line obtained by the plotting, the half life (t1/2) at that temperature can be obtained from formula (3).

The decomposition rate constant k is represented by the following formulae.

k=Aexp(−ΔE/RT) Formula (4):

ln k=ln A−ΔE/RT Formula (5):

In these formulae, A represents a frequency factor (1/h), ΔE represents an activation energy (J/mol), R represents a gas constant (8.314 J/mol˜K), and T represents an absolute temperature (K). Accordingly, when k is measured with respect to several temperatures, and a relationship between ln k and 1/T is plotted, the activation energy can be determined from the gradient of the straight line obtained by the plotting.

Further, a half life of a peroxide at any temperature or a decomposition temperature for obtaining any half life can be obtained from a straight line obtained by plotting a relationship between 1/T and ln t1/2 instead of ln k.

A value of a 10-hour half-life temperature of a peroxide can be obtained from a literature such as a product catalog of a peroxide maker. Specifically, values described in the catalog of NOF Corporation (http://www.nof.co.jp/upload_public/sogo/B0100.pdf) can be used.

The content (abundance) of (A) a peroxide in a relief forming layer having a crosslinked structure is preferably from 0.1% to 20% by mass, more preferably from 0.1% to 10% by mass, further preferably from 1% to 10% by mass based on the total mass of the crosslinked relief forming layer, from the viewpoint of satisfying both of the engraving sensitivity and film formability.

The content (abundance) of a peroxide in a relief forming layer having a crosslinked structure may be quantified by the following method.

0.5 g of a relief forming layer having a crosslinked structure and 0.03 g of naphthalene as a standard substance are weighed and dipped in N-methyl-2-pyrrolidone in a glass bottle. After dipping at room temperature for 12 hours, the mixture is put in an ultrasonic cleaner for 5 minutes.

The cycle of 12 hour dipping and 5 minute ultrasonic cleaner treatment is repeated three times. The resulting liquid is filtered with a 0.01 μm membrane filter, and HPCL (RI detector) is carried out to compare the amounts of the (A) peroxide and naphthalene as a standard substance to quantify the content of the (A) peroxide.

Next, respective components of the relief forming layer, other than (A) a peroxide, are described.

The relief forming layer according to the present invention is obtained preferably by forming a layer of a resin composition for a relief forming layer, which includes (A) a peroxide, (B) a binder polymer, and preferably (C) a compound capable of forming a crosslinked structure (hereinafter referred to as a crosslinking agent), (D) a photothermal conversion agent, (E) a polymerization initiator, a crosslinking accelerator, a plasticizer, and the like to form an uncrosslinked relief forming layer (a precursor layer of a relief forming layer), and forming therein a crosslinked structure by light or heat.

Since the formation of the crosslinked structure is carried out by the reaction with the (C) crosslinking agent included in the precursor layer (that is, the reaction between the polymerizable or crosslinkable group such as an ethylenic unsaturated bond included in the (C) crosslinking agent and the (B) binder polymer, or the reaction between the (C) crosslinking agents), the crosslinking agent substantially does not remain in the relief forming layer having a crosslinked structure. When the precursor layer includes (E) a polymerization initiator, since the polymerization initiator is involved in the reaction, the polymerization initiator also substantially does not remain in the relief forming layer.

<(B) Binder Polymer>

The relief forming layer according to the present invention contains (B) a binder polymer. The (B) binder polymer is a main component contained in the relief forming layer for laser engraving, and usually a thermoplastic resin, a thermoplastic elastomer or the like is used in accordance with purposes.

The binder polymer may be incorporated or may not be incorporated in the crosslinked structure included in the relief forming layer. That is, an embodiment in which a crosslinking agent and a binder polymer react with each other to form a crosslinked structure is also included in the present invention.

For example, from the viewpoint of the laser engraving sensitivity, a polymer containing a partial structure that thermally decomposes by light exposure or heating is preferable.

Further, for example, when a soft film having flexibility is desired to be formed, a soft resin or a thermoplastic elastomer is selected.

Still further, form the viewpoint of easiness in the preparation of the resin composition for a relief forming layer and improvement in the resistance of a resulting relief printing plate to an oil-based ink, a hydrophilic or alcoholphilic polymer is preferably used.

In addition, in the present invention, since it is required to form a crosslinked structure in the relief forming layer by heating or light exposure, a polymer having a carbon to carbon unsaturated bond in the molecule thereof, which is described below in detail, may be used as the binder polymer.

In this way, considering the properties of the resin composition for a relief forming layer in accordance with the purposes of applications thereof, a binder polymer that meets the purposes may be selected. The binder polymer may be used solely or in a combination of two or more kinds.

Hereinafter, various kinds of polymers usable as the binder polymer in the present invention will be described.

(Decomposable Polymer)

Examples of the binder polymer that is preferably used from the viewpoint of the laser engraving sensitivity may include a polymer (decomposable polymer) having a partial structure that receives energy such as light or heat and decomposes.

Examples of the decomposable polymer may include polymers that contain, as a monomer unit having an easily decomposable or breakable partial structure in the molecule thereof, styrene, α-methylstyrene, α-methoxystyrene, acryl esters, methacryl esters, ester compounds other than the foregoing ones, ether compounds, nitro compounds, carbonate compounds, carbamoyl compounds, hemiacetal ester compounds, oxyethylene compounds, aliphatic cyclic compounds, or the like.

Of these, particularly, polyethers such as polyethylene glycol, polypropylene glycol, or polytetraethylene glycol; aliphatic polycarbonates; aliphatic carbamates; polymethyl methacrylate; polystyrene; nitrocellulose; polyoxyethylene; polynorbornene; hydrogenated polycyclohexadiene; and a polymer having a molecular structure such as a dendrimer that is rich in branched structure may be preferably exemplified, from the viewpoint of decomposability.

Further, a polymer having a number of oxygen atoms in the molecular chain thereof is preferable, from the viewpoint of decomposability. From this viewpoint, a compound having a carbonate group, a carbamate group, or a methacryl group in the polymer main chain thereof may be preferably exemplified.

Examples of a polymer having an appropriate thermal decomposability may include polyester or polyurethane that is synthesized by using (poly)carbonate diol or (poly)carbonate dicarboxylic acid as a raw material and polyamide that is synthesized by using (poly)carbonate diamine as a raw material. These polymers may have a polymerizable unsaturated group in the main or side chain thereof. In particular, when a reactive functional group such as hydroxyl group, amino group or carboxyl group is involved, a polymerizable unsaturated group is easily incorporated into the thermally decomposable polymers.

Furthermore, as the decomposable polymer, a polyester such as polylactic acid that includes a hydroxylcarboxylic acid unit is usable. Specifically, the polyester is selected preferably from the group consisting of polyhydroxyalkanoate (PHA), a lactic acid polymer, polyglycolic acid (PGA), polycaprolactone (PCL), poly(butylene succinic acid), and their derivatives or mixtures.

(Thermoplastic Polymer)

As one of the binder polymers preferably used from the viewpoint of the laser engraving sensitivity, a thermoplastic polymer may be used.

The thermoplastic polymer may be an elastomer or non-elastomer resin and may be selected in accordance with the purposes of the resin composition for a relief forming layer in the present invention.

Examples of the thermoplastic elastomer may include an urethane thermoplastic elastomer, an ester thermoplastic elastomer, an amide thermoplastic elastomer, and a silicone thermoplastic elastomer. For the purpose of improving the laser engraving sensitivity of these thermoplastic elastomers, an elastomer that is obtained by incorporating an easily decomposing functional group such as carbamoyl group or carbonate group into the main chain of the elastomer may be used. A mixture of the thermoplastic polymer and the thermal decomposable polymer may be used.

The thermoplastic elastomer exhibits a rubber elasticity at normal temperature and has a molecular structure composed of a soft segment such as polyether or rubber molecules and a hard segment that prevents plastic deformation at around normal temperature similarly to vulcanized rubber. Examples of the hard segment include various types such as a frozen phase, a crystalline phase, hydrogen bond, or ionic crosslinking. The thermoplastic elastomer is preferable when the resin composition for a relief forming layer in the present invention is applied to the production of a relief printing plate such as a flexo printing plate that requires flexibility.

The kind of the thermoplastic elastomer is selected in accordance with purposes. When solvent resistance is required, a urethane, ester, amide, or fluoro thermoplastic elastomer is preferable, for example. When heat resistance is required, a urethane, olefin, ester, or fluoro thermoplastic elastomer is preferable. By selecting the kind of the thermoplastic elastomer, the hardness of a film formed from the resin composition may be varied considerably.

Examples of the non-elastic resin may include polyester resin, unsaturated polyester resin, polyamide resin, polyamideimide resin, polyurethane resin, unsaturated polyurethane resin, polysulfone resin, polyethersulfone resin, polyimide resin, polycarbonate resin, wholly aromatic polyester resin, and a hydrophilic polymer having a hydroxyethylene unit (for example, polyvinylalchol derivatives).

(Hydrophilic or Alcoholphilic Polymer)

As the binder polymer used in the present invention, a hydrophilic or alcoholphilic one is preferable from the viewpoint of removing engraving scraps. Examples of the hydrophilic polymer may include specifically the ones described below, but among these, a hydrophilic polymer having a hydroxyethylene unit is preferable. In addition, as the hydrophilic or alcoholphilic binder, a polymer such as polyvinylbutyral is preferably used, for example.

The hydrophilic polymer that is one of the preferable examples of the binder polymer is described in detail.

The hydrophilic polymer means a water-soluble or water-swellable polymer. Here, in the present invention, “water-soluble” means that the polymer is dissolved in water at 25° C. in an amount of 5% or more by mass, and “water-swellable” means that the polymer absorbs water and expands when it is added to 25° C. water in an amount of 5% by mass and that the polymer is recognized not to be dissolved in water by visual observation but no apparent solid (powdery) precipitation is observed.

As the hydrophilic polymer, a single kind of polymer may be used or plural kinds of polymers may be used.

Examples of the hydrophilic polymer may include a hydrophilic polymer having a hydroxyethylene unit; polysaccharides having a hydrophilic functional group such as cellulose; an acrylic resin that has a salt structure like sodium polyacrylate obtained by neutralizing an acidic functional group, a salt structure obtained by neutralizing an amino group, or an onium structure; polyamide resin or polyester resin in which a hydrophilic group such as polyethyleneoxide is incorporated; and gelatin.

As the hydrophilic polymer, from the viewpoint of exhibiting adequate hydrophilicity, a hydrophilic polymer having a hydroxyethylene group; cellulose that has a polar group such as an amino group, a carboxylic acid group, a sulfonic acid group, a sulfuric acid group, or a salt structure obtained by neutralizing these groups; an acrylic resin that has a polar group such as an amino group, a carboxylic acid group, a sulfonic acid group, a sulfuric acid group, or a salt structure that is obtained by neutralizing these groups; and polyamide resin are preferable. A hydrophilic polymer having a hydroxyethylene; an acrylic resin that has a polar group such as an amino group, a carboxylic acid group, a sulfonic acid group, a sulfuric acid group, or a salt structure obtained by neutralizing these groups; and polyamide resin are more preferable. Polyvinylalcohols and polyamide resin are still more preferable.

As the hydrophilic polymer, from the viewpoint of having film forming property and UV-ink resistance, a polymer selected from polyvinylalcohol (PVA) and the derivatives thereof is particularly preferable.

The PVA and PVA derivatives will be described in detail as a preferable example of a vinyl polymer described later.

In the present invention, the PVA and PVA derivatives may include a copolymer or polymer that contains a hydroxyethylene unit in an amount of from 0.1 mol % to 100 mol %, preferably from 1 mol % to 98 mol %, and still more preferably from 5 mol % to 95 mol %, and a modified product thereof.

As the hydrophilic polymer, particularly, at least one selected from the PVA and the derivatives thereof and a hydrophilic polymer having no hydroxyethylene unit (hereinafter, also referred to as “non-PVA derivative” appropriately) may be used in combination.

As a method of synthesizing hydrophilic polyamide, the following method may be used.

ε-Caprolactam and/or adipic acid are reacted with a polyethylene glycol having both ends modified with amine to obtain a polyamide having polyethylene glycol unit, which is then reacted with piperazine to obtain a hydrophilic polyamide having a piperazine framework. Further, a hydrophilic polyamide having a crosslinkable functional group incorporated in the polymer may be obtained by reacting the amide group of the hydrophilic polyamide and the epoxy group of glycidylmethacrylate. These non-PVA derivatives may be used solely or as a mixture of two or more kinds.

The non-PVA derivatives mean the ones that have a polarity close to PVA and the derivatives thereof to such an extent that they exhibit compatibility with PVA and the derivatives thereof.

Specific examples of the non-PVA derivatives may include a hydrophilic polyamide that is obtained by incorporating a hydrophilic group such as polyethylene glycol or piperazine into a water insoluble polyamide obtained by polymerizing adipic acid, 1,6-hexanediamine, or ε-caprolactam. The hydrophilic polyamide exhibits compatibility with the PVA derivatives by an action of the hydrophilic group thereof, so that the hydrophilic polyamide is suitably used as a non-PVA derivative. That is, the hydrophilic polyamide has an adequate compatibility with the PVA and the derivatives thereof and easily enters between the molecules of the PVA and the derivatives thereof, thereby lowering the intermolecular force between these two kinds of polymers and softening the polymer.

(Hydrophobic Polymer)

As the binder polymer in the present invention, a relatively hydrophobic binder polymer may be also used.

As the relatively hydrophobic polymer, for the purpose of adjusting film hardness or flexibility upon film forming and properties such as compatibility with the other components such as coexisting polymerizable compounds or initiators, a polymer that contains, as a polymerizable or copolymerizable component, the following monomers may be used.

A compound having one ethylenic unsaturated bond, such as: a (meth)acrylate having a hydroxyl group such as 2-hydroxyethyl (meth)acrylate, 2-hydroxypropyl (meth)acrylate, 2-hydroxybutyl (meth)acrylate, 3-chloro-2-hydroxypropyl (meth)acrylate, or β-hydroxy-β′-(meth)acryloyloxyethyl phthalate; an alkyl (meth)acrylate such as methyl (meth)acrylate, ethyl (meth)acrylate, propyl (meth)acrylate, butyl (meth)acrylate, isoamyl (meth)acrylate, 2-ethylhexyl (meth)acrylate, lauryl (meth)acrylate, or stearyl (meth)acrylate; a cycloalkyl (meth)acrylate such as cyclohexyl (meth)acrylate; a halogenated alkyl (meth)acrylate such as chloroethyl (meth)acrylate or chloropropyl (meth)acrylate; an alkoxyalkyl (meth)acrylate such as methoxyethyl (meth)acrylate, ethoxyethyl (meth)acrylate, or butoxyethyl (meth)acrylate; a phoenoxyalkyl (meth)acrylate such as phenoxyethyl (meth)acrylate or nonylphenoxyethyl (meth)acrylate; an alkoxyalkylene glycol (meth)acrylate such as ethoxydiethylene glycol (meth)acrylate, methoxytriethylene glycol (meth)acrylate, or methoxydipropylene glycol (meth)acrylate; (meth)acrylamides such as (meth)acrylamide, diacetone (meth)acrylamide, or N,N′-methylene bis(meth)acrylamide; 2,2-dimethylaminoethyl (meth)acrylate; 2,2-diethylaminoethyl (meth)acrylate; N,N-dimethylaminoethyl (meth)acrylamide; and N,N-dimethylaminopropyl (meth)acrylamide.

A compound having two or more ethylenic unsaturated bonds, such as: a di(meth)acrylate of polyethylene glycol such as diethylene glycol di(meth)acrylate; a polypropylene glycol di(meth)acrylate such as dipropylene glycol di(meth)acrylate; trimethylolpropane tri(meth)acrylate; pentaerythritol tri(meth)acrylate; pentaerythritol tetra(meth)acrylate; glycerol tri(meth)acrylate; a polyfunctional (meth)acrylate that is obtained by addition reaction between ethylene glycol diglycidylether and a compound having an ethylenic unsaturated bond and an active hydrogen such as unsaturated carboxylic acid or unsaturated alcohol; a polyfunctional (meth)acrylate that is obtained by addition reaction between an unsaturated epoxy compound such as glycidyl (meth)acrylate and a compound having an active hydrogen such as carboxylic acid or amine; a polyfunctional (meth)acrylamide such as methylene bis(meth)acrylamide; and a polyfunctional vinyl compound such as divinylbenzene.

In the present invention, these may be used solely or in a combination of two or more kinds thereof.

As the monomer serving as the polymerizable component, from the viewpoint of film forming property, an alkoxyalkylene glycol (meth)acrylate such as 2-hydroxyethyl (meth)acrylate, 2-hydroxypropyl (meth)acrylate, 2-hydroxybutyl (meth)acrylate, ethoxydiethylene glycol (meth)acrylate, methoxytriethylene glycol (meth)acrylate, or methoxydipropylene glycol (meth)acrylate; (meth)acrylamide; diacetone (meth)acrylamide; cyclohexyl (meth)acrylate; benzyl (meth)acrylate; and N-acryloylmorpholine are preferable. Of these, acrylates are particularly preferable from the viewpoint of securing flexibility of resulting polymers.

Besides the above, as the binder polymer, the following polymer may be used.

Namely, a polymer having at least an olefin or a carbon to carbon triple bond in the main chain thereof may be used, and for example, SB (polystyrene-polybutadiene), SBS (polystyrene-polybutadiene-polystyrene), SIS (polystyrene-polyisoprene-polystyrene), and SEBS (polystyrene-polyethylene-polybutylene-polystyrene) may be used.

Polymer Having Carbon to Carbon Unsaturated Bond

In the present invention, since it is necessary that a crosslinked structure is included in the relief forming layer, a polymer having a carbon to carbon unsaturated bond in the molecule thereof may be used as the binder polymer, from the viewpoint of improving efficiency of formation of a crosslinked structure. The carbon to carbon unsaturated bond may be incorporated in the main chain and/or side chain of the polymer. Hereinafter, the carbon to carbon unsaturated bond is referred to as simply “unsaturated bond” in some cases. Further, the carbon to carbon unsaturated bond at the end of the main chain or side chain is referred to as “polymerizable group” in some cases.

When a carbon to carbon unsaturated bond is incorporated in the main chain of the polymer, it may be incorporated at one end or both ends or in the main chain of the polymer main chain. Further, when a carbon to carbon unsaturated bond is incorporated in the side chain of the polymer, it may be linked to the main chain structure directly or through an appropriate linking group.

Examples of the polymer having a carbon to carbon unsaturated bond in the main chain thereof may include SB (polystyrene-polybutadiene), SBS (polystyrene-polybutadiene-polystyrene), SIS (polystyrene-polyisoprene-polystyrene), and SEBS (polystyrene-polyethylene-polybutylene-polystyrene).

When a polymer having a highly reactive polymerizable unsaturated group such as methacryloyl group is used as the polymer having a carbon to carbon unsaturated bond in the side chain thereof, a film having an extremely high mechanical strength may be prepared. Particularly in a polyurethane or polyester thermoplastic elastomer, a highly reactive polymerizable unsaturated group may be incorporated easily in the molecule thereof.

In order to introduce an unsaturated bond or a polymerizable group into the binder polymer, any known method may be selected, such as a method in which a structural unit having a polymerizable group precursor obtained by linking a protective group to a polymerizable group is copolymerized in a polymer; and then the protective group is eliminated to restore the polymerizable group, and a method in which a polymer compound having plural reactive groups such as hydroxyl, amino, epoxy, carboxyl, acid anhydride, ketone, hydrazine, isocyanate, isothiocyanate, cyclic carbonate, or ester group is prepared; after that, a linking agent (for example, polyisocyanate in the case of hydroxyl group or amino group) having plural groups capable of linking to the above reactive groups is reacted with the polymer compound; and then, after the molecular weight is adjusted and the terminal groups are transformed into terminal linking groups, the polymer compound is reacted through a polymer reaction with an organic compound that has a polymerizable unsaturated group and a group having a capability of reacting with the terminal linking groups so as to introduce a polymerizable group. In accordance with these methods, the amount of the unsaturated bond and the polymerizable group introduced into the polymer compound may be regulated.

The polymer having an unsaturated bond may be preferably used in combination with a polymer having no unsaturated bond. Namely, a polymer that is obtained by adding hydrogen to an olefin portion of the polymer having a carbon-carbon unsaturated bond or a polymer that is obtained from a monomer having a hydrogenated olefin portion, for example, a monomer obtained by hydrogenating butadiene, isoprene or the like, may be used together because these polymers have an adequate compatibility. Thereby, the amount of the unsaturated bond that the binder polymer possesses may be controlled.

When these are used together, the polymer having no unsaturated bond may be used in an amount of usually from 1 part to 90 parts by mass and preferably from 5 parts to 80 parts by mass with respect to 100 parts by mass of the polymer having an unsaturated bond.

Note that, as described later, in an embodiment in which the binder polymer is not required to be curable, including a case where the other polymerizable compounds are used together, an unsaturated bond is not necessarily essential for the binder polymer. Various kinds of polymers that have no unsaturated bond may be used as the binder polymer. Preferable examples of the polymer having no unsaturated bond may include polyester, polyamide, polystyrene, acrylic resin, acetal resin, and polycarbonate.

The number average molecular weight of the binder polymer that has or does not has an unsaturated bond is in the range of preferably from 1,000 to 1,000,000 and more preferably from 5,000 to 500,000. When the number average molecular weight is in the range of from 1,000 to 1,000,000, the mechanical strength of resulting films may be secured. The number average molecular weight described herein is measured by gel permeation chromatography (GPC) using a polystyrene having a known molecular weight as a standard sample.

As the binder polymer in the present invention, among the various kinds of binder polymers as described above, a polymer selected from the group consisting of vinyl polymers, polyamide, polyurethane, and polyurea is preferably used from the viewpoint of improving engraving sensitivity.

Hereinafter, these preferable binder polymers are described.

(Vinyl Polymers)

The vinyl polymers according to the present invention are preferably polymers or copolymers obtained from the following vinyl monomers including acrylic acid esters, methacrylic acid esters, vinylesters, acrylamides, methacrylamides, olefins, styrenes, crotonic acid esters, itaconic acid diesters, maleic acid diesters, and fumaric acid diesters, but the present invention is in no way limited by these polymers or copolymers.

Examples of the acrylic acid esters may include: methyl acrylate, ethyl acrylate, n-propyl acrylate, isopropyl acrylate, n-butyl acrylate, tert-butyl acrylate, isobutyl acrylate, sec-butyl acrylate, amyl acrylate, hexyl acrylate, 2-ethylhexyl acrylate, octyl acrylate, tert-octyl acrylate, 2-chloroethyl acrylate, 2-bromoethyl acrylate, 4-chlorobutyl acrylate, cyanoethyl acrylate, 2-acetoxyethyl acrylate, dimethylaminoethyl acrylate, benzyl acrylate, methoxybenzyl acrylate, 2-chlorocyclohexyl acrylate, cyclohexyl acrylate, furfuryl acrylate, tetrahydrofurfuryl acrylate, phenyl acrylate, 5-hydroxypentyl acrylate, 2,2-dimethyl-3-hydroxypropyl acrylate, 2-methoxyethyl acrylate, 3-methoxybutyl acrylate, 2-ethoxyethyl acrylate, 2-iso-propoxyethyl acrylate, 2-butoxyethyl acrylate, 2-(2-methoxyethoxy)ethyl acrylate, 2-(2-butoxyethoxy)ethyl acrylate, ω-methoxypolyethylene glycol acrylate (addition mole number n is 9), 1-bromo-2-methoxyethyl acrylate, and 1,1-dichloro-2-ethoxyethyl acrylate.

Examples of the methacrylic acid esters may include: methyl methacrylate, ethyl methacrylate, n-propyl methacrylate, isopropyl methacrylate, n-butyl methacrylate, tert-butyl methacrylate, isobutyl methacrylate, sec-butyl methacrylate, amyl methacrylate, hexyl methacrylate, cyclohexyl methacrylate, benzyl methacrylate, chlorobenzyl methacrylate, octyl methacrylate, sulfopropyl methacrylate, N-ethyl-N-phenylaminoethyl methacrylate, 2-(3-phenylpropyloxy)ethyl methacrylate, dimethylaminophenoxyethyl methacrylate, furfuryl methacrylate, tetrahydrofurfuryl methacrylate, phenyl methacrylate, cresyl methacrylate, naphthyl methacrylate, 2-hydroxyethyl methacrylate, 4-hydroxybutyl methacrylate, triethylene glycol monomethacrylate, dipropylene glycol monomethacrylate, 2-methoxyethyl methacrylate, 3-methoxybutyl methacrylate, 2-acetoxyethyl methacrylate, 2-acetoacetoxyethyl methacrylate, 2-ethoxyethyl methacrylate, 2-iso-propoxyethyl methacrylate, 2-butoxyethyl methacrylate, 2-(2-methoxyethoxy)ethyl methacrylate, 2-(2-ethoxyethoxy)ethyl methacrylate, 2-(2-butoxyethoxy)ethyl methacrylate, and ω-methoxypolyethylene glycol methacrylate (addition mole number n is 6).

Examples of the vinylesters may include: vinyl acetate, vinyl propionate, vinyl butylate, vinyl isobutylate, vinyl caproate, vinylchloro acetate, vinylmethoxy acetate, vinylphenyl acetate, vinyl benzoate, and vinyl salicylate.

Examples of the acrylamides may include: acrylamide, methyl acrylamide, ethyl acrylamide, propyl acrylamide, butyl acrylamide, tert-butyl acrylamide, cyclohexyl acrylamide, benzyl acrylamide, hydroxymethyl acrylamide, methoxyethyl acrylamide, dimethylaminoethyl acrylamide, phenyl acrylamide, dimethyl acrylamide, diethyl acrylamide, β-cyanoethylacrylamide, N-(2-acetoacetoxyethyl)acrylamide, and diacetone acrylamide.

Examples of the methacrylamides may include: methacrylamide, methyl methacrylamide, ethyl methacrylamide, propyl methacrylamide, butyl methacrylamide, tert-butyl methacrylamide, cyclohexyl methacrylamide, benzyl methacrylamide, hydroxymethyl methacrylamide, methoxyethyl methacrylamide, dimethylaminoethyl methacrylamide, phenyl methacrylamide, dimethyl methacrylamide, diethyl methacrylamide, β-cyanoethyl methacrylamide, and N-(2-acetoacetoxyethyl) methacrylamide.

Examples of the olefins may include: dicyclopentadiene, ethylene, propylene, 1-butene, 1-pentene, vinyl chloride, vinylidene chloride, isoprene, chloroprene, butadiene, and 2,3-dimethyl butadiene.

Examples of the styrenes may include: styrene, methylstyrene, dimethylstyrene, trimethylstyrene, ethylstyrene, isopropylstyrene, chloromethylstyrene, methoxystyrene, chlorostyrene, dichlorostyrene, bromostyrene, and vinylbenzoic acid methylester.

Examples of the crotonic acid esters may include: butyl crotonate and hexyl crotonate.

Examples of the itaconic acid diesters may include: dimethyl itaconate, diethyl itaconate, and dibutyl itaconate.

Examples of the maleic acid diesters may include: diethyl maleate, dimethyl maleate, and dibutyl maleate.

Examples of the fumaric acid diesters may include: diethyl fumarate, dimethyl fumarate, and dibutyl fumarate.

Examples of the other monomers that are used for preparation of the vinyl polymer may include the following monomers:

allyl compounds such as allyl acetate, allyl caproate, allyl laurate, or allyl benzoate;

vinyl ethers such as methylvinyl ether, butylvinyl ether, hexylvinyl ether, methoxyethylvinyl ether, or dimethylaminoethylvinyl ether;

vinyl ketones such as methylvinyl ketone, phenylvinyl ketone, or methoxyethylvinyl ketone;

vinyl heterocyclic compounds such as vinylpyridine, N-vinylimidazole, N-vinyloxazolidone, N-vinyltriazole, or N-vinylpyrrolidone;

glycidyl esters such as glycidyl acrylate or glycidyl methacrylate; and

unsaturated nitriles such as acrylonitrile or methacrylonitrile.

The vinyl polymers used in the present invention may be a homo-polymer of the monomers described above or, if necessarily, a copolymer obtained from two or more kinds of the monomers.

As the binder polymer in the present invention, among the vinyl polymers, a vinyl polymer that is soluble in water and/or ethanol is preferable.

In the present invention, “a polymer that is soluble in water and/or ethanol” means that precipitates of polymers are not found and the solution (dispersion liquid) is transparent and uniform when the solubility of the polymer is observed in a manner described below.

Namely, 0.1 g of a binder polymer in a powder or pellet form and 2 mL of water or 2 mL of ethanol are mixed; the mixture is covered with a lid and allowed to stand at room temperature for 24 hours; and the solubility of the binder polymer is evaluated by visual observation.

As the vinyl polymer that is soluble in water and/or ethanol, a polyvinyl alcohol (PVA) derivative is preferable. The PVA derivative in the present invention means a copolymer or polymer that contains a hydroxyethylene unit in an amount of from 0.1 mol % to 100 mol %, preferably from 1 mol % to 98 mol %, and more preferably from 5 mol % to 95 mol %, or a modified product thereof. Therefore, polyvinyl alcohol itself is also included. The monomer that forms the copolymer may be selected appropriately from known copolymerizable monomers. The modified products are exemplified as follows.

Examples of the modified products of the PVA derivatives may include: a polymer in which at least part of the hydroxyl groups of the hydroxyethylene units is modified into carboxyl groups; a polymer in which part of the hydroxyl groups is modified into (meth)acryloyl groups; a polymer in which at least part of the hydroxyl groups is modified into amino groups; and a polymer in which ethylene glycol, propylene glycol, or a multimer thereof is introduced into at least part of the hydroxyl groups.

The polymer in which at least part of the hydroxyl groups of the hydroxyethylene units is modified into carboxyl groups may be obtained through esterification between polyvinyl alcohol or partly saponified polyvinyl alcohol and a multi-functional carboxylic acid such as succinic acid, maleic acid, or adipic acid.

The amount of the carboxyl groups introduced is preferably from 0.01 mol to 1.00 mol and more preferably from 0.05 mol to 0.80 mol with respect to 1 mol of the hydroxyl groups.

The polymer in which at least part of the hydroxyl groups of the hydroxyethylene units is modified into (meth)acryloyl groups is obtained through addition of glycidyl (meth)acrylate to the above carboxyl group modified polymer or through esterification between polyvinyl alcohol or partly saponified polyvinyl alcohol and (meth)acrylic acid.

The amount of the (meth)acryloyl groups introduced is preferably from 0.01 mol to 1.00 mol and more preferably from 0.03 mol to 0.50 mol with respect to 1 mol of the hydroxyl groups. Note that, the term “(meth)acryloyl group” is a generic name of acryloyl group and/or methacryloyl group. The term “(meth)acrylate” is a generic name of acrylate and/or methacrylate. Also, the term “(meth)acrylic acid” or the like is the same.

The polymer in which at least part of the hydroxyl groups of the hydroxyethylene units is modified into amino groups may be obtained through esterification between polyvinyl alcohol or partly saponified polyvinyl alcohol and a carboxylic acid having an amino group such as carbamic acid.

The amount of the amino groups introduced is preferably from 0.01 mol to 1.00 mol and more preferably from 0.05 mol to 0.70 mol with respect to 1 mol of the hydroxyl groups.

The polymer in which ethylene glycol, propylene glycol, or a multimer thereof is introduced into at least part of the hydroxyl groups of the hydroxyethylene units may be obtained by a method in which polyvinyl alcohol or partly saponified polyvinyl alcohol and glycols are heated in the presence of a sulfuric acid catalyst while by-product water is removed from the reaction system.

The amount of the ethylene glycol or propylene glycol or multimer thereof introduced is preferably from 0.01 mol to 0.90 mol and more preferably from 0.03 mol to 0.50 mol with respect to 1 mol of the hydroxyl groups.

Among these modified products, the polymer in which at least part of the hydroxyl groups of the hydroxyethylene units is modified into (meth)acryloyl groups is preferably used. Namely, by directly introducing an unreacted crosslinkable functional group into the hydrophilic polymer, the strength of resulting cured films may be increased without using a large amount of a polymerizable compound having an ethylenic unsaturated bond that is described later, thereby enabling the resulting cured films to attain both flexibility and strength.

As the vinyl polymers of the present invention, polyvinyl acetal may be also effectively used. Polyvinyl acetal obtained by treating polyvinyl alcohol with aldehydes may be used. Examples of the aldehydes that are used for the acetal treatment are specifically described below, but they are not limitative.

Specific examples of the aldehydes used for the acetal treatment may include: aliphatic aldehydes such as formaldehyde, acetaldehyde, propione aldehyde, n-butyl aldehyde, t-butyl aldehyde, amyl aldehyde, hexyl aldehyde, or 2-ethylhexyl aldehyde; alicyclic aldehydes such as cyclohexyl aldehyde or furfural; and aromatic aldehydes such as benzaldehyde, an alkyl-substituted benzaldehyde, a halogen-substituted benzaldehyde, or a phenyl-substituted alkylaldehyde. Of these, acetaldehyde and butylaldehyde are preferably used because they are easy to handle. These aldehydes may be used solely or in a combination of two or more kinds.

(Polyamide)

Polyamide may be obtained by polycondensation between a diamine compound and a dicarboxylic acid compound, polycondensation of an aminocarboxylic acid compound, ring-opening polymerization of lactams, and others.

Examples of the diamine compound, dicarboxylic acid compound, aminocarboxylic acid compound, and lactams that are used for the synthesis of the polyamide in the present invention are described below, but the present invention is in no way limited by these examples.

Examples of the diamine compound may include: ethylenediamine, 1,3-propanediamine, 1,2-propanediamine, hexamethylenediamine, octamethylenediamine, o-phenylenediamine, m-phenylenediamine, p-phenylenediamine, piperazine, 2,5-dimethylpiperazine, 4,4′-diaminophenylether, 3,3′-diaminodiphenylsulfone, and xylylenediamine.

Examples of the dicarboxylic acid compound may include: oxalic acid, malonic acid, succinic acid, glutaric acid, dimethyl malonic acid, adipic acid, pimelic acid, α,α-dimethyl succinic acid, acetone dicarboxylic acid, sebacic acid, 1,9-nonane dicarboxylic acid, fumaric acid, maleic acid, itaconic acid, citraconic acid, phthalic acid, isophthalic acid, terephthalic acid, 2-butyl terephthalic acid, tetrachloro terephthalic acid, acetylene dicarboxylic acid, poly(ethylene terephthalate) dicarboxylic acid, 1,2-cyclohexane dicarboxylic acid, 1,4-cyclohexane dicarboxylic acid, ω-poly(ethyleneoxy) dicarboxylic acid, and p-xylylene dicarboxylic acid.

These dicarboxylic acid compounds may be used in the form of an alkylester (for example, dimethylester) of carboxylic acid, in the acid chloride form of dicarboxylic acid, or in the form of an acid anhydride such as maleic anhydride, succinic anhydride or phthalic anhydride.

Examples of the aminocarboxylic acid may include glycine, alanine, phenylalanine, ω-aminohexanoic acid, ω-aminodecanoic acid, w-aminoundecanoic acid, and anthranilic acid.

Examples of the monomers (lactams) used for ring-opening polymerization may include ω-caprolactam, azetidinone, and pyrolidone.

(Polyurethane)

Polyurethane is basically synthesized by polyaddition reaction using a diol compound and a diisocyanate compound as raw materials.

Examples of the diol compound and diisocyanate compound that are used for polyurethane synthesis in the present invention are described below, but the present invention is in no way limited by these examples.

Specific examples of the diol compound may include: ethylene glycol, 1,2-propane diol, 1,3-propane diol, 1,3-butane diol, 2,3-butane diol, 2,2-dimethyl-1,3-propane diol, 1,4-pentane diol, 2,4-pentane diol, 3,3-dimethyl-1,2-butane diol, 2-ethyl-2-methyl-1,3-propane diol, 1,6-hexane diol, 2,5-hexane diol, 2-methyl-2,4-pentane diol, 2,2-diethyl-1,3-propane diol, 2,4-dimethyl-2,4-pentane diol, 2-methyl-2-propyl-1,3-propane diol, 2,5-dimethyl-2,5-hexane diol, 2-ethyl-1,3-hexane diol, 1,2-octane diol, 2,2,4-trimethyl-1,3-pentane diol, 1,4-cyclohexane dimethanol, diethylene glycol, triethylene glycol, dipropylene glycol, tripropylene glycol, polyethylene glycol (average molecular weight is 200, 300, 400, 600, 1,000, 1,500, or 4,000), polypropylene glycol (average molecular weight is 200, 400, or 1,000), polyester polyol, 4,4′-dihydroxy-diphenyl-2,2-propane, 4,4-dihydroxyphenylsulfone, 2,2-bis(hydroxymethyl)propionic acid, 2,2-bis(hydroxymethyl) butanoic acid, 2,5,6-trimethoxy-3,4-dihydroxy hexanoic acid, 2,3-dihydroxy-4,5-dimethoxy pentanoic acid, 2,4-di(2-hydroxy)ethyloxycarbonylbenzene sulfonic acid, and salts thereof.

Preferable specific examples of the diisocyanate compound may include: ethylene diisocyanate, isophorone diisocyanate, hexamethylene diisocyanate, 1,4-cyclohexane diisocyanate, 2,4-toluene diisocyanate, 1,3-xylene diisocyanate, 1,5-naphthalene diisocyanate, m-phenylene diisocyanate, p-phenylene diisocyanate, 3,3′-dimethyl-4,4′-diphenylmethane diisocyanate, 3,3′-dimethylbiphenylene diisocyanate, dicyclohexylmethane diisocyanate, and methylene bis(4-cyclohexyl isocyanate).

(Polyurea)

Polyurea may be basically obtained by polyaddition between a diamine compound and a diisocyanate compound or deammoniation between a diamine compound and urea.

Examples of the diamine compound and diisocyanate compound that are used for the synthesis of polyurea in the present invention are described below, but the present invention is in no way limited by these examples.

Examples of the diamine compound may include a compound that is selected from the same group of diamines as that described in the foregoing section of polyamide.

Further, examples of the diisocyanate compound may include a compound selected from the same group of diisocyanates as that described in the foregoing section of polyurethane.

In the present invention, as the binder polymer, from the viewpoint of engraving sensitivity, vinyl polymers are particularly preferable and vinyl polymers that are soluble in water and/or ethanol are still more preferable.

It is thought that in the present invention, since the (A) peroxide and the (B) binder polymer are used in combination, not only the heat generated by the laser irradiation but also the heat generated by the decomposition of the (A) peroxide acts on the adjacent (A) binder polymer, so that the thermal decomposition in the process (iv) is accelerated and the laser engraving sensitivity is very high.

In the present invention, a weight average molecular weight (evaluated by GPC measurement in terms of polystyrene) of the binder polymer is preferably from 5,000 to 500,000. When the weight average molecular weight is 5,000 or more, an excellent shape retention property as a single resin is attained. When 500,000 or less, the binder polymer is easy to dissolve in solvent such as water and is advantageous for preparing a relief forming layer for laser engraving. The weight average molecular weight of the binder polymer is more preferably from 10,000 to 400,000 and particularly preferably from 15,000 to 300,000.

The total content of the binder polymer is, with respect to the total solid mass of the relief forming layer, preferably from 15% to 75% by mass, and more preferably from 20% to 65% by mass.

That is, in the relief forming layer in the relief printing plate precursor for laser engraving of the present invention, by selecting the content of the binder polymer to be 15% by mass or more, sufficient printing durability of the resulting relief printing plate to be used as a printing plate is attainable. By selecting 75% by mass or less, the content of the other components is not insufficient, and sufficient flexibility of the resulting relief printing plate to be used as a flexo printing plate is attainable.

<(C) Crosslinking Agent>

From the viewpoint of effectively forming a crosslinked structure in the relief forming layer, the resin composition for forming a relief forming layer preferably includes a crosslinking agent.

The crosslinking agent in the invention is not particularly limited as long as it is capable of polymerizing and curing the relief forming layer by a photo or thermal reaction (such as a radical polymerization reaction or a crosslinking reaction with an acid or a base as an initiating species).

In particular, (C-1) a polymerizable compound having an ethylenic unsaturated bond (hereinafter also referred to as a polymerizable compound), (C-2) a crosslinking agent having a —SiR¹R²R³ group, wherein R¹-R³ each independently represent a hydrogen atom, a halogen atom, or a monovalent organic group, wherein at least one of R¹-R³ represents an alkyl group, an aryl group, an alkoxy group, a hydroxy group, or a halogen atom, and (C-3) a compound having groups selected from the group consisting of acid anhydride groups, isocyanate groups, hydroxy groups, amino groups, block isocyanate groups, carboxyl groups, and epoxy groups, are preferably used.

The crosslinked structure in the relief forming layer may be formed by the reaction between these compounds and the binder, or the reaction between these compounds, or by both the reaction.

The molecular weights of these crosslinking agents are not particularly limited but preferably from 50 to 3,000, more preferably from 70 to 2,500, and further preferably from 100 to 2,000.

Hereinafter, crosslinking agents which may be preferably used in the invention are described in detail.

(C-1) Polymerizable Compound Having Ethylenic Unsaturated Bond

In the present invention, from the viewpoint of forming a crosslinked structure in a relief forming layer, the resin composition for forming the relief forming layer preferably includes a polymerizable compound having an ethylenic unsaturated bond (hereinafter, simply referred to as “polymerizable compound” in some cases) as a crosslinking agent.

The polymerizable compound may be arbitrarily selected from compounds having at least one, preferably two or more, and more preferably from 2 to 6 ethylenic unsaturated double bonds.

A mono-functional monomer having one ethylenic unsaturated double bond in the molecule thereof and a multi-functional monomer having two or more ethylenic unsaturated double bonds in the molecule thereof that are used as the polymerizable compound are described below.

Since it is necessary that the relief forming layer according to the present invention includes a crosslinked structure, the multi-functional monomer is preferably used. The multi-functional monomer has a molecular weight of preferably from 200 to 2,000.

Examples of the mono-functional monomer and multi-function monomer may include: an ester of an unsaturated carboxylic acid (for example, acrylic acid, methacrylic acid, itaconic acid, crotonic acid, isocrotonic acid, maleic acid or the like) and a polyhydric alcohol compound; and an amide of an unsaturated carboxylic acid and a polyamine compound.

Specific examples of the ester monomer of a polyhydric alcohol compound and an unsaturated carboxylic acid may include: as an acrylic acid ester, ethylene glycol diacrylate, triethylene glycol diacrylate, 1,3-butandiol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol pentaacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, and a polyester acrylate oligomer.

As a methacrylic acid ester, tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, dipentaerythritol pentamethacrylate, sorbitol trimethacrylate, sorbitol tetramethacrylate, bis[p-(3-methacryloxy-2-hydroxypropoxy)phenyl]dimethylmethane, and bis-[p-(methacryloxyethoxy)phenyl]dimethylmethane may be used.

As an itaconic acid ester, ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate may be used.

As a crotonic acid ester, ethylene glycol dicrotonate, tetramethylene glycol dicrotonate, pentaerythritol dicrotonate, and sorbitol tetradicrotonate may be used.

As an isocrotonic acid ester, ethylene glycol diisocrotonate, pentaerythritol diisocrotonate, and sorbitol tetraisocrotonate may be used.

As a maleic acid ester, ethylene glycol dimaleate, triethylene glycol dimaleate, pentaerythritol dimaleate, and sorbitol tetramaleate may be used.

In addition, a mixture of the foregoing ester monomers may be also used.

Specific examples of the amide monomer of a polyamine compound and an unsaturated carboxylic acid may include methylene bis-acrylamide, methylene bis-methacrylamide, 1,6-hexamethylene bis-acrylamide, 1,6-hexamethylene bis-methacrylamide, diethylenetriamine tris-acrylamide, xylylene bis-acrylamide, and xylylene bis-methacrylamide.

Further, urethane acrylates as described in JP-A No. 51-37193; polyester acrylates as described in JP-A No. 48-64183, Japanese Examined Patent Application (JP-B) Nos. 49-43191 and 52-30490; and multi-functional acrylates or methacrylates such as epoxy acrylates obtained by reacting an epoxy resin and (meth)acrylic acid may be used. Still further, light curable monomers or oligomers as described in Journal of the Adhesion Society of Japan, Vol. 20, No. 7, page 300 to 308 (1984) may be used.

Specifically, NK OLIGO U-4HA, U-4H, U-6HA, U-6ELH, U-108A, U-1084A, U-200AX, U-122A, U-340A, U-324A and UA-100 (trade names, manufactured by Shin-nakamura Chemical Co., Ltd.); UA-306H, AI-600, UA-101T, UA-101I, UA-306T and UA-306I (trade names, manufactured by Kyoeisha Chemical Co., Ltd.); ARTRESIN UN-9200A, UN-3320HA, UN-3320HB, UN-3320HC, SH-380G, SH-500 and SH-9832 (trade names, manufactured by Negami Chemical Industrial Co., Ltd.); and PLEX6661-O (trade name, manufactured by Degussa Corp., Germany) may be used.

In the present invention, as the polymerizable compound, from the viewpoint of improving engraving sensitivity, a compound having a sulfur atom in the molecule thereof is preferably used.

As the polymerizable compound having a sulfur atom in the molecule thereof, from the viewpoint of improving engraving sensitivity, a polymerizable compound (hereinafter, referred to as “sulfur-containing multi-functional monomer”, appropriately) having two or more ethylenic unsaturated bonds and a carbon to sulfur bond that is positioned at a site where two of the ethylenic unsaturated bonds are linked together is preferably used, particularly.

As a carbon to sulfur bond containing functional group that is contained in the sulfur-containing multi-functional monomer in the present invention, a functional group that contains sulfide, disulfide, sulfoxide, sulfonyl, sulfone amide, thiocarbonyl, thiocarboxylic acid, dithiocarboxylic acid, sulfamic acid, thioamide, thiocarbamate, dithiocarbamate, or thiourea may be exemplified.

As a carbon to sulfur bond containing linking group that links two of the ethylenic unsaturated bonds in the sulfur-containing multi-functional monomer, at least one unit selected from —C—S—, —C—SS—, —NH(C═S)O—, —NH(C═O)S—, —NH(C═S)S—, and —C—SO₂— may be preferably exemplified.

There is not any limitation on the number of the sulfur atom contained in the molecule of the sulfur-containing multi-functional monomer as long as the number is at least 1, and the number may be appropriately selected in accordance with purposes, but the number is preferably from 1 to 10, more preferably from 1 to 5, and still more preferably from 1 to 2, from the viewpoint of balancing between engraving sensitivity and solubility in a coating solvent.

There is not any limitation on the number of the ethylenic unsaturated portions contained in the molecule as long as the number is at least 2, and the number may be selected appropriately in accordance with purposes, but the number is preferably from 2 to 10, more preferably from 2 to 6, and still more preferably from 2 to 4, from the viewpoint of flexibility of resulting crosslinked films.

As the ethylenic unsaturated portion contained in the sulfur-containing multi-functional monomer, the partial structure represented by any of the following formulas (1) to (5) is suitable, but from the viewpoint of decomposability of a polymerized product, the partial structure represented by any of formulas (1) to (3) is preferable. The partial structure represented by formula (1) is more preferable.

Note that, in the sulfur-containing multi-functional monomer of the present invention, regarding any partial structure of formulas (1) to (5), two or more same kinds or two or more different kinds may exist in one molecule.

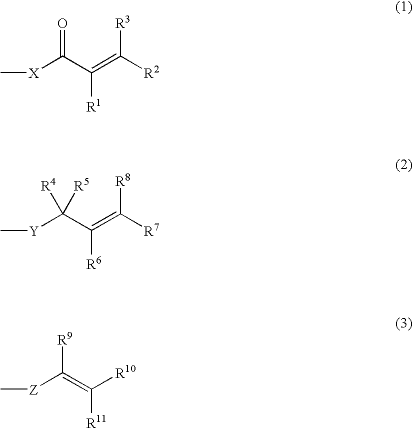

At first, there will be explained formulas (1) to (3).

In formulas (1) to (3), R¹ to R¹¹ each are independently hydrogen atom or a mono-valent substituent group. X and Y each are independently oxygen atom, sulfur atom, —NR^{a}—, or sulfonyl group. Z is oxygen atom, sulfur atom, —NR^{a}—, sulfonyl group, or phenylene group. Here, R^{a} is hydrogen atom or a mono-valent organic group.

In formula (1), R¹ to R³ each are independently hydrogen atom or a mono-valent substituent group.

Examples of R¹ may include hydrogen atom and an organic group such as an alkyl group that may have a substituent group. Of these, specifically, hydrogen atom, methyl group, methylalkoxy group, or methylester group is preferable.

R² and R³ each may independently be: hydrogen atom, a halogen atom, amino group, a dialkylamino group, carboxyl group, an alkoxycarbonyl group, sulfo group, nitro group, cyano group, an alkyl group that may have a substituent group, an aryl group that may have a substituent group, an alkoxy group that may have a substituent group, an aryloxy group that may have a substituent group, an alkylamino group that may have a substituent group, an arylamino group that may have a substituent group, an alkylsulfonyl group that may have a substituent group, or an arylsulfonyl group that may have a substituent group. Of these, hydrogen atom, carboxyl group, an alkoxycarbonyl group, an alkyl group that may have a substituent group, or an aryl group that may have a substituent group is preferable. Examples of the substituent group that may be introduced into these groups may include methoxycarbonyl group, ethoxycarbonyl group, isopropoxycarbonyl group, methyl group, ethyl group, and phenyl group.

X is preferably oxygen atom, sulfur atom, or —NR^{a}—; examples of R^{a} may include an alkyl group that may have a substituent group.

In formula (2), R⁴ to R⁸ each are independently hydrogen atom or a mono-valent substituent group.

Examples of R⁴ to R⁸ may include: hydrogen atom, a halogen atom, amino group, a dialkylamino group, carboxyl group, an alkoxycarbonyl group, sulfo group, nitro group, cyano group, an alkyl group that may have a substituent group, an aryl group that may have an substituent group, an alkoxy group that may have a substituent group, an aryloxy group that may have a substituent group, an alkylamino group that may have a substituent group, an arylamino group that may have a substituent group, an alkylsulfonyl group that may have a substituent group, and an arylsulfonyl group that may have a substituent group. Of these, hydrogen atom, carboxyl group, an alkoxycarbonyl group, an alkyl group that may have a substituent group, or an aryl group that may have a substituent group is preferable. Examples of the substituent group that may be introduced into these groups may include the ones exemplified as the substituent group that may be introduced in formula (1).

Y is preferably oxygen atom, sulfur atom, or —NR^{a}—; and as R^{a}, examples similar to the ones in formula (1) may be exemplified.

In formula (3), R⁹ to R¹¹ each are independently hydrogen atom or a mono-valent substituent group.

Specific examples of R⁹ to R¹¹ may include: hydrogen atom, a halogen atom, amino group, a dialkylamino group, carboxyl group, an alkoxycarbonyl group, sulfo group, nitro group, cyano group, an alkyl group that may have a substituent group, an aryl group that may have an substituent group, an alkoxy group that may have a substituent group, an aryloxy group that may have a substituent group, an alkylamino group that may have a substituent group, an arylamino group that may have a substituent group, an alkylsulfonyl group that may have a substituent group, and an arylsulfonyl group that may have a substituent group. Of these, hydrogen atom, carboxyl group, an alkoxycarbonyl group, an alkyl group that may have a substituent group, or an aryl group that may have a substituent group is preferable. Examples of the substituent group that may be introduced into these groups may include the ones exemplified as the substituent group that may be introduced in formula (1).

Z is preferably oxygen atom, sulfur atom, —NR^{a}—, or phenylene group; and as R^{a}, examples similar to the ones in formula (1) may be exemplified.

The sulfur-containing multi-functional monomer in the present invention may include, besides the partial structure represented by any of formulas (1) to (3), a linking group L that links the ethylenic unsaturated portions. L represents a di-valent or more linking group that has a carbon to sulfur bond. From the viewpoint of thermal decomposability, the linking group L preferably has an ester bond besides a carbon to sulfur bond. In a more preferable embodiment, the linking group L has an ester bond and a hydroxyl group at the same time.

As a functional group having a carbon to sulfur bond that is incorporated in the linking group L, a functional group that contains sulfide, disulfide, sulfoxide, sulfonyl, sulfone amide, thiocarbonyl, thiocarboxylic acid, dithiocarboxylic acid, sulfamic acid, thioamide, thiocarbamate, dithiocarbamate, or thiourea may be exemplified. From the viewpoint of engraving sensitivity, a functional group that contains disulfide, thiocarbamate or dithiocarbamate is preferable. A functional group that contains disulfide is more preferable.

The linking group L contains preferably a hydrocarbon group besides the functional group having a carbon to sulfur bond. Particularly, the linking group L has a total carbon number of preferably from 1 to 10. Among these, the linking group L contains preferably plural hydrocarbon groups that have from 1 to 6 carbon atoms respectively and are linked together through a structure other than a hydrocarbon group, such as an ester. As the hydrocarbon group, an alkylene group having from 1 to 6 carbon atoms, phenylene group or the like is preferable. As the structure, other than hydrocarbon groups, that is included in the linking group L, besides ester bond, amide bond, urea bond, urethane bond, ether bond, and carbonyl group may be preferably exemplified, but ester bond is the most preferable. The hydrocarbon group may be substituted appropriately by a mono-valent substituent group. As the substituent group, hydroxyl group, thiol group, amino group, carboxyl group, cyano group, nitro group or the like is preferably used. Particularly, as the hydrocarbon group that is included in the linking group L, a hydrocarbon group substituted by a hydroxyl group is preferable. The linking group L preferably has a structure having from 1 to 5 hydrocarbon groups per one ethylenic unsaturated bond.

Preferable specific examples of the sulfur-containing multi-functional monomer having the partial structure represented by any of formulas (1) to (3) are described below, but the present invention is in no way limited by these examples.

Rs in the following specific examples represent hydrogen atom or methyl group, and these may be the same or different from each other.

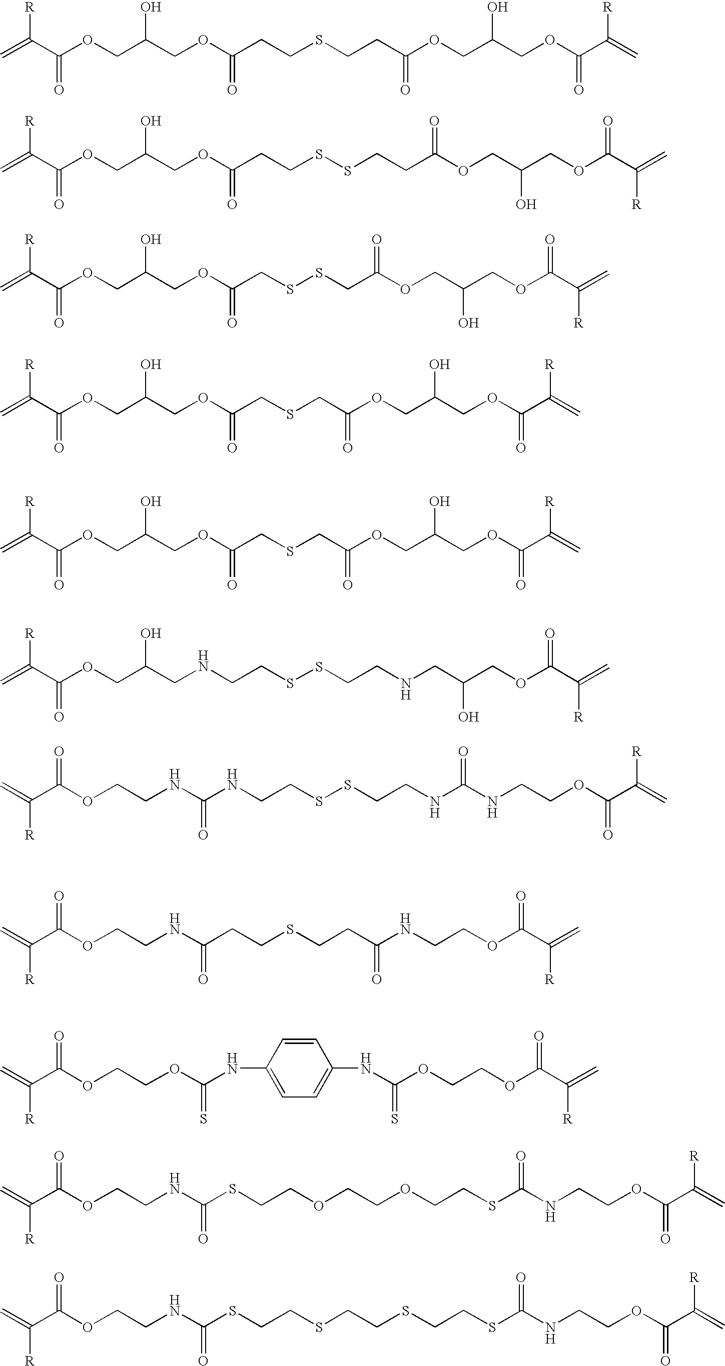

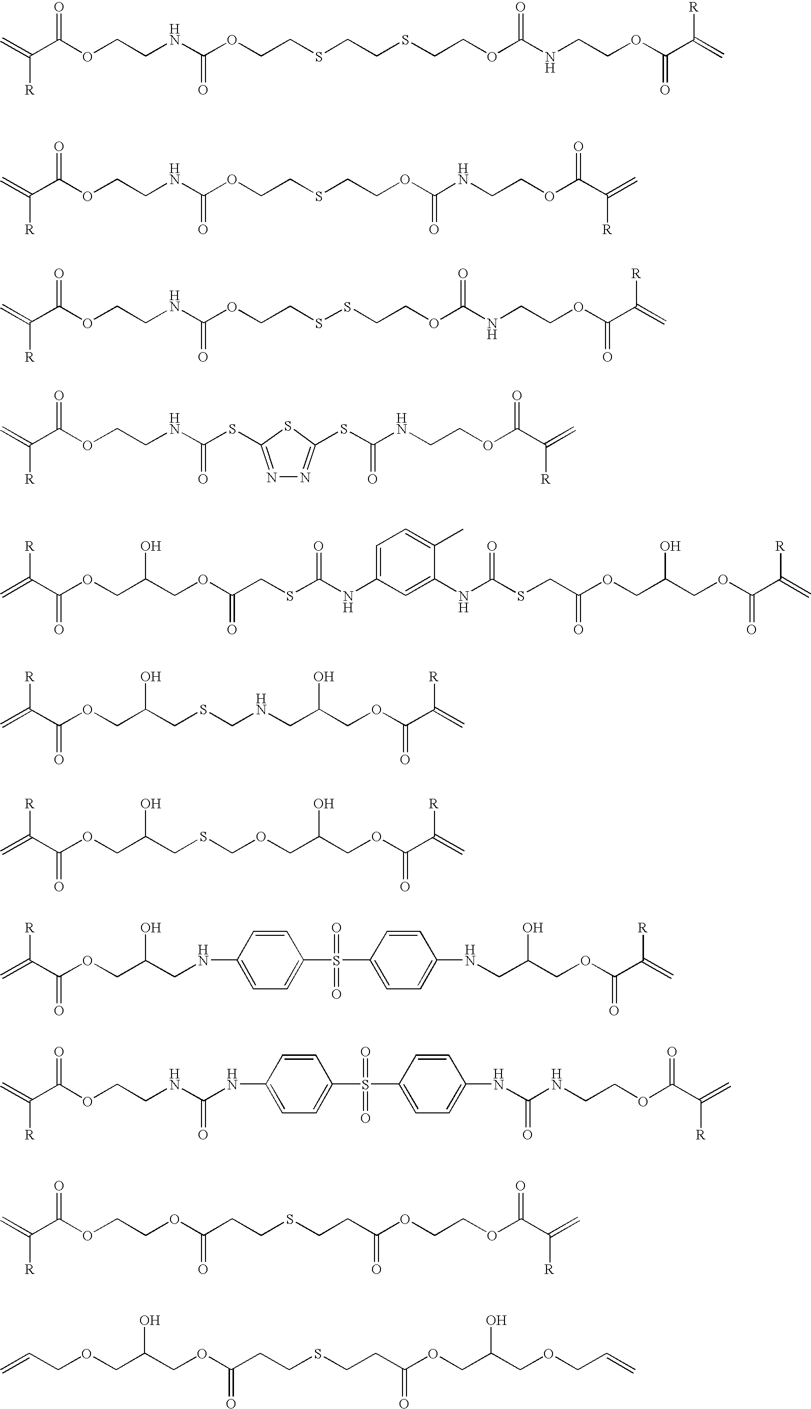

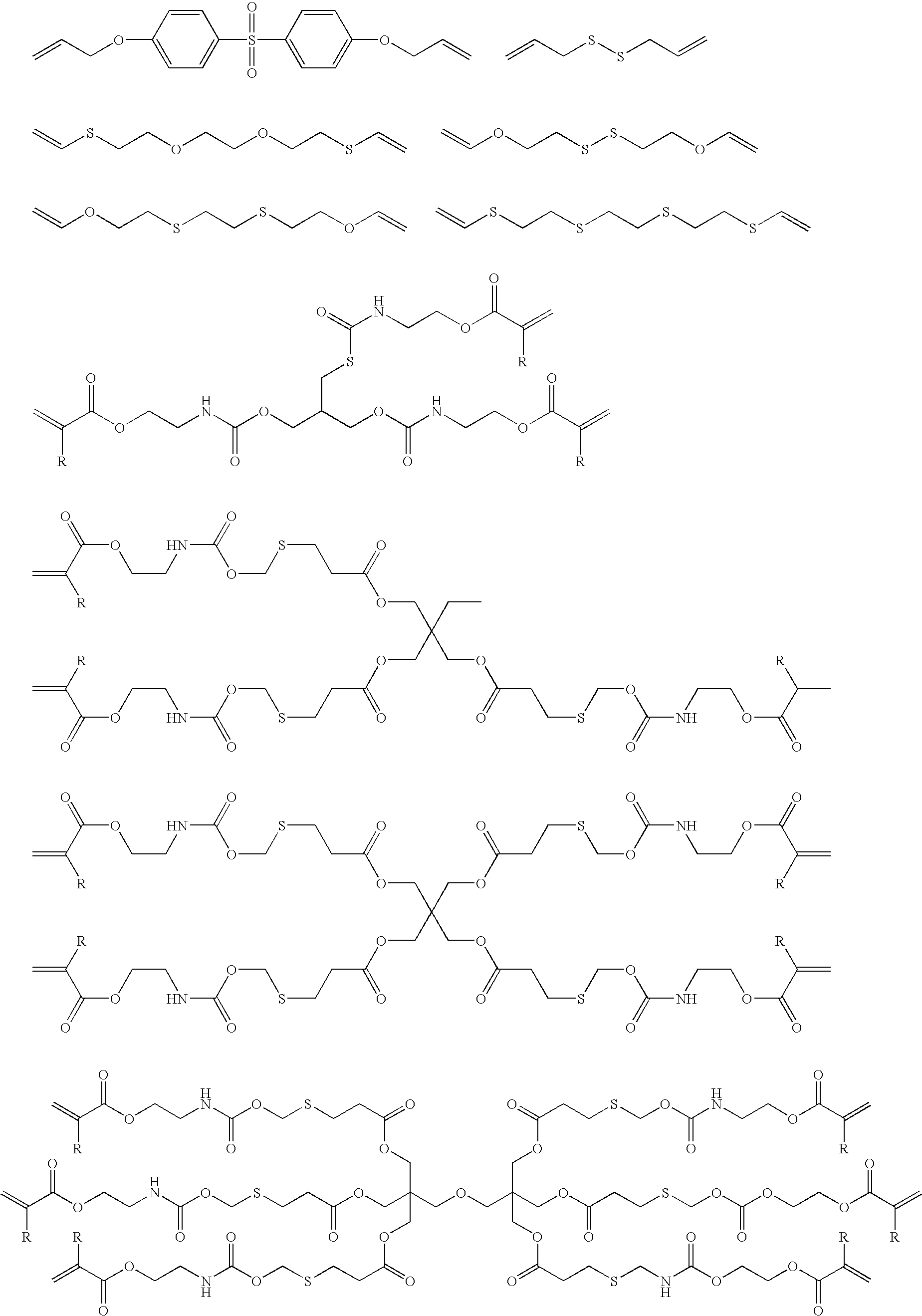

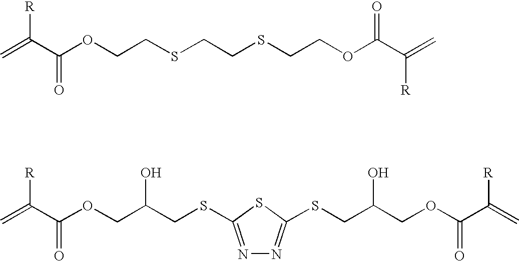

Next, there will be described the partial structures represented by the following formulas (4) and (5).

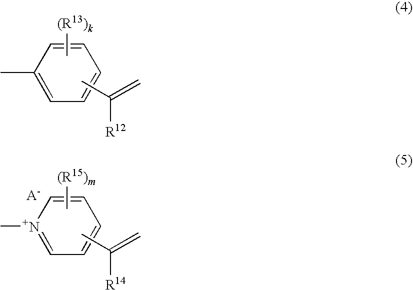

In formula (4), R¹² is hydrogen atom or methyl group; R¹³ is an atom or atomic group that is substitutable; k is an integer of from 0 to 4

In formula (5), R¹⁴ is hydrogen atom or methyl group; R¹⁵ is an atom or atomic group that is substitutable; m is an integer of from 0 to 4; and A⁻ is a counter anion.

The pyridinium ring may be in the form of a benzopyridinum having a condensed benzene ring in which two R¹⁵s link together to form the benzene ring. In this case, a quinolium or isoquinolium group may be included.

The atoms or atomic groups represented by R¹³ and R¹⁵ each are independently a halogen atom, amino group, a dialkylamino group, carboxyl group, an alkoxycarbonyl group, sulfo group, nitro group, cyano group, an alkyl group that may have a substituent group, an aryl group that may have a substituent group, an alkoxy group that may have a substituent group, an aryloxy group that may have a substituent group, an alkylamino group that may have a substituent group, an arylamino group that may have a substituent group, an alkylsulfonyl group that may have a substituent group, an arylsulfonyl group that may have a substituent group, and the like. Of these, carboxyl group, an alkoxycarbonyl group, an alkyl group that may have a substituent group, and an aryl group that may have a substituent group are preferable. Examples of the substituent group that may be introduced into these groups may include methoxycarbonyl group, ethoxycarbonyl group, isopropoxycarbonyl group, methyl group, ethyl group, and phenyl group.

Examples of the counter anion represented by A⁻ may include: F⁻, Cl⁻, Br⁻, I⁻, BF₄⁻, PF₆⁻, AsF₆⁻, SbF₆⁻, BAr₄⁻ (Ar is an aryl group that may be substituted by arbitrary number of fluorine atom or CF₃; the four Ars may be the same or different from one another), CF₃SO₃⁻, p-CH₃C₆H₄SO₃⁻, CH₃SO₃⁻, and CF₃COO⁻.

The sulfur-containing multi-functional monomer in the present invention may include, besides the partial structure represented by formula (4) or (5), a linking group L that links the ethylenic unsaturated portions. The linking group L has the same meaning as that of the foregoing linking group L, and the preferable examples thereof are also the same.

Preferable examples of the sulfur-containing multi-functional monomer having the partial structure represented by formula (4) or formula (5) are described below, but the present invention is in no way limited by these examples.

Rs in the specific examples represents hydrogen atom or methyl group, these Rs may be the same or different from each other.

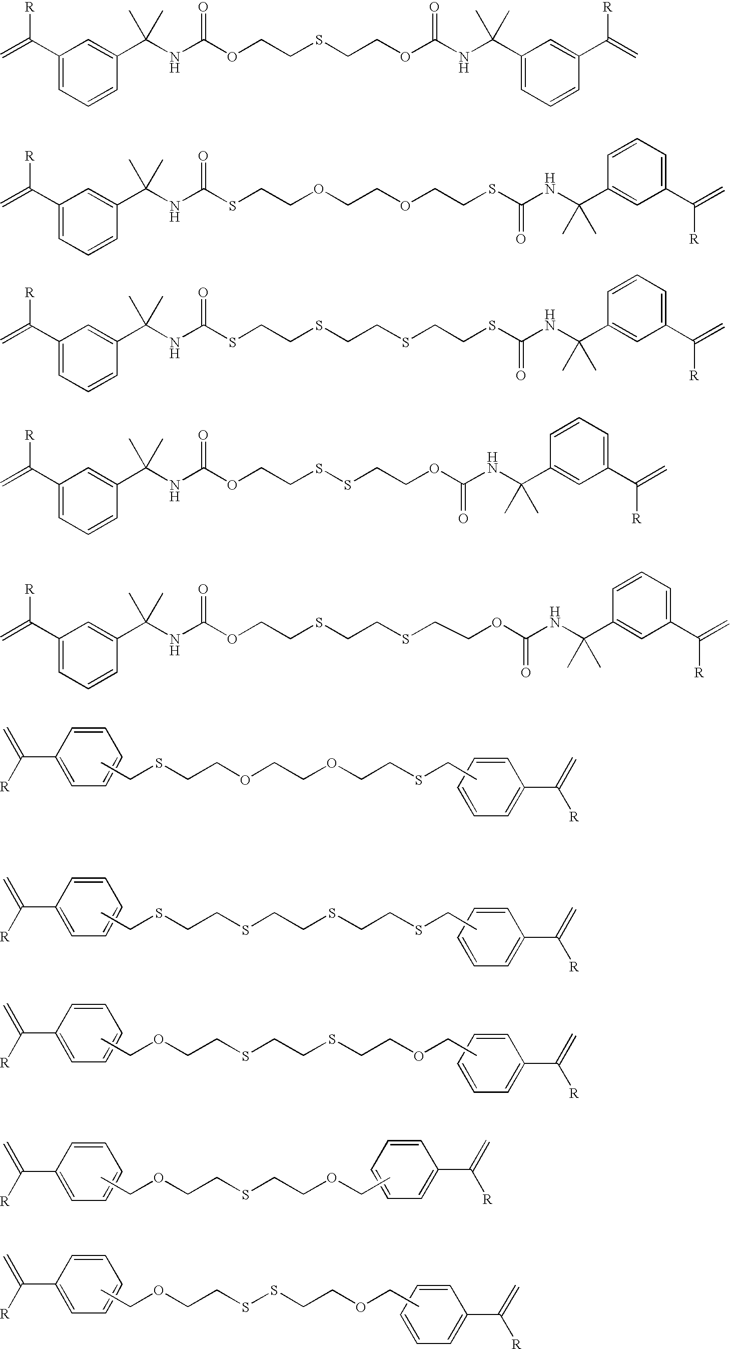

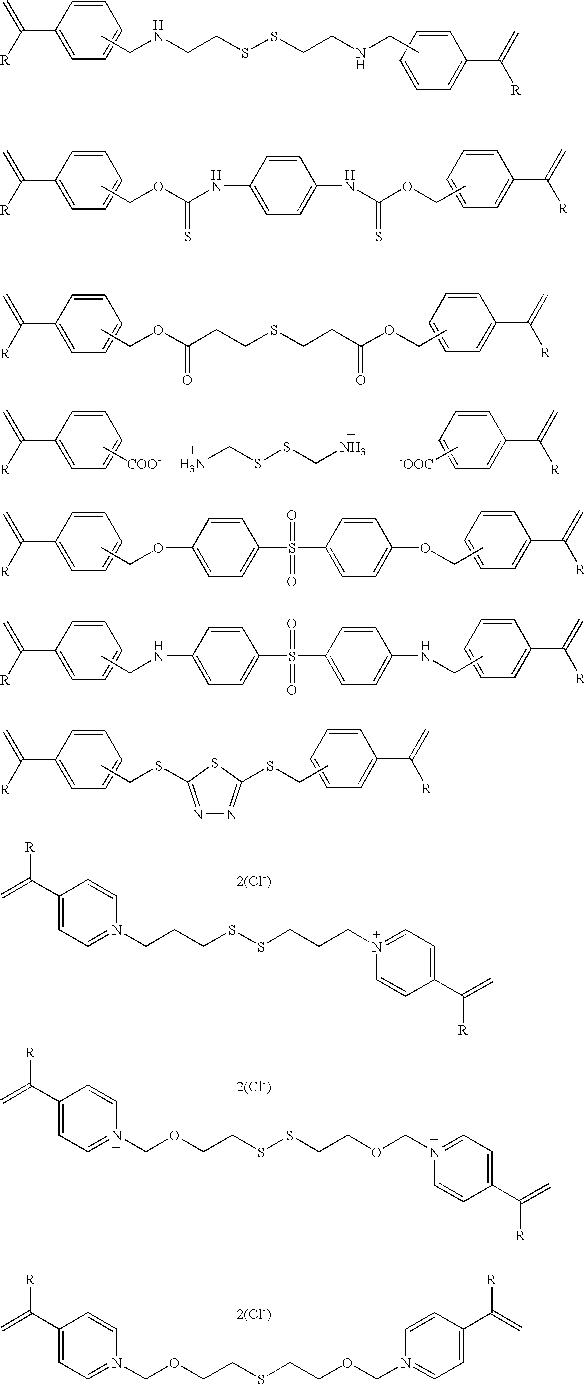

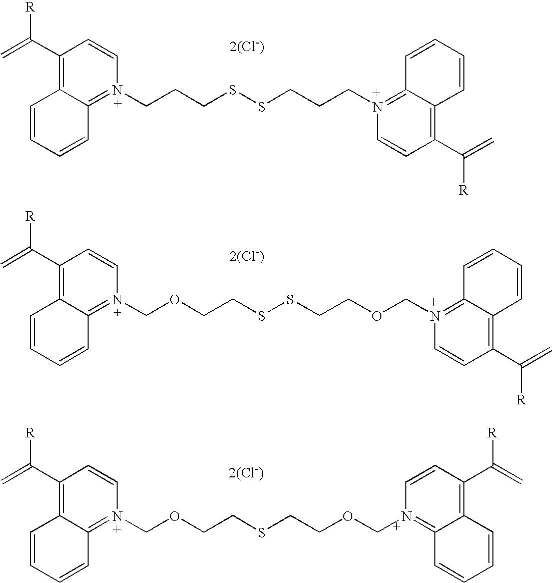

The sulfur-containing multi-functional monomer in the present invention may be synthesized through a reaction between a sulfur atom containing dicarboxylic acid and an epoxy group containing (meth)acrylate; a reaction between a sulfur atom containing diol and an isocyanate containing (meth)acrylate; a reaction between a dithiol and an isocyanate containing (meth)acrylate; a reaction between a diisocyanate and a hydroxy group containing (meth)acrylate; a known esterification reaction; and the like. Alternatively, commercially available products may be used.

The molecular weight of the sulfur-containing multi-functional monomer is, from the viewpoint of the flexibility of resulting films, preferably from 120 to 3,000 and more preferably from 120 to 1,500.

The sulfur-containing multi-functional monomer in the present invention may be used solely, but may be used as a mixture with a multi-functional or mono-functional polymerizable compound that has no sulfur atom in the molecule thereof.

From the viewpoint of engraving sensitivity, a mode of using the sulfur-containing multi-functional monomer solely or a mode of using the sulfur-containing multi-functional monomer as a mixture with a mono-functional ethylenic monomer is preferable. A mode of using the sulfur-containing multi-functional monomer as a mixture with a mono-functional ethylenic monomer is more preferable.

When, as crosslinking agents, a sulfur-containing multi-functional monomer and another crosslinking agent other than the monomer, such as a polymerizable compound, are used together, the content of the sulfur-containing multi-functional monomer in the total content of the crosslinking agents is preferably 5% by mass or more, and more preferably 10% by mass or more.

(C-2) Crosslinking Agent Having —SiR¹R²R³ Group

As a crosslinking agent which may be used in the invention, a crosslinking agent having at least a —SiR¹R²R³ group as a crosslinkable group may be preferably exemplified, and a crosslinking agent having two or more —SiR¹R²R³ groups may be more preferably exemplified.

R¹-R³ are each independently represent a hydrogen atom, a halogen atom, or a monovalent organic group, wherein at least one of R¹-R³ is an alkyl group, an alkoxy group, a hydroxy group, or a halogen atom.

It is preferable that at least two of R¹-R³ each independently represent an alkoxy group or a halogen atom, and it is particularly preferable that R¹-R³ each independently represent an alkoxy group or a halogen atom. Further, it is preferable that at least two of R¹-R³ represent alkoxy groups from the viewpoint of handling of the compound.

The alkoxy groups in R¹-R³ are preferably alkoxy groups having from 1 to 30 carbon atoms, more preferably alkoxy groups having from 1 to 15 carbon atoms, and further preferably alkoxy groups having from 1 to 5 carbon atoms, from the viewpoint of the rinsing property and the printing durability.

Examples of the halogen atoms in R¹-R³ include F, Cl, Br and I atoms, and Cl and Br atoms are preferable, and Cl atoms are more preferable, from the viewpoint of easy synthesis and stability of the compound.

In particular, it is preferable that all of R¹-R³ are methoxy groups or ethoxy groups.

A crosslinking agent having two or more —SiR¹R²R³ groups is also preferably used. In particular, a crosslinking agent having two to six —SiR¹R²R³ groups is preferably used. The linking group that links two or more —SiR¹R²R³ groups in the crosslinking agent having two or more —SiR¹R²R³ groups may be a divalent or higher-valent organic group, and from the viewpoint that the engraving sensitivity is high, the linking group is preferably a divalent or higher-valent organic group including a hetero atom (such as N, S or O), and more preferably a divalent or higher-valent organic group including a S atom.

As the crosslinking agent having at least a —SiR¹R²R³ group, a compound having two —SiR¹R²R³ groups in each of which a methoxy group or an ethoxy group is bonded to the Si atom wherein these Si atoms are linked to each other via an alkylene group containing a hetero atom (preferably a S atom) is preferably used.

Examples of the crosslinking agent having a —SiR¹R²R³ group include vinyl trichlorosilane, vinyl trimethoxysilane, vinyl triethoxysilane, β-(3,4-epoxy cyclohexyl)ethyl trimethoxysilane, γ-glycidoxy propyl trimethoxysilane, γ-glycidoxy propyl methyl diethoxysilane, γ-glycidoxy propyl triethoxysilane, γ-methacryloxy propyl methyl dimethoxysilane, γ-methacryloxy propyl trimethoxysilane, γ-methacryloxy propyl methyl diethoxysilane, γ-methacryloxy propyl triethoxysilane, γ-acryloxy propyl trimethoxysilane, N-(β-aminoethyl)-γ-aminopropyl methyl dimethoxysilane, N-(β-aminoethyl)-γ-aminopropyltrimethoxysilane, N-(β-aminoethyl)-γ-aminopropyl triethoxysilane, γ-aminopropyltrimethoxysilane, γ-aminopropyl triethoxysilane, N-phenyl-γ-aminopropyltrimethoxysilane, γ-mercapto propyl trimethoxysilane, γ-chloropropyl trimethoxysilane, and γ-ureide propyl triethoxysilane.

Specific examples of the crosslinking agent having a —SiR¹R²R³ group which may be used in the invention are preferably the compounds represented by the following formulae, but not limited thereto. In the following formulae, Et represents an ethyl group, and Me represents a methyl group.

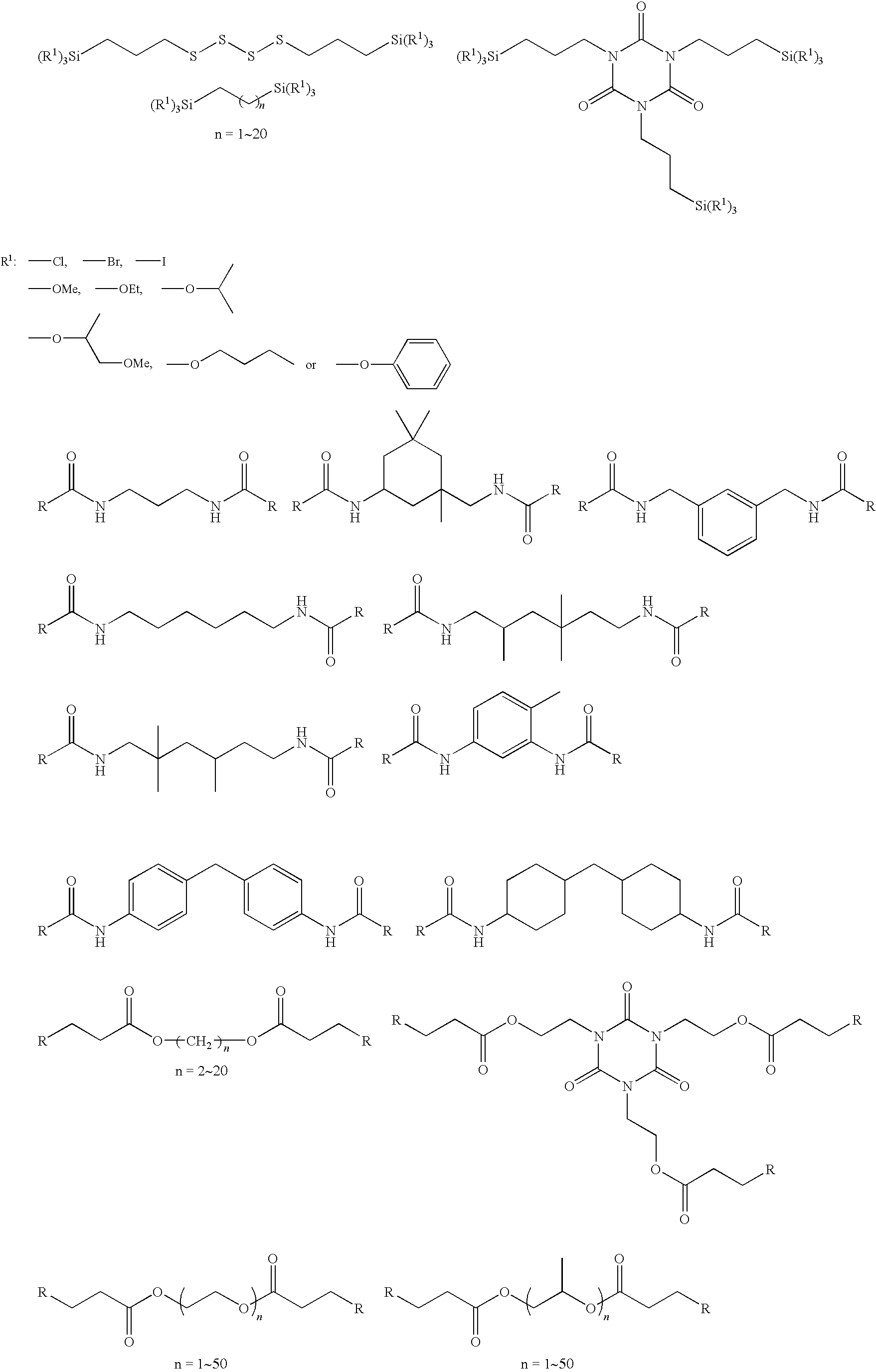

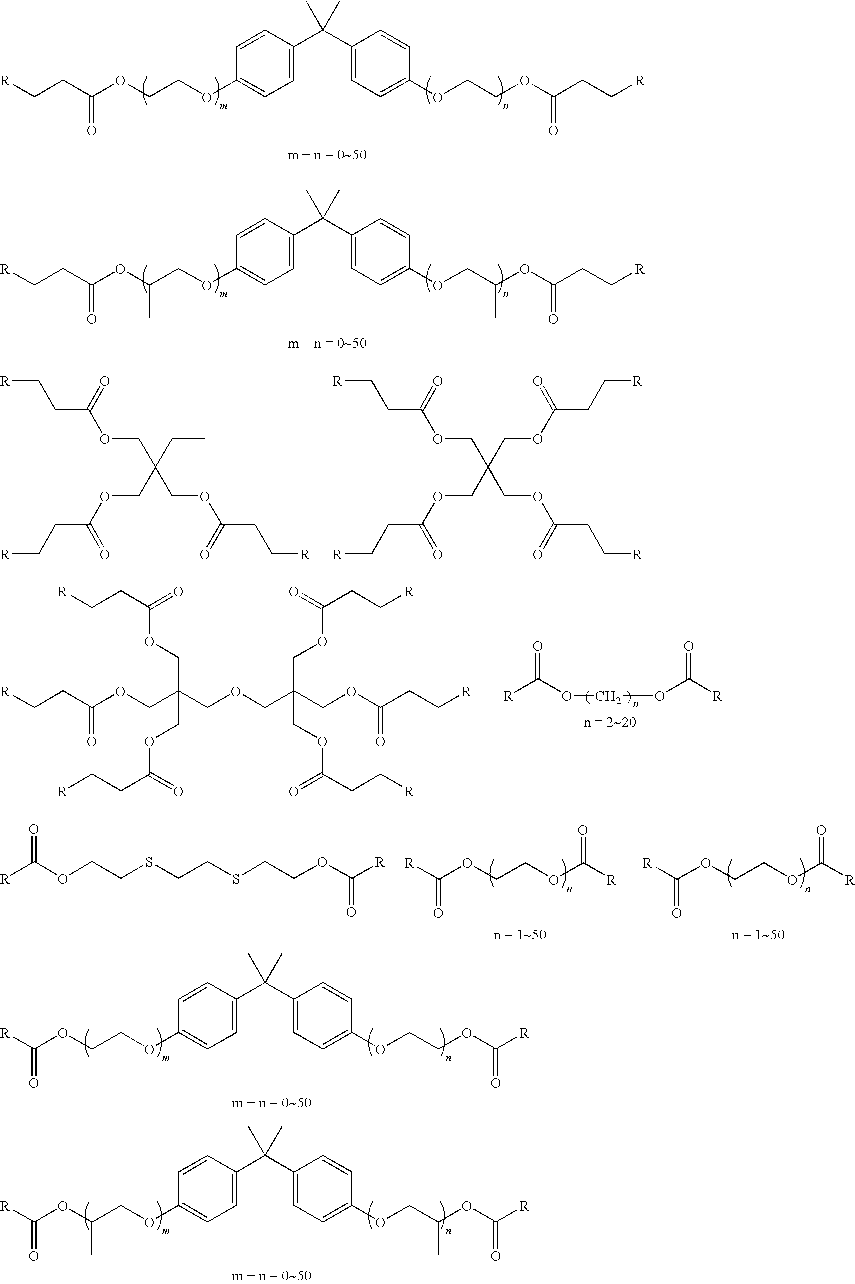

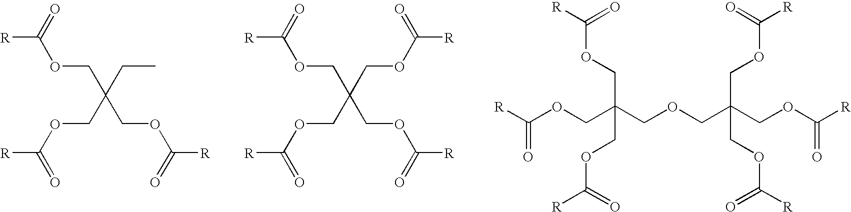

In the above formulae, R represents a partial structure selected from the following structures. When plural Rs or R¹s are present in the molecule, these may be the same or different from each other, and from the viewpoint of synthesis suitability, they are preferably the same.

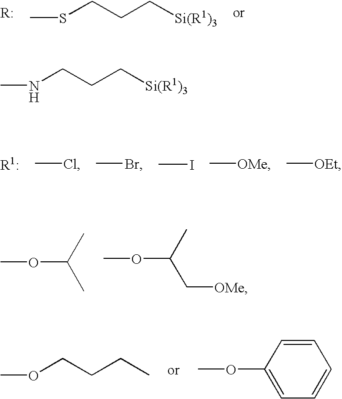

As other examples of the crosslinking agent, the compounds represented by the following formulae may also be preferably exemplified.

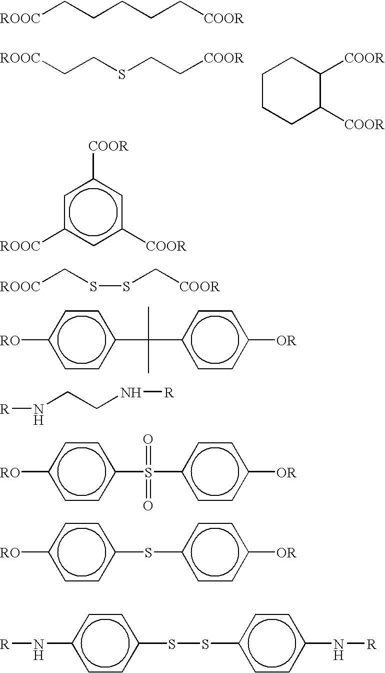

In the above formulae, R represents a partial structure represented by the following formula, wherein R¹ has the same meaning as that described above. When plural Rs or R¹s are present in the molecule, these may be the same or different from each other, and from the viewpoint of synthesis suitability, they are preferably the same.

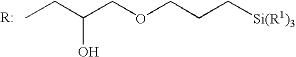

As the (C-2) crosslinking agent having a —SiR¹R²R³ group, a compound appropriately synthesized may be used, but from the viewpoint of the cost, commercially available one is preferably used. These compounds may be available from Shin-Etsu Chemical Co., Ltd., Dow Corning Toray Co., Ltd., and the like, as a silane compound or a silane coupling agent.

When a compound having a —SiR¹R²R³ group is used as a crosslinking agent, a binder polymer having a functional group capable of reacting with the compound (such as a hydroxy group) is preferably used, but another binder polymer may also be used.

(C-3) Crosslinking Agent Having Functional Groups Selected from the Group Consisting of Acid Anhydride Groups, Isocyanate Groups, Block Isocyanate Groups, Carboxyl Groups, and Epoxy Groups

In the present invention, it is also preferable to use a crosslinking agent having functional groups selected from the group consisting of acid anhydride groups, isocyanate groups, block isocyanate groups, carboxyl groups, and epoxy groups. In particular, a crosslinking agent having acid anhydride groups or isocyanate groups as the functional groups are preferable.

Preferable examples of a crosslinking agent having two or more acid anhydride groups which may be used in the invention include tetrabasic acid dianhydrides. Specific examples of the tetrabasic acid dianhydrides include aliphatic or aromatic tetracarboxylic acid dianhydrides such as biphenyl tetracarboxylic acid dianhydride, naphthalene tetracarboxylic acid dianhydride, diphenyl ether tetracarboxylic acid dianhydride, butane tetracarboxylic acid dianhydride, cyclopentane tetracarboxylic acid dianhydride, pyromellitic acid dianhydride, benzophenone tetracarboxylic acid dianhydride, and pyridine tetracarboxylic acid dianhydride. Further, examples of a compound having three carboxylic acid anhydride structures include mellitic acid trianhydride.

Examples of a crosslinking agent having two or more isocyanate groups which may be used in the invention include an aromatic diisocyanate compound such as 2,4-tolylene diisocyanate, 2,6-tolylene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate; an aliphatic diisocyanate compound such as hexamethylene diisocyanate, trimethyl hexamethylene diisocyanate, and lysine diisocyanate; an alicyclic diisocyanate compound such as isophorone diisocyanate, 4,4′-methylene bis(cyclohexylisocyanate), methylcyclohexane-2,4 (or, 2,6)-diisocyanate, and 1,3-bis(isocyanate methyl)cyclohexane; and a diisocyanate compound which is a reaction product of a diol and a diisocyanate, such as the adduct of 1 mol of 1,3-butylene glycol and 2 mol of tolylene diisocyanate.

When the (C-3) crosslinking agent having functional groups selected from the group consisting of acid anhydride groups, isocyanate groups, block isocyanate groups, carboxyl groups, and epoxy groups is used, a binder polymer having a functional group capable of reacting with the crosslinking agent (such as a carboxyl group or an amino group) is preferably used, but another binder polymer may also be used.

In the relief forming layer according to the present invention, film properties such as brittleness or flexibility may be also controlled by using (C) a crosslinking agent.

The total amount of the (C) crosslinking agent in the relief forming layer is, from the viewpoint of the flexibility or brittleness of resulting crosslinked films, in the range of preferably from 10% to 60% by mass and more preferably from 15% to 45% by mass, with respect to the nonvolatile components in the relief forming layer.

<Crosslinking Accelerator>

When using the compound having a —SiR¹R²R³ group or the like as the crosslinking agent in the resin composition, it is preferable that a crosslinking accelerator (hereinafter also referred to as a catalyst) is further included therein in order to accelerate the reaction between the crosslinking agent and the binder polymer.

The crosslinking accelerator which may be used in the invention is not particularly limited as long as it is capable of accelerating the reaction between the crosslinking agent and a specific polymer and/or the reaction between a specific hydrophilic compound and a specific polymer. Preferable examples thereof include (1) an acidic catalyst or a basic catalyst, and (2) a metal complex catalyst.

In particular, as the crosslinking accelerator, (1) an acidic catalyst or a basic catalyst is preferable. Further, when a hydroxy group is involved in the reaction, a basic catalyst is particularly preferable from the viewpoint of the crosslinking rate of the hydroxy group.

(1) Acidic Catalyst or Basic Catalyst

As the catalyst, an acidic compound or a basic compound is used as it is, or a solution in which the compound is dissolved in a solvent such as water or an organic solvent is used (hereinafter, they are also referred to as an acidic catalyst and a basic catalyst, respectively). The concentration when the compound is dissolved in a solvent is not particularly limited, and appropriately selected in accordance with the properties of the acidic compound or the basic compound, and the content of the catalyst.

The kind of the acidic catalyst or the basic catalyst is not particularly limited. Specific examples of the acidic catalyst include a hydrogen halide such as hydrochloric acid, nitric acid, sulfuric acid, sulfurous acid, hydrogen sulfide, perchloric acid, hydrogen peroxide, carbonic acid, a carboxylic acid such as formic acid or acetic acid, a substituted carboxylic acid represented by RCOOH wherein R is substituted with another element or a substituent group, a sulfonic acid such as benzenesulfonic acid, phosphoric acid, heteropoly acid, and inorganic solid acid. Examples of the basic catalyst include an ammonia base such as ammonia water, an amine such as ethylamine or aniline, an alkali metal hydroxide, an alkali metal alkoxide, an alkaline earth metal oxide, a quaternary ammonium salt compound, and a quaternary phosphonium salt compound, among which an amine is preferably used.

From the viewpoing of accelerating the alcohol exchange reaction in the film, methanesulfonic acid, p-toluenesulfonic acid, pyridinium p-toluene sulphonate, dodecyl benzene sulfonic acid, phosphoric acid, phosphonic acid, acetic acid, 1,8-diazabicyclo[5.4.0]undec-7-ene, 1,5-diazabicyclo[4.3.0]non-5-ene, and 1,1,3,3-tetramethylguanidine are preferable, and methanesulfonic acid, p-toluenesulfonic acid, phosphoric acid, 1,8-diazabicyclo[5.4.0]undec-7-ene, and 1,5-diazabicyclo[4.3.0]non-5-ene are particularly preferable.

(2) Metal Complex Catalyst

The metal complex catalyst which may be used in the invention is preferably a metal complex catalyst including a metal selected from the group consisting of metals in Groups 2, 4, 5 and 13 in the periodic table, and an oxo or hydroxy compound selected from the group consisting of a β-diketone, a ketoester, a hydroxy carboxylic acid and an ester thereof, an amino alcohol, and an enol active hydrogen compound.

Further, preferable examples of a metal for forming a complex excellent in catalytic effect include Group 2 elements such as Mg, Ca, Sr and Ba, Group 4 elements such as Ti and Zr, Group 5 elements such as V, Nb and Ta, and Group 13 elements such as Al ang Ga. Among them, a complex including Zr, Al or Ti (such as ethyl orthotitanate) is excellent and preferable.

When the composition used for forming a releif forming layer includes a crosslinking accelerator in addition to a crosslinking agent, one kind of the crosslinking accelerator, or two or more kinds thereof in combination, may be used.

The content of the crosslinking accelerator in the composition used for forming a releif forming layer is preferably from 0.01 to 20 parts by weight, and more preferably from 0.05 to 10 parts by weight with respect to 100 pars by weight of the crosslinking agent.

<(D) Photothermal Conversion Agent>

The relief forming layer according to the present invention preferably contains (D) a photothermal conversion agent.

It is considered that the photothermal conversion agent absorbs laser beam and generates heat, thereby promoting thermal decomposition of the components included in the relief forming layer having a crosslinked structure. For this reason, a photothermal conversion agent that absorbs light having a laser wavelength used for engraving is selected preferably.

When a laser (YAG laser, semiconductor laser, fiber laser, surface emitting laser, or the like) emitting infrared light with a wavelength of from 700 nm to 1,300 nm is used as a light source for laser engraving, the relief forming layer in the present invention preferably contains a photothermal conversion agent capable of absorbing light with a wavelength of from 700 nm to 1,300 nm.

As the photothermal conversion agent in the present invention, various kinds of dyes or pigments may be used.

As the dyes that are included in the photothermal conversion agents, commercially available dyes or known dyes described in a document such as “Senryo Binran” (edited by Yuki Gosei Kagaku Kyokai, published in 1970) are usable, for example. Specific examples thereof may include azo dyes, metal complex salt azo dyes, pyrazolone azo dyes, naphthoquinone dyes, anthraquinone dyes, phthalocyanine dyes, carbonium dyes, diimmonium dyes, quinoneimine dyes, methine dyes, cyanine dyes, squarylium dyes, pyrylium salts, and metal thiolate complexes.

As the dyes preferably used in the present invention, the dyes described in the paragraphs [0124] to [0137] in JP-A No. 2008-63554 may be exemplified.

One of the preferable photothermal conversion agents used in the present invention is at least one compound selected from cyanine compounds and phthalocyanine compounds, from the viewpoint of having a high engraving sensitivity. Furthermore, when these photothermal conversion agents are used in a combination (manner) that the thermal decomposition temperature of the photothermal conversion agents is equal or higher than the thermal decomposition temperature of a hydrophilic polymer that is suitably used as the binder polymer, the engraving sensitivity is desirably likely to become still higher.

Of the dyes that are included in the photothermal conversion agents used in the present invention, a dye having a maximum absorption at a wavelength of from 700 nm to 1,300 nm is preferable.

As the dyes preferably used in the present invention, among cyanine dyes such as heptamethine cyanine dyes; oxonol dyes such as pentamethine oxonol dyes; indolium dyes; benzindolium dyes; benzothiazolium dyes; quinolinium dyes; and phthalide compounds or the like that are reacted with a developer, dyes having a maximum absorption wavelength of from 700 nm to 1,300 nm may be exemplified. Optical absorption properties are considerably changed depending on the kind of substituent groups and the position thereof in the molecule, the number of conjugated bonds, the kinds of counter ions, the environment around the colorant molecules, and others.

Commercially available common laser pigments, saturated absorption pigments, near infrared ray absorption pigments are also usable. Examples of the laser pigments may include: “ADS740PP”, “ADS745HT”, “ADS760MP”, “ADS740WS”, “ADS765WS”, “ADS745HO”, “ADS790NH” and “ADS800NH” (trade names, American Dye Source, Inc., Canada); and “NK-3555”, “NK-3509” and “NK-3519” (trade names, manufactured by Hayashibara Biochemical Laboratories, Inc.). Examples of the near infrared ray absorption pigments may include: “ADS775MI”, “ADS775MP”, “ADS775HI”, “ADS775PI”, “ADS775PP”, “ADS780MT”, “ADS780BP”, “ADS793EI”, “ADS798MI”, “ADS798MP, “ADS800AT”, “ADS805PI”, “ADS805PP”, “ADS805PA”, “ADS805PF”, “ADS812MI”, “ADS815EI”, “ADS818HI”, “ADS818HT”, “ADS822MT”, “ADS830AT”, “ADS838MT”, “ADS840MT”, “ADS845BI”, “ADS905AM”, “ADS956BI”, “ADS1040T”, “ADS1040P”, “ADS1045P”, “ADS1050P”, “ADS1060A”, “ADS1065A”, “ADS1065P”, “ADS1100T”, “ADS1120F”, “ADS1120P”, “ADS780WS”, “ADS785WS”, “ADS790WS”, “ADS805WS”, “ADS820WS”, “ADS830WS”, “ADS850WS”, “ADS780HO”, “ADS810CO”, “ADS820HO”, “ADS821NH”, “ADS840NH”, “ADS880MC”, “ADS890MC” and “ADS920MC (trade names, American Dye Source, Inc., Canada); “YKR-2200”, “YKR-2081”, “YKR-2900”, “YKR-2100” and “YKR-3071” (trade names, manufactured by Yamamoto Chemicals Inc.); “SDO-1000B” (trade name, manufactured by Arimoto Chemical Co., Ltd.); and “NK-3508” and “NKX-114” (trade name, manufactured by Hayashibara Biochemical Laboratories, Inc.). Note that, these are not limitative.

As the pigments that are included in the photothermal conversion agents used in the present invention, commercially available pigments and the pigments described in “Color Index (C. I.) Binran”, “Saishin Ganryo Binran” (edited by Nippon Ganryo Gijutsu Kyokai, published in 1977), “Saishin Ganryo Oyo Gijutsu” (published by CMC Publishing Co., Ltd., 1986), and “Insatsu Ink Gijutsu” (published by CMC Publishing Co., Ltd., 1984) are usable.

Regarding the kinds of the pigments, black color pigments, yellow color pigments, orange color pigments, brown color pigments, red color pigments, purple color pigments, blue color pigments, green color pigments, fluorescent pigments, metal power pigments, and polymer bonded pigments may be exemplified. Specifically, insoluble azo pigments, azo lake pigments, condensed azo pigments, chelate azo pigments, phthalocyanine pigments, anthraquinone pigments, perylene or perinone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, carbon black, and the like are usable. Among these pigments, carbon black is preferable.

Any carbon blacks, including those classified in accordance with ASTM and those for various applications (for example, for use in coloring, rubbers, or dry cells), are usable as long as they show stable dispersibility or the like in the composition. Examples of carbon blacks include furnace black, thermal black, channel black, lamp black, and acetylene black, for example. In order to disperse easily the black colorant such as carbon black, color chips or paste may be used, in which the black colorant is preliminary dispersed in nitrocellulose or a binder, if necessary, with a dispersing agent. These chips or paste are easily available in the market.

In the present invention, a variety of carbon blacks from the one having a relatively small specific surface area and a relatively low DBP absorption to the finely pulverized one having a larger specific surface area may be used. Preferable examples of carbon black may include “PRINTEX (registered trademark) U”, “PRINTEX (registered trademark) A”, and “SPEZIALSCHWARZ (registered trademark) 4” (available from Degussa Corp.).

As carbon black applicable to the present invention, a conductive carbon black having a specific surface area of at least 150 m²/g and a DBP number of at least 150 ml/100 g is preferable, from the viewpoint of enhancing engraving sensitivity by conducting efficiently the heat generated by photothermal conversion to the surrounding polymer and the like.

The specific surface area is preferably at least 250 and particularly preferably at least 500 m²/g. The DBP number is preferably at least 200 and particularly preferably at least 250 ml/100 g. The carbon black may be an acidic or basic carbon black. The carbon black is preferably a basic carbon black. A mixture containing a different kind of binders may be also used.

An adequate conductive carbon black that has a specific surface area of up to about 1500 m²/g and a DBP number of up to about 550 ml/100 g is commercially available as “KETJENBLACK (registered trade mark) EC300J” and “KETJENBLACK (registered trade mark) EC600J” (available from Akzo Corp.); “PRINREX (registered trade mark) XE” (available from Degussa Corp.); “BLACK PEARLS (registered trade mark) 2000 (available from Cabot Corp.); and “KETJENBLACK” (manufactured by Lion Corp.), for example.

The content of the photothermal conversion agent in the relief forming layer in the relief printing plate precursor for laser engraving of the present invention is, although the content considerably changes in accordance with the magnitude of the intrinsic molecular extinction coefficient thereof, in the range of preferably from 0.01% to 20% by mass with respect to the total solid content of the relief forming layer, more preferably from 0.05% to 10% by mass, and particularly preferably from 0.1% to 5% by mass.

<(E) Polymerization Initiator>

The relief forming layer according to the present invention preferably contains (E) a polymerization initiator. In particular, when a polymerizable compound having an ethylenic unsaturated bond is used as a crosslinking agent, (E) a polymerization initiator is preferably used.

Polymerization initiators known among the people in the art are usable without any limitation. Specifically, many are described in, for example, Chemical Review, 93, 435 (1993) by Bruce M. Monroe et al.; Journal of Photochemistry and biology A: Chemistry, 73.81 (1993) by R. S. Davidson; “Photoinitiated Polymerization—Theory and Applications”: Rapra Review vol. 9, Report, Papra Technology (1998) by J. P. Faussier; Prog. Polym. Sci., 21, 1 (1996) by M. Tsunooka et al; and the like. Further, a group of compounds that cause oxidative or reductive cleavage of bonds are also known, which are described in Topics in Current Chemistry, 156, 59 (1990) by F. D. Saeva; Topics in Current Chemistry, 168, 1 (1993) by G. G. Maslak; JACS, 112, 6329 (1990) by H. B. Shuster et al.; JACS, 102, 3298 (1980) by I. D. F. Eaton et al.; and others.

As a preferable specific example of the polymerization initiator, a radical polymerization initiator that generates radicals by light and/or heat energies and initiates and promotes polymerization reaction of polymerizable compounds will be described in detail below, but the present invention is in no way limited by the following description.

In the present invention, preferable radical polymerization initiators may include (a) aromatic ketones, (b) onium salt compounds, (c) organic peroxides, (d) thio compounds, (e) hexaaryl biimidazole compounds, (f) keto-oxime ester compounds, (g) borate compounds, (h) azinium compounds, (i) metallocene compounds, (j) active ester compounds, (k) compounds having a carbon to halogen bond, and (l) azo compounds. Specific examples of (a) to (l) are described below, but the present invention is in no way limited by these examples.

In the present invention, from the viewpoint of providing an improved engraving sensitivity and an adequate relief edge form when applied to a relief forming layer of a relief printing plate precursor, the (c) organic peroxides and the (l) azo compounds are preferable, and the (c) organic peroxides are particularly preferable. The (c) organic peroxides used as a polymerization initiator may be compounds included in the above-described (A) peroxides, but are preferably selected from compounds having lower decomposition temperature from the viewpoint of efficiency of formation of a crosslinked structure. Details of such a compound will be described below.

Generally, when hardness is increased so as to improve the relief edge form, engraving sensitivity becomes lowered. However, by using the sulfur-containing multi-functional monomer that is exemplified as a preferable embodiment of the polymerizable compounds and the foregoing preferable polymerization initiator, the edge form may be improved without lowering engraving sensitivity. Presumably, the oxygen atom or nitrogen atom contained in the polymerization initiator interacts with the sulfur atom of the sulfur-containing multi-functional monomer, so that these two components become close to each other in position, whereby the edge form is improved by increasing polymerization degree and hardness. In addition, owing to the low-temperature thermal decomposition property of the sulfur-containing multi-functional monomer, lowering in the sensitivity caused by increasing polymerization degree may be prevented, presumably.

As the (a) aromatic ketones, (b) onium salt compounds, (d) thio compounds, (e) hexaaryl biimidazole compound, (f) keto-oxime ester compounds, (g) borate compounds, (h) azinium compounds, (i) metallocene compounds, (j) active ester compounds, and (k) compounds having a carbon to halogen bond, the compounds described in the paragraphs [0074] to [0118] of JP-A No. 2008-63554 may be preferably used.

As the (c) organic peroxides and (1) azo compounds, the compounds described below are preferable.

(c) Organic Peroxides

The (c) organic peroxides preferably used as the radical polymerization initiator in the present invention may include almost all of organic compounds that have at least one oxygen to oxygen bond in the molecule thereof, and examples thereof may include the organic peroxides described above.

The relief forming layer according to the present invention including a crosslinked structure may be formed by applying and drying a resin composition for forming a relief forming layer, and crosslinking the resulting layer by light exposure or heating. Accordingly, from the viewpoint of effectively forming a crosslinked structure by light exposure or heating, a compound having a relatively low 10-hour half-life temperature is preferably used. Specifically, when the crosslinked structure is formed by heating, a compound having a 10-hour half-life temperature that is equal to or lower than the heating temperature for heat crosslinking, or a 10-hour half-life temperature that is lower than a temperature that is higher, by 5° C., than the heating temperature for heat crosslinking is preferably used.

From such a viewpoint, as an organic peroxide to be used as an initiator, peroxy esters such as 3,3′,4,4′-tetra-(tert-butylperoxycarbonyl)benzophenone, 3,3′,4,4′-tetra-(tert-amylperoxycarbonyl)benzophenone, 3,3′,4,4′-tetra-(tert-hexylperoxycarbonyl)benzophenone, 3,3′,4,4′-tetra-(tert-octylperoxycarbonyl)benzophenone, 3,3′,4,4′-tetra-(cumylperoxycarbonyl)benzophenone, 3,3′,4,4′-tetra-(p-isopropylcumylperoxycarbonyl)benzophenone, and di-tert-butyldiperoxy isophthalate are preferable.

The relationship between a peroxide included in the relief forming layer having a crosslinked structure and an organic peroxide to be used as a polymerization initiator is explained. That is, as the organic peroxide to be used as a polymerization initiator, almost all of which is decomposed in the formation of the crosslinked structure, an organic peroxide having a relatively low 10-hour half-life temperature may be used, and, as the (A) peroxide remaining in the layer having a crosslinked structure, a peroxide having a relatively high 10-hour half-life temperature such as 100° C. or higher may be used.

(1) Azo Compounds

Examples of the (1) azo compounds preferably used as the radical polymerization initiator in the present invention may include: 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyano valeric acid), 2,2′-azobis dimethyl isobutyrate, 2,2′-azobis(2-methylpropione amide oxime), 2,2′-azobis[2-(2-imidazoline-2-il)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azibis(N-butyl-2-methylpropionamide), 2,2′-azobis(N-cyclohexyl-2-methylpropione amide), 2,2′-azobis[N-(2-propenyl)-2-methylpropionamide], and 2,2′-azobis(2,4,4-trimethylpentane).

The polymerization initiator in the present invention may be used as one kind solely or two or more kinds in combination.

The polymerization initiator may be added in an amount of preferably from 0.01% to 10% by mass and more preferably from 0.1% to 3% by mass with respect to the total solid content of the resin composition for a relief forming layer.

<Other Additives>

The resin composition for a relief forming layer according to the present invention preferably contains a plasticizer. The plasticizer has an action of softening a film formed from the resin composition, and the plasticizer is required to have an adequate compatibility with the binder polymer.

Examples of the plasticizer may include preferably dioctylphthalate, didodecylphthalate, polyethylene glycols, and polypropylene glycols (mono-ol type or di-ol type), and polypropylene glycols (mono-ol type or di-ol type) are preferably used.

In order to improve engraving sensitivity, nitrocellulose or a highly heat-conductive material is preferably added as additives to the resin composition for a relief forming layer according to the present invention. Nitrocellulose generates heat by itself upon laser engraving because nitrocellulose is a self-reacting compound, and it assists thermal decomposition of the binder polymer such as hydrophilic polymers coexisting therein. Thereby, engraving sensitivity is considered to be enhanced.

The highly heat-conductive material is added so as to assist heat conduction. As the heat-conductive material, inorganic compounds such as metal particles and organic compounds such as conductive polymers may be exemplified. As the metal particles, gold fine particles, silver fine particles, and copper fine particles may be exemplified, which have a particle diameter in the order of from micrometers to several nanometers. As the conductive polymers, conjugated polymers are particularly preferable, and specifically polyaniline and polythiophene may be exemplified.

<Metal Compound>

The resin composition for a relief forming layer according to the present invention may contain, as an additive for improving the engraving sensitivity, a metal compound containing a metal selected from the group consisting of metals in Group 1 to Group 15 in the periodic table.

The “metal” in the invention indicates one classified as a metal in the periodic table. Specifically, the metal is classified as a metal in the periodic table described in D. F. Shriver, P. W. Atkins, Inorganic Chemistry 3rd Ed., OXFORD University Press, 1999, P. 283. Examples thereof include alkali metals such as sodium and potassium, alkaline-earth metals such as magnesium and calcium, transition metals such as titanium, vanadium, molybdenum, manganese, iron, cobalt, nickel, copper and zinc, and typical metals such as aluminum, gallium, tin, lead and bismuth.

As the metal compound in the present invention, any compound that contains metal selected from the group consisting of metals in Group 1 to Group 15 in the periodic table is usable, but elemental metal or alloys are not included. Specific examples of the metal compound include metal salts and metal complexes.

Hereinafter, a metal compound that is preferably used in the present invention will be described specifically.

The metal compound in the present invention contains preferably at least one metal selected from the group consisting of metals in Group 1, Group 2, Group 4, Group 12, Group 13, Group 14, and Group 15 in the periodic table from the viewpoint of engraving sensitivity.

Particularly, from the viewpoints of the engraving sensitivity and the rinsing property of the engraving scraps, a metal compound that contains at least one metal selected from the group consisting of Na, K, Ca, Mg, Ti, Zr, Al, Zn, Sn, and Bi is preferable.

In the present invention, there is not any particular limitation on the anionic portion of the metal compound, and the anionic portion may be selected arbitrarily in accordance with purposes. However, from the viewpoint of thermal stability, the metal compound is preferably at least one selected from the group consisting of oxides, sulfides, halides, carbonates, carboxylates, sulfonates, phosphates, nitrates, sulfates, alkoxides, hydroxides, and acetylacetonate complexes that may have a substituent group.

Particularly, at least one metal compound, which is selected from the group consisting of halides, carboxylates, nitrates, sulfates, hydroxides, and acetylacetonate complexes that may have a substituent group, is preferable.

More specifically, in the present invention, preferably, the metal compound contains at least one metal selected from the group consisting of metals in Group 1, Group 2, Group 4, Group 12, Group 13, Group 14, and Group 15 in the periodic table, and the metal compound is an oxide, sulfide, halide, carbonate, carboxylate, sulfonate, phosphate, nitrate, sulfate, alkoxide, hydroxide, or acetylacetonate complex of the at least one metal, wherein the acetylacetonate complex may have a substituent group.

Particularly preferably, the metal compound contains at least one metal selected from the group consisting of Na, K, Ca, Mg, Ti, Zr, Al, Zn, Sn, and Bi, and the metal compound is an oxide, sulfide, halide, carbonate, carboxylate, sulfonate, phosphate, nitrate, sulfate, alkoxide, hydroxide, or acetylacetonate complex of the at least one metal, wherein the acetylacetonate complex may have a substituent group.

Alternatively, a metal compound that contains at least one metal selected from the group consisting of metals in Group 1, Group 2, Group 4, Group 12, Group 13, Group 14, and Group 15 of the periodic table and is a halide, carboxylate, nitrate, sulfate, hydroxide, or acetylacetonate complex of the at least one metal, wherein the acetylacetonate complex may have a substituent group, is also preferable.

Among these, a metal compound that contains at least one metal selected from the group consisting of Na, K, Ca, Mg, Ti, Zr, Al, Zn, Sn, and Bi and is a halide, carboxylate, nitrate, sulfate, hydroxide, or acetylacetonate complex of the at least one metal, wherein the acetylacetonate complex may have a substituent group, is particularly preferable.

Examples of a preferable combination of the metal and anionic portion of the metal compound in the present invention are described below.

Na: alkoxide, carboxylate, or acetylacetonate complex that may have a substituent group;

K: alkoxide, carboxylate, or acetylacetonate complex that may have a substituent group;

Ca: oxide, halide, carboxylate, nitrate, or acetylacetonate complex that may have a substituent group;

Mg: oxide, halide, carboxylate, nitrate, or acetylacetonate complex that may have a substituent group;

Ti: alkoxide or acetylacetonate complex that may have a substituent group;

Zr: alkoxide or acetylacetonate complex that may have a substituent group;

Al: chloride, alkoxide, hydroxide, carboxylate, or acetylacetonate complex that may have a substituent group;

Zn: oxide, halide, carboxylate, or acetylacetonate complex that may have a substituent group;

Sn: halide, carboxylate, or acetylacetonate complex that may have a substituent group; and

Bi: halide, carboxylate, or acetylacetonate complex that may have a substituent group.

More specific examples of the metal compound in the present invention may include: sodium methoxide, sodium acetate, sodium 2-ethylhexanoate, (2,4-pentanedionato) sodium, potassium butoxide, potassium acetate, potassium 2-ethylhexanoate, (2,4-pentanedionato) potassium, calcium fluoride, calcium chloride, calcium bromide, calcium iodide, calcium oxide, calcium sulfide, calcium acetate, calcium 2-ethylhexanoate, calcium phosphate, calcium nitrate, calcium sulfate, calcium ethoxide, bis(2,4-pentanedionato) calcium, magnesium fluoride, magnesium chloride, magnesium bromide, magnesium iodide, magnesium oxide, magnesium sulfide, magnesium acetate, magnesium 2-ethylhexanoate, magnesium phosphate, magnesium nitrate, magnesium sulfate, magnesium ethoxide, bis(2,4-pentanedionato) magnesium, titanium ethoxide, bis(2,4-pentanedionato) titanium oxide, zirconium ethoxide, tetrakis(2,4-pentanedionato) zirconium, vanadium chloride, manganese oxide, bis(2,4-pentanedionato) manganese, iron chloride, tris(2,4-pentanedionato) iron, iron bromide, ruthenium chloride, cobalt chloride, rhodium chloride, iridium chloride, nickel chloride, bis(2,4-pentanedionato) nickel, palladium chloride, palladium acetate, bis(2,4-pentanedionato) palladium, platinum chloride, copper chloride, copper oxide, copper sulfate, bis(2,4-pentanedionato) copper, silver chloride, aluminum isopropoxide, bis(acetato)hydroxy aluminum, bis(2-ethylhexanoato)hydroxy aluminum, dihydroxy aluminum stearate, hydroxy aluminum bis(stearate), aluminum tris(stearate), tris(2,4-pentanedionato)aluminum, zinc chloride, zinc nitrate, zinc acetate, zinc benzoate, zinc oxide, zinc sulfide, bis(2,4-pentanedionato) zinc, zinc 2-ethylhexanoate, tin chloride, tin 2-ethylhexanoate, bis(2,4-pentanedionato) tin dichloride, lead chloride, bismuth 2-ethylhexanoate, and bismuth nitrate.

The content of the metal compound in the resin composition for a relief forming layer according to the present invention is, from the viewpoint of both of engraving sensitivity and film forming property, preferably from 0.01% to 50% by mass, more preferably from 0.1% to 40% by mass, and particularly preferably from 0.1% to 20% by mass, with respect to the (B) binder polymer.

Further, by using a co-sensitizer, the sensitivity at which the resin composition is photo-cured may be still more enhanced.

Still further, a small amount of a heat-polymerization inhibitor is desirably added so as to prevent unnecessary heat-polymerization of the polymerizable compounds during production or storage of the composition.

Colorants such as dyes or pigments may be added for the purpose of coloring the relief forming layer. Owing to this, characteristics such as visibility of image portions or adaptability for a tester that measures image density may be improved.

Still further, known additives such as fillers may be added for the purpose of improving the properties of the formed relief forming layer having a crosslinked structure.

[Relief Printing Plate Precursor for Laser Engraving]

The relief printing plate precursor for laser engraving of the present invention has a relief forming layer in which a crosslinked structure has been formed by light exposure or heating of a layer of the resin composition for a relief forming layer. The relief forming layer is preferably formed on a support.

In the relief printing plate precursor for laser engraving of the present invention, a relief forming layer having a crosslinked structure formed by light or heat is preferably provided on a support. A “relief printing plate” may be produced by laser engraving the printing plate precursor.

The relief printing plate precursor for laser engraving may have, optionally, an adhesive layer between the support and the relief forming layer, and further may have a slip coating layer or a protective film on the relief forming layer.

<Relief Forming Layer>

The relief forming layer included in the relief printing plate precursor for laser engraving of the present invention includes a crosslinked structure formed by curing a layer of a resin composition for a relief forming layer, which includes polymerizable components such as a polymerizable compound and a polymerization initiator, by at least light exposure or heating. The relief forming layer further includes (A) a peroxide.

A preferable embodiment of preparing a relief printing plate from the relief printing plate precursor of the present invention includes forming a relief layer by laser engraving a relief forming layer including a crosslinked structure to obtain a relief printing plate. Since the relief forming layer according to the present invention includes a crosslinked structure, the resulting relief layer can be prevented from being abraded upon printing, and a relief printing plate having a relief layer with sharp patterns is obtainable after laser engraving.

The fact that a crosslinked structure is formed in the relief forming layer may be confirmed by the phenomenon that the relief forming layer becomes insoluble in the coating solvent.

Note that, the relief forming layer may be obtained by molding a resin composition for forming a relief forming layer into a sheet or sleeve shape, and then forming a crosslinked structure by light exposure or heating.

The relief forming layer is usually formed on a support as described below. However, the relief forming layer may be directly formed or placed and fixed on a surface of a member such as a cylinder in a plate-making or printing apparatus.

Hereinafter, an embodiment in which the relief forming layer is formed in a sheet shape is mainly explained.

<Support>

A support usable for a relief printing plate precursor for laser engraving is described.

The material used for the support of a relief printing plate precursor for laser engraving is not particularly limited, but a material having a high dimensional stability is preferably used. Examples of the material may include: metal such as steel, stainless steel or aluminum; plastic resin such as polyester (PET, PBT or PAN, for example) or polyvinylchloride; synthetic rubber such as styrene-butadiene rubber; and a plastic resin (epoxy resins, phenol resins, or the like) reinforced with glass fibers. As the support, a PET (polyethylene terephthalate) film or a steel substrate is preferably used. The shape of the support is determined considering whether the relief forming layer is formed in a sheet shape or in a sleeve shape. A preferable support for a sleeve shape relief forming layer will be described in detail below.

<Adhesive Layer>

Between the relief forming layer and the support, an adhesive layer may be formed in order to increase the adhesion force between these two layers.

Any material is usable for the adhesive layer as long as the material increases the adhesion force after the relief forming layer is crosslinked. Preferably, the adhesion force is also high even before the relief forming layer is crosslinked. Here, the adhesion force means both ones between the support and the adhesive layer and between the adhesive layer and the relief forming layer.

The adhesion force between the support and the adhesive layer is preferably at least 1.0 N/cm in terms of a peeling force per 1 cm width of a test sample or the layers cannot be peeled off and more preferably at least 3.0 N/cm or the layers cannot be peeled off, when the adhesive layer and the relief forming layer are peeled off from a laminate composed of a support, an adhesive layer and a relief forming layer at a speed of 400 mm/minute.

The adhesion force between the adhesive layer and the relief forming layer is preferably at least 1.0 N/cm in terms of a peeling force per 1 cm width of a test sample or the adhesive layer cannot be peeled off and more preferably at least 3.0 N/cm or the adhesive layer cannot be peeled off, when the adhesive layer is peeled off from a laminate composed of an adhesive layer and a relief forming layer at a speed of 400 mm/minute.

As the material (adhesive) usable for the adhesive layer, a material described in “Handbook of Adhesives” edited by I. Skeist, 2nd edition (1977) is usable.

<Protective Film and Slip Coating Layer>

The relief forming layer becomes a portion (relief layer) in which a relief is formed after laser engraving, and the surface of the relief layer serves as an ink receiving portion. The relief forming layer after being crosslinked is reinforced by crosslinking, so that scars or dents that bring about adverse effects on printing are hardly developed on the surface of the relief forming layer. However, the relief forming layer before being crosslinked lacks strength in many cases, so that scars and dents are easily developed on the surface thereof. Considering this, for the purpose of preventing scars and dents from being developed on the surface of the relief forming layer, a protective film may be applied to the surface of the relief forming layer. Such a layer is formed after the film drying step.

The protective film does not effectively prevent scars and dents when it is too thin, on the other hand, when too thick, handling becomes difficult and the cost also becomes high. Therefore, the thickness of the protective film is preferably from 25 μm to 500 μm and more preferably from 50 μm to 200 μm.

As the protective film, known materials for use in protective films of printing plates may be used, which include a polyester film such as PET (polyethylene terephthalate) or a polyolefin film such as PE (polyethylene) or PP (polypropylene), for example. The surface of the film may be plane or may be matted.

When the protective film is applied onto the relief forming layer, the protective film is required to be peelable.

When the protective film is unpeelable or, to the contrary, difficult to adhere to the relief forming layer, a slip coating layer may be formed between these two layers.

A material used for the slip coating layer preferably contains, as a primary ingredient, a water-soluble or dispersible, less adhesive resin such as polyvinylalcohol, polyvinylacetate, partially saponified polyvinylalcohol, hydroxyalkylcellulose, alkylcellulose, or polyamide resin. Among these, considering adhesiveness, a partially saponified polyvinylalcohol having a saponification degree of from 60 mol % to 99 mol % and hydroxyalkyl cellulose and alkylcellulose with an alkyl group having from 1 to 5 carbon atoms are particularly preferably used.

When the protective film is peeled off from a laminate composed of a relief forming layer (and a slip coating layer) and a protective film at a speed of 200 mm/minute, the peeling force is preferably from 5 mN/cm to 200 mN/cm per 1 cm and more preferably from 10 mN/cm to 150 mN/cm. When 5 mN/cm or more, the laminate can be handled while the protective film is kept unpeeled. At a peeling force of 200 mN/cm or less, the protective film may be peeled off without any difficulty.

—Method of Preparing Relief Printing Plate Precursor for Laser Engraving—

Next, a method of preparing a relief printing plate precursor for laser engraving is described.

There is not any particular limitation on the preparation of the relief forming layer in the relief printing plate precursor for laser engraving. However, the relief forming layer is preferably formed by a method comprising: (1) forming a layer of a resin composition comprising a peroxide, a binder polymer, and a crosslinking agent; (2) drying the layer of the resin composition by heating; and (3) forming a crosslinked structure in the dried layer of the resin composition by at least light exposure or heating.

### <Step (1): Forming a Layer of a Resin Composition Comprising a Peroxide, a Binder Polymer, and a Crosslinking Agent>

As the step (1), there may be mentioned a method in which a coating liquid composition for forming a relief forming layer (a resin composition for forming a relief forming layer) is prepared, and melt extruded onto a support after solvent is removed from the resin composition. In another method, the resin composition for forming a relief forming layer may be cast on a support, which is then dried in an oven so as to remove solvent from the resin composition.

After that, if necessary, a protective film may be applied onto the relief forming layer by lamination. Lamination may be carried out by press bonding the protective film and the relief forming layer by a heated calendar roll or the like, or by allowing the protective film to adhere firmly onto the relief forming layer that has a small amount of solvent impregnated in the surface thereof.

When the protective film is used, a method in which the relief forming layer is layered on the protective film at first, then the support is laminated thereon may be employed.

When the adhesive layer is applied, a support having an adhesive layer coated thereon may be used. When the slip coating layer is applied, a protective film having a slip coating layer coated thereon may be used.

The resin composition for forming a relief forming layer may be produced by dissolving or dispersing the peroxide, the binder polymer and optional components including the photothermal conversion agent and the plasticizer in an appropriate solvent, and then dissolving the crosslinking agent therein.

<Step (2): Drying the Layer of the Resin Composition>

Thereafter, the layer of the resin composition is dried. Almost all of the solvent is required to be removed in the process of producing the relief printing plate precursor, and thus low molecular volatile alcohols (for example, methanol, ethanol, n-propanol, isopropanol, or propyleneglycol monomethylether) are used as the solvent, and the total addition amount of the solvent is suppressed preferably as small as possible. In the drying step, in order to promote drying, heating may be carried out. The addition amount of the solvent may be suppressed by keeping the preparation system at high temperature, but the polymerizable compound become easy to polymerize when the temperature becomes too high. Therefore, after the polymerizable compound and/or the polymerization initiator are added, the preparation temperature of the resin composition is kept to be preferably from 30° C. to 80° C.

<Step (3): Forming a Crosslinked Structure in the Dried Layer of the Resin Composition by at Least Light Exposure or Heating>

In the present invention, the relief printing plate precursor for laser engraving may be in the state in which the relief forming layer is crosslinked. When the relief forming layer is prepared by crosslinking a layer of a resin composition for forming a relief forming layer, a step of crosslinking a dried layer of the resin composition by irradiation of active light and/or heating is preferably carried out.

The meaning of forming a “crosslinked structure” in the present invention includes a crosslinking reaction through which binder polymers are linked together and also includes a curing reaction of components in a resin composition for a relief forming layer caused by a reaction among crosslinking agents or a reaction between binder polymer and crosslinking agent.

As described above, in step (3), an uncrosslinked layer of a resin composition (relief forming layer precursor layer) is crosslinked by irradiation of active light and/or heating.

In step (3), when a process of crosslinking by light and a process of crosslinking by heat are used in combination, these processes may be performed simultaneously or separately.

Step (3) is the one in which a relief forming layer of a relief printing plate precursor for laser engraving is crosslinked by at least light or heat.

The relief forming layer contains a crosslinking agent, and optionally a photothermal conversion agent, a polymerization initiator and the like, in addition to a peroxide and a binder polymer. Step (3) is the one in which a crosslinked structure is formed by a crosslinking agent.

When a polymerizable compound having an ethylenic unsaturated bond is used as a crosslinking agent, a polymerization initiator is preferably used. The polymerization initiator is preferably a radical generating agent. The radical generating agent is roughly classified into a photo-polymerization initiator and a heat-polymerization initiator depending on whether radical generation is initiated by light or heat.

When the resin composition for a relief forming layer contains the photo-polymerization initiator, active light that serves as a trigger for the photo-polymerization initiator is irradiated on the relief forming layer so as to crosslink the relief forming layer (a process of crosslinking by light).

Active light is irradiated usually on the entire face of the relief forming layer. Examples of active light may include visible light, UV-light, and electron beam, but UV-light is most popular. When the side of the relief forming layer facing to the support is regarded as the rear face thereof, it is enough that active light is irradiated only on the front face thereof, but it is preferable that active light is also irradiated on the rear face when the support is a transparent film that transmits the active light. When a protective film is put on the front face, the front face may be irradiated through the protective film or after the protective film is removed. In the presence of oxygen, polymerization is possibly inhibited, so that active light may be irradiated after the relief forming layer is covered with a polyvinyl chloride sheet and evacuated.

When the resin composition for a relief forming layer contains the heat-polymerization initiator (the photo-polymerization initiator described above may also serve as the heat-polymerization initiator), the relief forming layer may be crosslinked by heating the relief printing plate precursor including the relief forming layer precursor layer (a process of crosslinking by heat). As a heating method, a method of heating the printing plate precursor in a hot-air oven or a near infrared oven for a predetermined time and a method of contacting with a heated roll for a predetermined time may be used.

When step (3) is the process of crosslinking by light, an apparatus irradiating active light is relatively expensive, but the printing plate precursor is hardly exposed to high temperature, so that the printing plate precursor has practically no limitations on the raw materials thereof.

When step (3) is the process of crosslinking by heat, an advantage of not requiring an extra expensive apparatus is expected, but the printing plate precursor is exposed to high temperature. The raw materials used herein are required to be carefully selected by considering that a thermoplastic polymer that becomes soft at high temperature may be deformed during heating, and the peroxide included in the resin composition may decompose by heat to lower the sensitivity improving effect.

Upon crosslinking by heat, a heat-polymerization initiator may be added. As the heat-polymerization initiator, commercial heat-polymerization initiators for use in free radical polymerization may be used. Examples of the heat-polymerization initiators may include a peroxide having relatively low decomposition temperature, and a compound having a hydroperoxide or azo group. A typical vulcanizing agent may be used for crosslinking A heat-crosslinkable (heat-curable) resin, for example an epoxy resin, may be added to the layer as a crosslinkable component, thereby enabling heat-crosslinking.

As a method of forming a crosslinked structure in the relief forming layer in step (3), the process of crosslinking by heat is preferable because the layer of a resin composition for a relief forming layer is curable (crosslinkable) uniformly from the surface to inside.

Since the relief forming layer includes a crosslinked structure, the following advantages are expected: a first one is that the relief formed after laser engraving becomes sharp; and a second one is that adhesiveness of scraps produced by laser engraving is suppressed. By using a relief forming layer including a crosslinked structure, undesirable phenomena which tend to occur in a relief forming layer not including a crosslinked structure may be suppressed. That is, the phenomenon that when a relief forming layer is subjected to laser engraving, unintended portions are easy to melt and deform by remaining heat that is conducted to the peripheries of a laser irradiated portion, thereby not providing a sharp relief layer in some cases, and the phenomenon that due to liquid low molecular weight components having strong adhesiveness, the engraving scraps produced when the relief forming layer is engraved have strong adhesiveness, may be suppressed.

Embodiments in which a relief forming layer is formed in a sleeve shape are explained below. Any known methods for molding a resin composition may be employed when the relief forming layer is formed in a sleeve shape. Examples thereof include: a casting method; a method including extruding a resin from a nozzle or a dice by a machine such as a pump or an extruder and adjusting a thickness thereof by use of a blade or by a calendar processing with rolls. During the molding, heat with a temperature, by which characteristics of a resin composition which forms the relief forming layer are not deteriorated, can be applied. A rolling treatment, an abrading treatment, and/or the like may be further performed if necessary. Also when a relief forming layer is formed in a sleeve shape, the step (3) is carried out to form a crosslinked structure after formation of a layer of a resin composition, which is the same as in the case in which a relief forming layer is formed in a sheet shape.

When the relief forming layer is made into a sleeve shape, the relief forming layer may be formed in a cylindrical shape at the initial stage, or may be formed in a sheet shape at first and then made into a cylindrical shape by fixing on a cylindrical support or a plate cylinder. There is no particular limitation on the fixing method to the cylindrical support, and examples thereof include: fixing by using an adhesive tape having an adhesive layer provided on each of both sides; and fixing via a layer containing an adhesive agent.

Examples of the adhesive tape include: a tape having an adhesive agent layer of an acrylic resin, a methacrylic resin, a styrene thermoplastic elastomer or the like formed on both sides of a film base material such as a polyester film or a polyolefin film; and a tape which has a base material formed of a foamed body of a polyolefin resin such as polyethylene or a polyurethane resin and provided with an adhesive agent layer as described above on both sides thereof and has a cushioning property. A commercially available tape with adhesive on both sides or a cushion tape having adhesive agent layers on both sides may be appropriately used as well.

The adhesive agent layer used in the case where a support and the relief forming layer are fixed via the adhesive agent layer can be formed using any known adhesive agents. Examples of an adhesive agent which can be used for the fixing of the relief forming layer to the cylindrical support include a rubber adhesive agent such as a styrene butadiene rubber (SBR), a chloroprene rubber or a nitrile rubber, and an adhesive agent which is hardened by moisture in air such as a silicone resin or a polyurethane resin having a silyl group.

When the relief forming layer is made into a cylindrical shape, the relief forming layer may be molded into a cylindrical shape by a known method at first and then fixed on a cylindrical support, or may be directly molded on a cylindrical support by extrusion molding or the like so as to be a sleeve shape. The former method is preferably used in view of the productivity. When the relief forming layer is made into a sleeve shape, the thus-formed sleeve-shaped relief forming layer may be crosslinked and hardened after being fixed onto a cylindrical support if necessary, and a rolling treatment, an abrading treatment or the like can be further carried out if desired.

Examples of the cylindrical support used in making the relief forming layer into a sleeve shape include: a metal sleeve formed of a metal such as nickel, stainless steel, iron or aluminum; a plastic sleeve formed by molding a resin; a sleeve formed of a fiber reinforced plastics (FRP sleeve) having a glass fiber, a carbon fiber, an aramid fiber or the like as a reinforcing fiber; and a sleeve formed of a polymer film and having a shape maintained by compressed air.

The thickness of the cylindrical support may be arbitrarily selected depending upon the object, and the thickness can be typically sufficient as long as it is 0.1 mm or more and as long as the cylindrical support is not destructed by a pressure applied thereto when it is subjected to printing. In the case that the cylindrical support is a metal sleeve or a hard plastic sleeve, those having a thickness of 5 mm or more may be used as well, and it is also possible to use a cylindrical support having a solid body fixed by a rotation axis.

In view of an effective fixation of a stretchable relief forming layer to the cylindrical support, the cylindrical support preferably has such characteristics that an inner diameter of the cylindrical support can expand by a compressed air pressure of about 6 bars and that it returns to have its initial inner diameter after the compressed air pressure is released. A support having such a structure (namely, a structure with a diameter which can be easily adjusted by compressed air or the like) is preferable since a stress can be applied to the relief forming layer having a sleeve shape from inside thereof, a tightly rolling characteristic of the relief forming layer can work and, the relief layer can be stably fixed on a cylindrical support or a plate cylinder even when a stress is applied thereto when it is subjected to printing.

The thickness of the relief forming layer in the relief printing plate precursor for laser engraving is preferably from 0.05 mm to 10 mm, more preferably from 0.05 mm to 7 mm, and particularly preferably from 0.05 mm to 3 mm, from the viewpoint of satisfying various adaptabilities for flexo printing such as abrasion resistance or ink transferring performance.

The shore A hardness of the relief forming layer in the relief printing plate is preferably from 50° to 90°.

When the shore A hardness is 50° or more, fine halftone dots formed by engraving hardly fall down and collapse even though they receive a strong printing pressure from a relief printing machine, so that printing may be performed adequately. On the other hand, when the shore A hardness of the relief forming layer is 90° or less, thin or faded printing may be prevented at solid portions even in the flexo printing with a kiss-touch printing pressure.

The shore A hardness described herein is evaluated with a durometer (spring type rubber hardness tester) as follows: a depressor (called a stylus or indenter) is pushed onto the surface of an object to be measured so as to deform it; and then the amount of deformation (pushed depth) is measured and numerically quantified.

The fact that the formed relief forming layer includes a crosslinked structure may be confirmed in the above-described manner. The amount of the (A) peroxide included in the relief forming layer having a crosslinked structure may be confirmed in the manner which is described in the Examples described below.

[Relief Printing Plate and Production Thereof]

The method of producing a relief printing plate of the present invention includes (4) forming a relief layer by laser engraving a relief forming layer having a crosslinked structure in the relief printing plate precursor for laser engraving of the present invention, which is produced through the steps (1) to (3). By the method of producing a relief printing plate of the present invention, a relief printing plate of the present invention, which has a relief layer preferably on a support, may be produced.

<Step (4)>

In the method of producing a relief printing plate of the invention, the relief forming layer having a crosslinked structure in the obtained relief printing plate precursor of the invention after the step (3) is laser engraved to form a relief layer. By the method of producing a relief printing plate of the invention, a relief printing plate including a relief layer of the invention may be produced.

In the method of producing a relief printing plate of the present invention, after step (4), if necessary, the following steps (5) to (7) may be included.

Step (5): a step of rinsing the surface of a relief layer after engraving, that is the engraved surface, with water or a liquid containing water as a primary ingredient (rinsing step).

Step (6): a step of drying the engraved relief layer (drying step).

Step (7): a step of further crosslinking the relief layer by applying energy to the relief layer after engraving (post crosslinking step).

Step (3) is a step of forming a relief layer by laser engraving a relief forming layer that includes a crosslinked structure formed through steps (1) to (3), and includes a peroxide. Specifically, a relief layer is formed by engraving with a laser beam that corresponds to an image to be formed and is irradiated on a crosslinked relief forming layer. Preferably, there may be mentioned a process in which scanning irradiation is carried out with respect to the relief forming layer by controlling a laser head by a computer based on digital data of the image to be formed.

In step (4), an infrared laser is preferably used. When the infrared laser is irradiated, the molecules contained in the relief forming layer cause molecular vibration, and heat is generated. When a high power laser such as a carbon dioxide gas laser or a YAG laser is used as the infrared laser, a large amount of heat is generated at a laser irradiated portion and the molecules contained in the relief forming layer are broken or ionized and selectively removed, that is, engraving is done. The advantage of laser engraving is a three-dimensional structural control because engraving depth can be selected arbitrarily. For example, a portion where fine halftone dots are printed may be engraved shallowly or with shoulders, so that the relief is prevented from falling down by an action of printing pressure; and a grooved portion where fine outline characters are printed may be engraved deeply, so that the groove is not easily filled with ink and that outline characters may be prevented from being collapsed.

In particular, when an infrared laser that corresponds to the absorption wavelength of a photothermal conversion agent included in the relief forming layer is used for engraving, the relief layer may be removed selectively with a still higher sensitivity and a relief layer with sharp images is obtained. As the infrared laser used in step (4), from the viewpoint of productivity, cost-effectiveness and the like, a carbon dioxide gas laser or a semiconductor laser is preferable. In particular, a semiconductor infrared laser with a fiber is preferably used.

When engraving scraps are stuck to the engraved face, step (5) of removing the engraving scraps may be carried out, in which the engraved face is rinsed with water or a liquid containing water as a primary ingredient. Examples of the method of rinsing may include: a method of washing with tap water; a method of spraying high pressure water; and a method of brushing the engraved face in the presence of water with a batch-wise or continuous brushing machine that is known as a developing machine for a relief printing plate of photosensitive resin. When the slime of engraving scraps is not removed, a rinsing liquid with a surfactant added thereto may be used.

When step (5) of rinsing the engraved face is performed, step (6) of drying the engraved relief forming layer to vaporize the rinsing liquid may be preferably additionally performed.

Further, if necessary, step (7) of further crosslinking the relief layer may be additionally performed. By step (7) of additional crosslinking, the relief formed by engraving may become still stronger.

In this way, the relief printing plate of the present invention having a relief layer on a support is obtained.

The shore A hardness of the relief layer after the additional crosslinking step (7) is performed is preferably from 50° to 90°.

The relief printing plate produced in accordance with the method of the present invention allows printing with an oil-based ink or a UV ink using a relief printing machine, and also allows printing with a UV ink using a flexo printing machine.

According to the present invention, for example, the following embodiments <1> to <14> are provided.

<1> A relief printing plate precursor for laser engraving, comprising a relief forming layer that comprises a peroxide and a binder polymer, and comprises a crosslinked structure.

<2> The relief printing plate precursor of <1>, wherein the content of the peroxide is from 0.01% to 20% by mass based on the total mass of the relief forming layer.

<3> The relief printing plate precursor of <1> or <2>, wherein the peroxide includes at least one organic peroxide.

<4> The relief printing plate precursor of any one of <1> to <3>, wherein the peroxide includes at least one selected from the group consisting of a ketone peroxide, a diacyl peroxide, a dialkyl peroxide, a hydroperoxide, a peroxy ketal, a peroxy ester, and a peroxy dicarbonate.

<5> The relief printing plate precursor of any one of <1> to <4>, wherein the 10-hour half-life temperature of the peroxide is 100° C. or more.

<6> The relief printing plate precursor of any one of <1> to <5>, wherein the crosslinked structure of the relief forming layer is formed by at least light exposure or heating.

<7> The relief printing plate precursor of <6>, wherein the crosslinked structure of the relief forming layer is formed by heating.

<8> The relief printing plate precursor of <7>, wherein the 10-hour half-life temperature of the peroxide is higher, by 5° C. or more, than the heating temperature for forming the crosslinked structure of the relief forming layer.

<9> The relief printing plate precursor of any one of <1> to <8>, wherein the thickness of the relief forming layer is from 0.05 mm to 10 mm.

<10> The relief printing plate precursor of any one of <1>to <9>, wherein the shore A hardness of the relief forming layer is from 50° to 90°.

<11> A method of producing the relief printing plate precursor of any one of <1> to <10>, the method comprising:

forming a layer of a resin composition comprising a peroxide, a binder polymer, a polymerizable compound having an ethylenic unsaturated bond, and a polymerization initiator;

drying the layer of the resin composition; and

forming a crosslinked structure in the dried layer of the resin composition by at least light exposure or heating.

<12> A relief printing plate precursor for laser engraving produced by the method of <11>.

<13> A method of producing a relief printing plate, comprising forming a relief layer by laser engraving the relief forming layer in the relief printing plate precursor of <12>.

<14> A relief printing plate produced by the method of <13>.

In the relief printing plate precursor of the present invention, the relief forming layer includes a crosslinked structure and thus the mechanical strength of the relief forming layer is excellent, and further a peroxide is included in the relief forming layer, so that the engraving sensitivity to a laser is improved and the time for forming a relief layer may be shortened.

Since the laser engraving sensitivity of the relief forming layer in the relief printing plate precursor for laser engraving of the present invention is high, a high speed laser engraving may be carried out, so that the engraving time may also be shortened. Such a relief printing plate precursor of the present invention may be widely used for applications of a relief printing plate precursor which is subjected to laser engraving without limitation. For example, it may be used not only for a relief forming layer of a printing plate precursor which is subjected to laser engraving to form a convex relief but also for various printing plates in which an image is formed by laser engraving, such as an intaglio printing plate, a stencil printing plate, and a stamp.

Therefore, according to the present invention, a relief printing plate precursor for laser engraving which maintains sufficient mechanical strength of a relief forming layer, has high engraving sensitivity, and enables direct plate-making by laser engraving, as well as an easy method of producing the same, may be provided.

Further, according to the present invention, a relief printing plate including a relief layer having excellent mechanical strength, which is obtained from the relief printing plate precursor for laser engraving of the present invention, and a method of producing the same may be provided.

### EXAMPLES

The present invention will be further described in detail with reference to the following examples, but it should be construed that the present invention is in no way limited by those examples.

### Example 1

### Preparation of Resin Composition for Relief Forming Layer

In a three-necked flask with an stirring blade and a condenser tube, 40 g of DENKA BUTYRAL #3000-2 (trade name, polyvinyl butyral, manufactured by DENKI KAGAKU KOGYO KABUSHIKI KAISHA) as (B) a binder polymer, 0.75 g of KETJENBLACK EC600JD (trade name, manufactured by Lion Corp.) as (D) a photothermal conversion agent, 20 g of diethylene glycol as a plasticizer, and 47 g of ethanol as a solvent were charged, and heated at 70° C. for 2 hours with stirring to dissolve the polymer. Further, as (C) an ethylenic unsaturated compound, BLENMER PDE-200 (trade name, manufactured by NOF Corp.), BLENMER PME-200 (trade name, manufactured by NOF Corp.), and methacrylic acid (manufactured by Wako Pure Chemical Industries, Ltd.) in an amount of 15 g, 13 g, and 5 g respectively; as (E) a polymerization initiator, PERBUTYL Z (trade name, manufactured by NOF Corp.) in an amount of 1.6 g; as (A) a peroxide, PERHEXYNE 25B (trade name, manufactured by NOF Corp.) in an amount of 5.0 g; and as a metal compound, zinc chloride in an amount of 5.0 g were added thereto. The resulting mixture was stirred for 30 minutes to obtain a resin composition solution for forming a relief forming layer.

(Formation of Relief Forming Layer Having Crosslinked Structure)

A spacer (frame) with a predetermined thickness was placed on a PET substrate; the above obtained resin composition solution was cast carefully to an extent that the composition did not flow over the frame; and the composition was dried in an oven at 70° C. for 3 hours to form a relief forming layer precursor layer with a thickness of about 1 mm.

The resulting substrate having a relief forming layer precursor layer formed thereon was heated at 100° C. for 3 hours to heat crosslink the relief forming layer precursor layer to form a crosslinked structure. In this way, a relief printing plate precursor for laser engraving of Example 1 was obtained.

The thickness and shore A hardness of the relief forming layer in the relief printing plate precursor were measured. The results are shown in the following Table 1. The shore A hardness of the relief forming layer was measured in accordance with the measurement method described above. In each example and comparative example described later, the shore A hardness was also measured similarly.

(Preparation of Relief Printing Plate)

For image formation, 2 cm square solid portion of the relief forming layer was engraved using a near infrared laser engraving machine “FD-100” (trade name, manufactured by Tosei Electrobeam Co., Ltd.) equipped with a semiconductor laser having a maximum power of 16 W (laser oscillation wavelength was 840 nm) under the engraving conditions: 15 W of laser power; 100 mm/second of scan speed; and 0.15 mm of pitch interval. In this way, a relief printing plate was produced.

As the relief printing plate precursor to be engraved, a relief printing plate precursor having a relief forming layer aged for less than 1 day at room temperature after heat crosslinking of the relief forming layer (indicated as “1 day” in the following Tables), and a relief printing plate precursor having a relief forming layer aged for 6 months at room temperature after heat crosslinking of the relief forming layer (indicated as “6 months” in the following Tables), both the relief printing plate precursors being produced in the same manner, were used.

(Evaluation of Relief Printing Plate Precursor)

1. Engraving Depth

The engraving depth of the relief layer formed by laser engraving as described above was determined by observing a cross section of the engraved solid portion using a ULTRA-DEPTH COLOR 3D SHAPE MEASUREMENT MICROSCOPE VK9510 (trade name, manufactured by KEYENCE CORP.) and measuring the difference in height between the surface of the relief layer and the engraved portion. The results are shown in the following Tables.

2. (A) Quantitative Determination of (A) Peroxide

0.5 g of the relief forming layer having a crosslinked structure of the obtained relief printing plate precursor was weighed, and dipped in N-methyl-2-pyrrolidone in a glass bottle. Further, as a standard substance, 0.03 g of naphthalene was weighed, and added to the N-methyl-2-pyrrolidone in the glass bottle. These were dipped at room temperature for 1 hour and then put in an ultrasonic cleaner for 2 minutes. The cycle of the 1 hour dipping and the 2 minute ultrasonic cleaner treatment was repeated three times. The resulting liquid was filtered with a 0.01 μm membrane filter, and HPCL (RI detector) was carried out to compare the amounts of the (A) peroxide and naphthalene as a standard substance to quantify the content of the (A) peroxide included in the relief forming layer. The results are shown in the following Tables.

### Examples 2 to 7

Relief printing plate precursors were prepared and evaluated similarly to Example 1, except that DENKA BUTYRAL #3000-2 used as (B) a binder polymer in Example 1 was replaced by GOSENAL T-215 (trade name, manufactured by Nippon Synthetic Chemical Industry Co., Ltd., PVA derivative) in Example 2; polyvinyl acetate (manufactured by Alfa Aesar Corp.) in Example 3; AMILAN CM4000 (trade name, polyamine, manufactured by Toray Industries, Inc.) in Example 4; LEZAMIN ME8105LP (trade name, polyurethane, manufactured by Dainichiseika Color & Chemicals Mfg. Co., Ltd.) in Example 5; TR2000 (trade name, styrene and butadiene thermoplastic elastomer, manufactured by JSR Corp.) in Example 6; and polymethyl methacrylate (synthesized by free-radical polymerization of methyl methacrylate) in Example 7, respectively.

### Comparative Examples 1-7

Relief printing plate precursors were prepared and evaluated similarly to Examples 1-7, except that PERHEXYNE 25B was not added when preparing a resin composition for a relief forming layer.

### Example 8

A relief printing plate precursor was prepared and evaluated similarly to Example 1, except that 10 g of LANDY PL-2000 (trade name, manufactured by MIYOSHI OIL&FAT CO., LTD.), which is a highly decomposable polylactic acid, was added.

### Examples 9-13

Relief printing plate precursors were prepared and evaluated similarly to Example 1, except that PERHEXYNE 25B used in Example 1 was replaced by PERHEXYL D (trade name, manufactured by NOF Corp.) in Example 9; PERHEXA 25B (trade name, manufactured by NOF Corp.) in Example 10; PERCUMYL D (trade name, manufactured by NOF Corp.) in Example 11; PERCUMYL H (trade name, manufactured by NOF Corp.) in Example 12; and PERBUTYL H-69 (trade name, manufactured by NOF Corp.) in Example 13, respectively.

TABLE 1

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 1 | PERHEXYNE | 128.4 | 5 | 1.28 | 75 | Semiconductor | 585 | 585 |
| | 25B | | | | | laser | | |
| Example 2 | PERHEXYNE | 128.4 | 5 | 1.25 | 81 | Semiconductor | 580 | 580 |
| | 25B | | | | | laser | | |
| Example 3 | PERHEXYNE | 128.4 | 5 | 1.29 | 83 | Semiconductor | 550 | 550 |
| | 25B | | | | | laser | | |
| Example 4 | PERHEXYNE | 128.4 | 5 | 1.35 | 76 | Semiconductor | 565 | 565 |
| | 25B | | | | | laser | | |
| Example 5 | PERHEXYNE | 128.4 | 5 | 1.25 | 80 | Semiconductor | 565 | 565 |
| | 25B | | | | | laser | | |
| Example 6 | PERHEXYNE | 128.4 | 5 | 1.32 | 72 | Semiconductor | 550 | 550 |
| | 25B | | | | | laser | | |
| Example 7 | PERHEXYNE | 128.4 | 5 | 1.33 | 78 | Semiconductor | 565 | 565 |
| | 25B | | | | | laser | | |
| Comparative | None | — | — | 1.33 | 80 | Semiconductor | 470 | 470 |
| Example 1 | | | | | | laser | | |
| Comparative | None | — | — | 1.33 | 75 | Semiconductor | 465 | 465 |
| Example 2 | | | | | | laser | | |
| Comparative | None | — | — | 1.28 | 77 | Semiconductor | 435 | 435 |
| Example 3 | | | | | | laser | | |
| Comparative | None | — | — | 1.29 | 81 | Semiconductor | 450 | 450 |
| Example 4 | | | | | | laser | | |
| Comparative | None | — | — | 1.23 | 81 | Semiconductor | 450 | 450 |
| Example 5 | | | | | | laser | | |
| Comparative | None | — | — | 1.28 | 83 | Semiconductor | 435 | 435 |
| Example 6 | | | | | | laser | | |
| Comparative | None | — | — | 1.25 | 76 | Semiconductor | 450 | 450 |
| Example 7 | | | | | | laser | | |
| Example 8 | PERHEXYNE | 128.5 | 5 | 1.29 | 80 | Semiconductor | 595 | 595 |
| | 25B | | | | | laser | | |
| Example 9 | PERHEXYL D | 116.4 | 5 | 1.22 | 75 | Semiconductor | 560 | 560 |
| | | | | | | laser | | |
| Example 10 | PERHEXA | 117.9 | 5 | 1.25 | 72 | Semiconductor | 565 | 565 |
| | 25B | | | | | laser | | |
| Example 11 | PERCUMYL D | 116.4 | 5 | 1.36 | 72 | Semiconductor | 580 | 580 |
| | | | | | | laser | | |
| Example 12 | PERCUMYL H | 157.9 | 5 | 1.32 | 77 | Semiconductor | 550 | 550 |
| | | | | | | laser | | |
| Example 13 | PERBUTYL | 166.5 | 5 | 1.29 | 81 | Semiconductor | 560 | 560 |
| | H-69 | | | | | laser | | |

As is clear from Table 1, in the printing plate precursors of the invention, excellent engraving sensitivity is exhibited compared to those of the Comparative Examples not including a peroxide, and lowering of the sensitivity after aging is suppressed, regardless of the kind of the binder polymer or the peroxide used, or the presence or absence of the additive (polylactic acid).

### Examples 14-16

Relief printing plate precursors were prepared and evaluated similarly to Example 1, except that the amount of PERHEXYNE 25B used as (A) a peroxide in Example 1 was changed to 1.0 g in Example 14; 3.0 g in Example 15; and 10 g in Example 16, respectively.

### Examples 17-18

Relief printing plate precursors were prepared and evaluated similarly to Example 1, except that zinc chloride used in Example 1 was replaced by zinc nitrate hexahydrate (manufactured by Kanto Chemical Co., Inc.) in Example 17, and bis(2,4-pentanedionato) zinc (manufactured by Tokyo Chemical Industry Co., Ltd.) in Example 18, respectively.

### Comparative Examples 8 and 9

Relief printing plate precursors were prepared and evaluated similarly to Examples 17 and 18, except that PERHEXYNE 25B was not added when preparing a resin composition for a relief forming layer.

### Examples 19-20

Relief printing plate precursors were prepared and evaluated similarly to Example 11, except that zinc chloride used in Example 11 was replaced by zinc nitrate hexahydrate (manufactured by Kanto Chemical Co., Inc.) in Example 19, and bis(2,4-pentanedionato) zinc (manufactured by Tokyo Chemical Industry Co., Ltd.) in Example 20, respectively.

### Example 21

A relief printing plate precursor was prepared and evaluated similarly to Example 1, except that BLENMER PDE200 used as (C) a polymerizable compound in Example 1 was replaced by the following monomer M-1 (sulfur-containing multi-functional polymerizable compound).

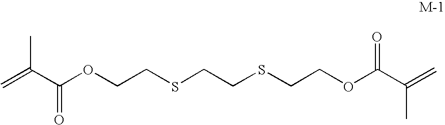

### Example 22

A relief printing plate precursor was prepared and evaluated similarly to Example 11, except that BLENMER PDE200 used as (C) a polymerizable compound in Example 11 was replaced by the above monomer M-1.

### Example 23

A relief printing plate precursor was prepared and evaluated similarly to Example 1, except that carbon black used as (D) a photothermal conversion agent in Example 1 was replaced by ADS820HO (trade name, cyanine compound, manufactured by American Dye Source, Inc.).

### Example 24

A relief printing plate precursor was prepared and evaluated similarly to Example 1, except that carbon black used as (D) a photothermal conversion agent in Example 1 was replaced by D99-009 (trade name, phthalocyanine compound, manufactured by Yamamoto Chemicals Inc.).

### Example 25

A relief printing plate precursor was prepared and evaluated similarly to Example 1, except that PERBUTYL Z used as (E) a polymerization initiator in Example 1 was replaced by V-30 (trade name, azo initiator, manufactured by Wako Pure Chemical Industries, Ltd.).

TABLE 2

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 14 | PERHEXYNE | 128.4 | 1 | 1.35 | 82 | Semiconductor | 565 | 565 |
| | 25B | | | | | laser | | |
| Example 15 | PERHEXYNE | 128.4 | 3 | 1.36 | 83 | Semiconductor | 575 | 575 |
| | 25B | | | | | laser | | |
| Example 16 | PERHEXYNE | 128.4 | 10 | 1.33 | 80 | Semiconductor | 585 | 585 |
| | 25B | | | | | laser | | |
| Example 17 | PERHEXYNE | 128.4 | 5 | 1.25 | 71 | Semiconductor | 580 | 580 |
| | 25B | | | | | laser | | |
| Example 18 | PERHEXYNE | 128.4 | 5 | 1.22 | 75 | Semiconductor | 585 | 585 |
| | 25B | | | | | laser | | |
| Comparative | None | — | — | 1.35 | 82 | Semiconductor | 465 | 465 |
| Example 8 | | | | | | laser | | |
| Comparative | None | — | — | 1.36 | 83 | Semiconductor | 470 | 470 |
| Example 9 | | | | | | laser | | |
| Example 19 | PERCUMYL D | 116.4 | 5 | 1.19 | 78 | Semiconductor | 575 | 575 |
| | | | | | | laser | | |
| Example 20 | PERCUMYL D | 116.4 | 5 | 1.35 | 73 | Semiconductor | 580 | 580 |
| | | | | | | laser | | |
| Example 21 | PERHEXYNE | 128.4 | 5 | 1.19 | 78 | Semiconductor | 600 | 600 |
| | 25B | | | | | laser | | |
| Example 22 | PERCUMYL D | 116.4 | 5 | 1.35 | 73 | Semiconductor | 595 | 595 |
| | | | | | | laser | | |
| Example 23 | PERHEXYNE | 128.4 | 5 | 1.33 | 72 | Semiconductor | 575 | 575 |
| | 25B | | | | | laser | | |
| Example 24 | PERHEXYNE | 128.4 | 5 | 1.24 | 83 | Semiconductor | 580 | 580 |
| | 25B | | | | | laser | | |
| Example 25 | PERHEXYNE | 128.4 | 5 | 1.34 | 77 | Semiconductor | 580 | 580 |
| | 25B | | | | | laser | | |

As is understood from Table 2, in the printing plate precursors of the invention, excellent engraving sensitivity is exhibited compared to those of the Comparative Examples not including a peroxide, and lowering of the sensitivity after aging is suppressed, regardless of the kind or amount of the polymerizable compound, the photothermal conversion agent or the peroxide used, or the kind of the additive. Further, from the comparison between Examples 1 and 11, and Examples 21 and 22, it was observed that when a sulfur-containing multi-functional polymerizable compound was used as a polymerizable compound, further improvement in sensitivity was attained.

### Example 26

### Preparation of Resin Composition for Relief Forming Layer

In a three-necked flask with an stirring blade and a condenser tube, 40 g of DENKA BUTYRAL #3000-2 (trade name, polyvinyl butyral, manufactured by DENKI KAGAKU KOGYO KABUSHIKI KAISHA) as (B) a binder polymer, 0.75 g of KETJENBLACK EC600JD (trade name, manufactured by Lion Corp.) as (D) a photothermal conversion agent, 20 g of diethylene glycol as a plasticizer, and 47 g of ethanol as a solvent were charged, and heated at 70° C. for 2 hours with stirring to dissolve the polymer. Further, as (C) an ethylenic unsaturated compound, BLENMER PDE-200 (trade name, manufactured by NOF Corp.), BLENMER PME-200 (trade name, manufactured by NOF Corp.), and methacrylic acid (manufactured by Wako Pure Chemical Industries, Ltd.) in an amount of 15 g, 13 g, and 5 g respectively; as (E) a polymerization initiator, IRGACURE 184 (trade name, manufactured by Ciba Specialty Chemicals Inc.) in an amount of 1.6 g; and as (A) a peroxide, PERHEXYNE 25B (trade name, manufactured by NOF Corp.) in an amount of 5.0 g were added thereto. The resulting mixture was stirred for 30 minutes to obtain a resin composition solution for forming a relief forming layer.

(Preparation of Relief Forming Layer)

A spacer (frame) with a predetermined thickness was placed on a PET substrate; the above obtained resin composition solution was cast carefully to an extent that the composition did not flow over the frame; and the composition was dried in an oven at 70° C. for 3 hours to form a relief forming layer precursor layer with a thickness of about 1 mm.

Then, UVA light was irradiated to the entire surface of the relief forming layer precursor layer formed on the substrate for 15 minutes, whereby a crosslinked structure was formed in the relief forming layer by photocrosslinking to obtain a relief printing plate precursor of Example 26.

(Formation of Relief Layer)

For image formation of the relief printing plate precursor, 2 cm square solid portion of the relief forming layer was engraved using a near infrared laser engraving machine “FD-100” (trade name, manufactured by Tosei Electrobeam Co., Ltd.) equipped with a semiconductor laser having a maximum power of 16 W (laser oscillation wavelength was 840 nm) under the engraving conditions: 15 W of laser power; 100 mm/second of scan speed; and 0.15 mm of pitch interval. In this way, a relief printing plate was produced.

A measurement of engraving depth and a quantitative determination of peroxide were carried out in the same manner as in Example 1. The results are shown in the following Table 3.

### Examples 27-32

Relief printing plate precursors were prepared and evaluated similarly to Example 26, except that DENKA BUTYRAL #3000-2 used as (B) a binder polymer in Example 26 was replaced by GOSENAL T-215 (trade name, manufactured by Nippon Synthetic Chemical Industry Co., Ltd., PVA derivative) in Example 27; polyvinyl acetate (manufactured by Alfa Aesar Corp.) in Example 28; AMILAN CM4000 (trade name, polyamine, manufactured by Toray Industries, Inc.) in Example 29; LEZAMIN ME8105LP (trade name, polyurethane, manufactured by Dainichiseika Color & Chemicals Mfg. Co., Ltd.) in Example 30; TR2000 (trade name, styrene and butadiene thermoplastic elastomer, manufactured by JSR Corp.) in Example 31; and polymethyl methacrylate (synthesized by free-radical polymerization of methyl methacrylate) in Example 32, respectively.

### Comparative Examples 10-16

Relief printing plate precursors were prepared and evaluated similarly to Examples 26-32, except that PERHEXYNE 25B ((A) a peroxide) was not added when preparing a resin composition for a relief forming layer.

### Example 33

A relief printing plate precursor was prepared and evaluated similarly to Example 27, except that 10 g of LANDY PL-2000 (trade name, polylactic acid, manufactured by MIYOSHI OIL&FAT CO., LTD.) was added.

### Examples 34-42

Relief printing plate precursors were prepared and evaluated similarly to Example 26, except that PERHEXYNE 25B used as (A) a peroxide in Example 26 was replaced by PERHEXYL D (trade name, manufactured by NOF Corp.) in Example 34; PERHEXA 25B (trade name, manufactured by NOF Corp.) in Example 35; PERCUMYL D (trade name, manufactured by NOF Corp.) in Example 36; PERCUMYL H (trade name, manufactured by NOF Corp.) in Example 37; PERBUTYL H-69 (trade name, manufactured by NOF Corp.) in Example 38; PERBUTYL L (trade name, manufactured by NOF Corp.) in Example 39; PERHEXYL I (trade name, manufactured by NOF Corp.) in Example 40; PERHEXA HC (trade name, manufactured by NOF Corp.) in Example 41; and NYPER BW (trade name, manufactured by NOF Corp.) in Example 42, respectively.

TABLE 3

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 26 | PERHEXYNE | 128.4 | 5 | 1.20 | 79 | Semiconductor | 575 | 575 |
| | 25B | | | | | laser | | |
| Example 27 | PERHEXYNE | 128.4 | 5 | 1.33 | 75 | Semiconductor | 570 | 570 |
| | 25B | | | | | laser | | |
| Example 28 | PERHEXYNE | 128.4 | 5 | 1.28 | 77 | Semiconductor | 540 | 540 |
| | 25B | | | | | laser | | |
| Example 29 | PERHEXYNE | 128.4 | 5 | 1.29 | 81 | Semiconductor | 555 | 555 |
| | 25B | | | | | laser | | |
| Example 30 | PERHEXYNE | 128.4 | 5 | 1.35 | 73 | Semiconductor | 555 | 555 |
| | 25B | | | | | laser | | |
| Example 31 | PERHEXYNE | 128.4 | 5 | 1.24 | 77 | Semiconductor | 540 | 540 |
| | 25B | | | | | laser | | |
| Example 32 | PERHEXYNE | 128.4 | 5 | 1.27 | 81 | Semiconductor | 555 | 555 |
| | 25B | | | | | laser | | |
| Comparative | None | — | — | 1.33 | 80 | Semiconductor | 460 | 460 |
| Example 10 | | | | | | laser | | |
| Comparative | None | — | — | 1.25 | 72 | Semiconductor | 455 | 455 |
| Example 11 | | | | | | laser | | |
| Comparative | None | — | — | 1.36 | 72 | Semiconductor | 430 | 430 |
| Example 12 | | | | | | laser | | |
| Comparative | None | — | — | 1.32 | 77 | Semiconductor | 445 | 445 |
| Example 13 | | | | | | laser | | |
| Comparative | None | — | — | 1.25 | 81 | Semiconductor | 445 | 445 |
| Example 14 | | | | | | laser | | |
| Comparative | None | — | — | 1.29 | 83 | Semiconductor | 430 | 430 |
| Example 15 | | | | | | laser | | |
| Comparative | None | — | — | 1.35 | 76 | Semiconductor | 445 | 445 |
| Example 16 | | | | | | laser | | |
| Example 33 | PERHEXYNE | 128.5 | 5 | 1.38 | 77 | Semiconductor | 585 | 585 |
| | 25B | | | | | laser | | |
| Example 34 | PERHEXYL D | 116.4 | 5 | 1.33 | 78 | Semiconductor | 540 | 540 |
| | | | | | | laser | | |
| Example 35 | PERHEXA | 117.9 | 5 | 1.34 | 74 | Semiconductor | 555 | 555 |
| | 25B | | | | | laser | | |
| Example 36 | PERCUMYL D | 116.4 | 5 | 1.23 | 81 | Semiconductor | 570 | 570 |
| | | | | | | laser | | |
| Example 37 | PERCUMYL H | 157.9 | 5 | 1.28 | 83 | Semiconductor | 540 | 540 |
| | | | | | | laser | | |
| Example 38 | PERBUTYL | 166.5 | 5 | 1.25 | 76 | Semiconductor | 550 | 550 |
| | H-69 | | | | | laser | | |
| Example 39 | PERBUTYL L | 98.3 | 5 | 1.19 | 80 | Semiconductor | 540 | 530 |
| | | | | | | laser | | |
| Example 40 | PERHEXYL I | 95.0 | 5 | 1.24 | 85 | Semiconductor | 545 | 530 |
| | | | | | | laser | | |
| Example 41 | PERHEXA HC | 87.1 | 5 | 1.28 | 77 | Semiconductor | 545 | 525 |
| | | | | | | laser | | |
| Example 42 | NYPER BW | 73.6 | 5 | 1.31 | 79 | Semiconductor | 540 | 510 |
| | | | | | | laser | | |

As is clear from Table 3, when light exposure is used for forming a crosslinked structure in the relief forming layer, excellent engraving sensitivity is exhibited and lowering of the sensitivity after aging is suppressed in the relief printing plate precursors of the present invention, similarly to the case where the crosslinked structure is formed by heating.

### Examples 43-84 and Comparative Examples 17-32

Examples 43-84 and Comparative Examples 17-32 were the same as Examples 1-42 and Comparative Examples 1-16, except that the laser used for engraving was changed from a semiconductor laser to a carbon dioxide laser.

As the carbon dioxide laser engraving machine, “CO₂ LASER MARKER ML-Z9500” (trade name, manufactured by KEYENCE CORP.) equipped with a carbon dioxide gas laser having a maximum powder of 30 W was used. Engraving conditions were: 15W of laser power; 100 mm/second of scan speed; and 0.15 mm of pitch interval. 2 cm square solid portion was engraved to prepare a relief printing plate. The evaluation results are shown in Tables 4-6.

TABLE 4

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 43 | PERHEXYNE | 128.4 | 5 | 1.28 | 75 | Carbon dioxide | 285 | 285 |
| | 25B | | | | | laser | | |
| Example 44 | PERHEXYNE | 128.4 | 5 | 1.25 | 81 | Carbon dioxide | 280 | 280 |
| | 25B | | | | | laser | | |
| Example 45 | PERHEXYNE | 128.4 | 5 | 1.29 | 83 | Carbon dioxide | 250 | 250 |
| | 25B | | | | | laser | | |
| Example 46 | PERHEXYNE | 128.4 | 5 | 1.35 | 76 | Carbon dioxide | 265 | 265 |
| | 25B | | | | | laser | | |
| Example 47 | PERHEXYNE | 128.4 | 5 | 1.25 | 80 | Carbon dioxide | 265 | 265 |
| | 25B | | | | | laser | | |
| Example 48 | PERHEXYNE | 128.4 | 5 | 1.32 | 72 | Carbon dioxide | 250 | 250 |
| | 25B | | | | | laser | | |
| Example 49 | PERHEXYNE | 128.4 | 5 | 1.33 | 78 | Carbon dioxide | 265 | 265 |
| | 25B | | | | | laser | | |
| Comparative | None | — | — | 1.33 | 80 | Carbon dioxide | 170 | 170 |
| Example 17 | | | | | | laser | | |
| Comparative | None | — | — | 1.33 | 75 | Carbon dioxide | 165 | 165 |
| Example 18 | | | | | | laser | | |
| Comparative | None | — | — | 1.28 | 77 | Carbon dioxide | 135 | 135 |
| Example 19 | | | | | | laser | | |
| Comparative | None | — | — | 1.29 | 81 | Carbon dioxide | 150 | 150 |
| Example 20 | | | | | | laser | | |
| Comparative | None | — | — | 1.23 | 81 | Carbon dioxide | 150 | 150 |
| Example 21 | | | | | | laser | | |
| Comparative | None | — | — | 1.28 | 83 | Carbon dioxide | 135 | 135 |
| Example 22 | | | | | | laser | | |
| Comparative | None | — | — | 1.25 | 76 | Carbon dioxide | 150 | 150 |
| Example 23 | | | | | | laser | | |
| Example 50 | PERHEXYNE | 128.5 | 5 | 1.29 | 80 | Carbon dioxide | 295 | 295 |
| | 25B | | | | | laser | | |
| Example 51 | PERHEXYL D | 116.4 | 5 | 1.22 | 75 | Carbon dioxide | 260 | 260 |
| | | | | | | laser | | |
| Example 52 | PERHEXA | 117.9 | 5 | 1.25 | 72 | Carbon dioxide | 265 | 265 |
| | 25B | | | | | laser | | |
| Example 53 | PERCUMYL D | 116.4 | 5 | 1.36 | 72 | Carbon dioxide | 280 | 280 |
| | | | | | | laser | | |
| Example 54 | PERCUMYL H | 157.9 | 5 | 1.32 | 77 | Carbon dioxide | 250 | 250 |
| | | | | | | laser | | |
| Example 55 | PERBUTYL | 166.5 | 5 | 1.29 | 81 | Carbon dioxide | 260 | 260 |
| | H-69 | | | | | laser | | |

TABLE 5

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 56 | PERHEXYNE | 128.4 | 1 | 1.35 | 82 | Carbon dioxide | 265 | 265 |
| | 25B | | | | | laser | | |
| Example 57 | PERHEXYNE | 128.4 | 3 | 1.36 | 83 | Carbon dioxide | 275 | 275 |
| | 25B | | | | | laser | | |
| Example 58 | PERHEXYNE | 128.4 | 10 | 1.33 | 80 | Carbon dioxide | 285 | 285 |
| | 25B | | | | | laser | | |
| Example 59 | PERHEXYNE | 128.4 | 5 | 1.25 | 71 | Carbon dioxide | 280 | 280 |
| | 25B | | | | | laser | | |
| Example 60 | PERHEXYNE | 128.4 | 5 | 1.22 | 75 | Carbon dioxide | 285 | 285 |
| | 25B | | | | | laser | | |
| Comparative | None | — | — | 1.35 | 82 | Carbon dioxide | 165 | 165 |
| Example 24 | | | | | | laser | | |
| Comparative | None | — | — | 1.36 | 83 | Carbon dioxide | 170 | 170 |
| Example 25 | | | | | | laser | | |
| Example 61 | PERCUMYL D | 116.4 | 5 | 1.19 | 78 | Carbon dioxide | 275 | 275 |
| | | | | | | laser | | |
| Example 62 | PERCUMYL D | 116.4 | 5 | 1.35 | 73 | Carbon dioxide | 280 | 280 |
| | | | | | | laser | | |
| Example 63 | PERHEXYNE | 128.4 | 5 | 1.19 | 78 | Carbon dioxide | 300 | 300 |
| | 25B | | | | | laser | | |
| Example 64 | PERCUMYL D | 116.4 | 5 | 1.35 | 73 | Carbon dioxide | 295 | 295 |
| | | | | | | laser | | |
| Example 65 | PERHEXYNE | 128.4 | 5 | 1.33 | 72 | Carbon dioxide | 275 | 275 |
| | 25B | | | | | laser | | |
| Example 66 | PERHEXYNE | 128.4 | 5 | 1.24 | 83 | Carbon dioxide | 280 | 280 |
| | 25B | | | | | laser | | |
| Example 67 | PERHEXYNE | 128.4 | 5 | 1.34 | 77 | Carbon dioxide | 280 | 280 |
| | 25B | | | | | laser | | |

TABLE 6

| | Peroxide | | | Relief forming | | | | |
|---|---|---|---|---|---|---|---|---|
| | | 10-hour | Residual | layer | | | | |
| | | half-life | amount | | Shore A | | Engraving depth | |
| | Compound | temp. | (% by | Thickness | hardness | Laser used for | (μm) | |
| | name | (° C.) | mass) | (mm) | (°) | engraving | 1 day | 6 months |
| Example 68 | PERHEXYNE | 128.4 | 5 | 1.20 | 79 | Carbon dioxide | 275 | 275 |
| | 25B | | | | | laser | | |
| Example 69 | PERHEXYNE | 128.4 | 5 | 1.33 | 75 | Carbon dioxide | 270 | 270 |
| | 25B | | | | | laser | | |
| Example 70 | PERHEXYNE | 128.4 | 5 | 1.28 | 77 | Carbon dioxide | 240 | 240 |
| | 25B | | | | | laser | | |
| Example 71 | PERHEXYNE | 128.4 | 5 | 1.29 | 81 | Carbon dioxide | 255 | 255 |
| | 25B | | | | | laser | | |
| Example 72 | PERHEXYNE | 128.4 | 5 | 1.35 | 73 | Carbon dioxide | 255 | 255 |
| | 25B | | | | | laser | | |
| Example 73 | PERHEXYNE | 128.4 | 5 | 1.24 | 77 | Carbon dioxide | 240 | 240 |
| | 25B | | | | | laser | | |
| Example 74 | PERHEXYNE | 128.4 | 5 | 1.27 | 81 | Carbon dioxide | 255 | 255 |
| | 25B | | | | | laser | | |
| Comparative | None | — | — | 1.33 | 80 | Carbon dioxide | 160 | 160 |
| Example 26 | | | | | | laser | | |
| Comparative | None | — | — | 1.25 | 72 | Carbon dioxide | 155 | 155 |
| Example 27 | | | | | | laser | | |
| Comparative | None | — | — | 1.36 | 72 | Carbon dioxide | 130 | 130 |
| Example 28 | | | | | | laser | | |
| Comparative | None | — | — | 1.32 | 77 | Carbon dioxide | 145 | 145 |
| Example 29 | | | | | | laser | | |
| Comparative | None | — | — | 1.25 | 81 | Carbon dioxide | 145 | 145 |
| Example 30 | | | | | | laser | | |
| Comparative | None | — | — | 1.29 | 83 | Carbon dioxide | 130 | 130 |
| Example 31 | | | | | | laser | | |
| Comparative | None | — | — | 1.35 | 76 | Carbon dioxide | 145 | 145 |
| Example 32 | | | | | | laser | | |
| Example 75 | PERHEXYNE | 128.5 | 5 | 1.38 | 77 | Carbon dioxide | 285 | 285 |
| | 25B | | | | | laser | | |
| Example 76 | PERHEXYL D | 116.4 | 5 | 1.33 | 78 | Carbon dioxide | 240 | 240 |
| | | | | | | laser | | |
| Example 77 | PERHEXA | 117.9 | 5 | 1.34 | 74 | Carbon dioxide | 255 | 255 |
| | 25B | | | | | laser | | |
| Example 78 | PERCUMYL D | 116.4 | 5 | 1.23 | 81 | Carbon dioxide | 270 | 270 |
| | | | | | | laser | | |
| Example 79 | PERCUMYL H | 157.9 | 5 | 1.28 | 83 | Carbon dioxide | 240 | 240 |
| | | | | | | laser | | |
| Example 80 | PERBUTYL | 166.5 | 5 | 1.25 | 76 | Carbon dioxide | 250 | 250 |
| | H-69 | | | | | laser | | |
| Example 81 | PERBUTYL L | 98.3 | 5 | 1.19 | 80 | Carbon dioxide | 240 | 230 |
| | | | | | | laser | | |
| Example 82 | PERHEXYL I | 95.0 | 5 | 1.24 | 85 | Carbon dioxide | 245 | 230 |
| | | | | | | laser | | |
| Example 83 | PERHEXA HC | 87.1 | 5 | 1.28 | 77 | Carbon dioxide | 245 | 225 |
| | | | | | | laser | | |
| Example 84 | NYPER BW | 73.6 | 5 | 1.31 | 79 | Carbon dioxide | 240 | 210 |
| | | | | | | laser | | |

As is understood from Tables 4-6, also when image formation is carried out by a carbon dioxide laser, excellent engraving sensitivity is exhibited and lowering of the sensitivity after aging is suppressed in the printing plate precursors of the present invention, similarly to the case when image formation is carried out by a semiconductor laser. Further, the tendency of sensitivity change due to the amount of the peroxide, the kind of the polymerizable compound, and the formation method of the crosslinked structure was the same as that when using a semiconductor laser.

### Examples 85-91

### Preparation of Resin Composition for Relief Forming Layer

In a three-necked flask with an stirring blade and a condenser tube, 50 g of DENKA BUTYRAL #3000-2 (trade name, polyvinyl butyral, Mw=90,000, manufactured by DENKI KAGAKU KOGYO KABUSHIKI KAISHA) as (B) a binder polymer, and 47 g of propylene glycol monomethyl ether acetate as a solvent were charged, and heated at 70° C. for 120 minutes with stirring to dissolve the polymer.

Thereafter, the solution temperature was adjusted to 40° C., and 1 g of KETJENBLACK EC600JD (trade name, carbon black, manufactured by Lion Corp.) as (D) a photothermal conversion agent was added thereto, and stirred for 30 minutes. Thereafter, 33 g of a compound having the following structure (compound listed in Table 7 below) as (C) a crosslinking agent, 0.8 g of 1,8-diazabicyclo[5.4.0]undec-7-ene as a crosslinking accelerator (catalyst), 5.0 g of PERHEXYNE 25B (trade name, manufactured by NOF Corp.) as (A) a peroxide, and 5.0 g of zinc 2-ethyl hexanoate as a metal compound were added thereto, and stirred at 40° C. for 10 minutes. By this procedure, a crosslinkable coating liquid (resin composition) for forming a relief forming layer was obtained.

Each of the obtained resin compositions for forming a relief forming layer was used to form a relief forming layer precursor layer on a PET substrate in the same manner as in Example 1.

The resulting substrate having a relief forming layer precursor layer formed thereon was heated at 100° C. for 3 hours to heat crosslink the relief forming layer precursor layer to form a crosslinked structure. In this way, relief printing plate precursors of Examples 85-91 were obtained.

In the same manner as in Example 1, the relief printing plate precursors were engraved using a near infrared laser engraving machine to prepare relief printing plates.

The measurement of engraving depth and the quantitative determination of peroxide were carried out in the same manner as in Example 1. The results are shown in Table 7 below.

### Examples 92-98

Relief printing plate precursors were prepared and evaluated in the same manner as in Examples 85-91, except that the same amount of PERCUMYL D was used in place of PERHEXYNE 25B as (A) a peroxide in the resin composition for forming a relief forming layer of Examples 85-91. The results are shown in Table 7 below.

### Comparative Examples 33-39

Relief printing plate precursors were prepared and evaluated in the same manner as in Examples 85-91, except that PERHEXYNE 25B as (A) a peroxide was not added to the resin composition for forming a relief forming layer of Examples 85-91. The results are shown in Table 7 below.

TABLE 7

| | Resin composition | | | Relief forming | | | | |
|---|---|---|---|---|---|---|---|---|
| | for relief forming layer | | | layer | | | | |
| | | (C) Cross- | | | Shore A | | Engraving depth | |
| | | linking | Metal | Thickness | hardness | Laser used for | (μm) | |
| | (A) Peroxide | agent | compound | (mm) | (°) | engraving | 1 day | 6 months |
| Ex 85 | PERHEXYNE | S-1 | Zinc 2-ethyl | 1.25 | 75 | Semiconductor | 555 | 555 |
| | 25B | | hexanoate | | | laser | | |
| Ex 86 | PERHEXYNE | S-2 | Zinc 2-ethyl | 1.33 | 78 | Semiconductor | 570 | 570 |
| | 25B | | hexanoate | | | laser | | |
| Ex 87 | PERHEXYNE | S-3 | Zinc 2-ethyl | 1.32 | 75 | Semiconductor | 545 | 545 |
| | 25B | | hexanoate | | | laser | | |
| Ex 88 | PERHEXYNE | S-4 | Zinc 2-ethyl | 1.30 | 71 | Semiconductor | 535 | 535 |
| | 25B | | hexanoate | | | laser | | |
| Ex 89 | PERHEXYNE | S-5 | Zinc 2-ethyl | 1.25 | 68 | Semiconductor | 545 | 545 |
| | 25B | | hexanoate | | | laser | | |
| Ex 90 | PERHEXYNE | S-6 | Zinc 2-ethyl | 1.28 | 73 | Semiconductor | 530 | 530 |
| | 25B | | hexanoate | | | laser | | |
| Ex 91 | PERHEXYNE | S-7 | Zinc 2-ethyl | 1.22 | 72 | Semiconductor | 535 | 535 |
| | 25B | | hexanoate | | | laser | | |
| Ex 92 | PERCUMYL D | S-1 | Zinc 2-ethyl | 1.28 | 72 | Semiconductor | 560 | 560 |
| | | | hexanoate | | | laser | | |
| Ex 93 | PERCUMYL D | S-2 | Zinc 2-ethyl | 1.40 | 69 | Semiconductor | 575 | 575 |
| | | | hexanoate | | | laser | | |
| Ex 94 | PERCUMYL D | S-3 | Zinc 2-ethyl | 1.30 | 74 | Semiconductor | 550 | 550 |
| | | | hexanoate | | | laser | | |
| Ex 95 | PERCUMYL D | S-4 | Zinc 2-ethyl | 1.24 | 77 | Semiconductor | 540 | 540 |
| | | | hexanoate | | | laser | | |
| Ex 96 | PERCUMYL D | S-5 | Zinc 2-ethyl | 1.34 | 74 | Semiconductor | 550 | 550 |
| | | | hexanoate | | | laser | | |
| Ex 97 | PERCUMYL D | S-6 | Zinc 2-ethyl | 1.28 | 78 | Semiconductor | 535 | 535 |
| | | | hexanoate | | | laser | | |
| Ex 98 | PERCUMYL D | S-7 | Zinc 2-ethyl | 1.29 | 79 | Semiconductor | 540 | 540 |
| | | | hexanoate | | | laser | | |
| Comp. | None | S-1 | Zinc 2-ethyl | 1.36 | 76 | Semiconductor | 480 | 480 |
| Ex 33 | | | hexanoate | | | laser | | |
| Comp. | None | S-2 | Zinc 2-ethyl | 1.45 | 79 | Semiconductor | 505 | 505 |
| Ex 34 | | | hexanoate | | | laser | | |
| Comp. | None | S-3 | Zinc 2-ethyl | 1.33 | 73 | Semiconductor | 470 | 470 |
| Ex 35 | | | hexanoate | | | laser | | |
| Comp. | None | S-4 | Zinc 2-ethyl | 1.31 | 71 | Semiconductor | 460 | 460 |
| Ex 36 | | | hexanoate | | | laser | | |
| Comp. | None | S-5 | Zinc 2-ethyl | 1.25 | 77 | Semiconductor | 470 | 470 |
| Ex 37 | | | hexanoate | | | laser | | |
| Comp. | None | S-6 | Zinc 2-ethyl | 1.35 | 72 | Semiconductor | 455 | 455 |
| Ex 38 | | | hexanoate | | | laser | | |
| Comp. | None | S-7 | Zinc 2-ethyl | 1.36 | 73 | Semiconductor | 460 | 460 |
| Ex 39 | | | hexanoate | | | laser | | |

The structures of the (C) crosslinking agents (S-1) to (S-7), which were used in Examples 85-98 and Comparative Examples 33-39, are as shown below.

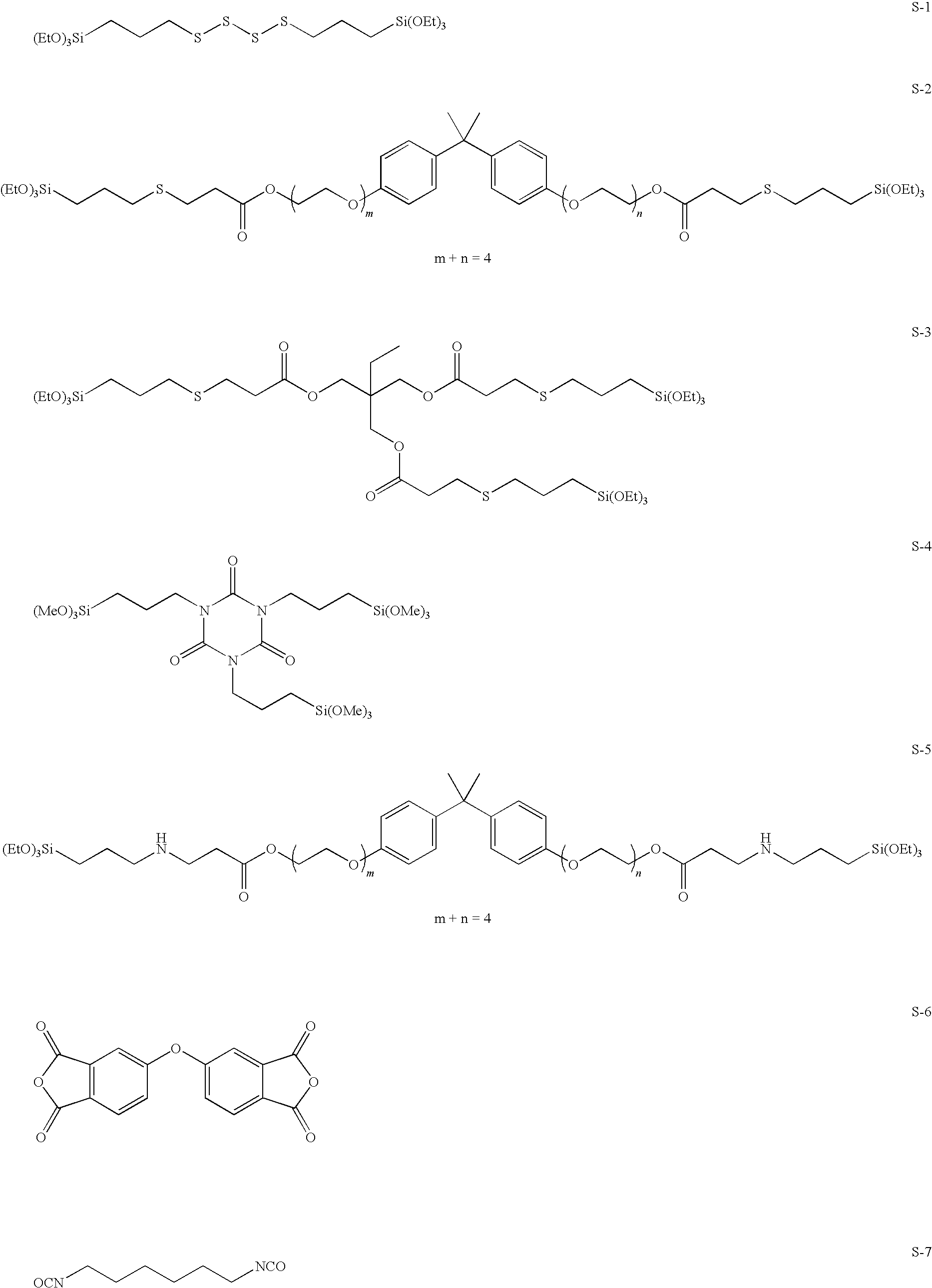

### Examples 99-112 and Comparative Examples 40-46

Examples 99-112 and Comparative Examples 40-46 were the same as Examples 85-98 and Comparative Examples 33-39, except that the laser used for engraving was changed from a semiconductor laser to a carbon dioxide laser.

As the carbon dioxide laser engraving machine, “CO₂ LASER MARKER ML-Z9500” (trade name, manufactured by KEYENCE CORP.) equipped with a carbon dioxide gas laser having a maximum powder of 30 W was used. Engraving conditions were: 15W of laser power; 100 mm/second of scan speed; and 0.15 mm of pitch interval. 2 cm square solid portion was engraved to prepare a relief printing plate. The evaluation results are shown in Tables 8.

TABLE 8

| | Resin composition | | | Relief forming | | | | |
|---|---|---|---|---|---|---|---|---|
| | for relief forming layer | | | layer | | | | |
| | | (C) Cross- | | | Shore A | | Engraving depth | |
| | | linking | Metal | Thickness | hardness | Laser used for | (μm) | |
| | (A) Peroxide | agent | compound | (mm) | (°) | engraving | 1 day | 6 months |
| Ex 99 | PERHEXYNE | S-1 | Zinc 2-ethyl | 1.25 | 75 | Carbon dioxide | 255 | 255 |
| | 25B | | hexanoate | | | laser | | |
| Ex 100 | PERHEXYNE | S-2 | Zinc 2-ethyl | 1.33 | 78 | Carbon dioxide | 270 | 270 |
| | 25B | | hexanoate | | | laser | | |
| Ex 101 | PERHEXYNE | S-3 | Zinc 2-ethyl | 1.32 | 75 | Carbon dioxide | 245 | 245 |
| | 25B | | hexanoate | | | laser | | |
| Ex 102 | PERHEXYNE | S-4 | Zinc 2-ethyl | 1.30 | 71 | Carbon dioxide | 235 | 235 |
| | 25B | | hexanoate | | | laser | | |
| Ex 103 | PERHEXYNE | S-5 | Zinc 2-ethyl | 1.25 | 68 | Carbon dioxide | 245 | 245 |
| | 25B | | hexanoate | | | laser | | |
| Ex 104 | PERHEXYNE | S-6 | Zinc 2-ethyl | 1.28 | 73 | Carbon dioxide | 230 | 230 |
| | 25B | | hexanoate | | | laser | | |
| Ex 105 | PERHEXYNE | S-7 | Zinc 2-ethyl | 1.22 | 72 | Carbon dioxide | 235 | 235 |
| | 25B | | hexanoate | | | laser | | |
| Ex 106 | PERCUMYL D | S-1 | Zinc 2-ethyl | 1.28 | 72 | Carbon dioxide | 260 | 260 |
| | | | hexanoate | | | laser | | |
| Ex 107 | PERCUMYL D | S-2 | Zinc 2-ethyl | 1.40 | 69 | Carbon dioxide | 275 | 275 |
| | | | hexanoate | | | laser | | |
| Ex 108 | PERCUMYL | S-3 | Zinc 2-ethyl | 1.30 | 74 | Carbon dioxide | 250 | 250 |
| | | | hexanoate | | | laser | | |
| Ex 109 | PERCUMYL D | S-4 | Zinc 2-ethyl | 1.24 | 77 | Carbon dioxide | 240 | 240 |
| | | | hexanoate | | | laser | | |
| Ex 110 | PERCUMYL D | S-5 | Zinc 2-ethyl | 1.34 | 74 | Carbon dioxide | 250 | 250 |
| | | | hexanoate | | | laser | | |
| Ex 111 | PERCUMYL D | S-6 | Zinc 2-ethyl | 1.28 | 78 | Carbon dioxide | 235 | 235 |
| | | | hexanoate | | | laser | | |
| Ex 112 | PERCUMYL D | S-7 | Zinc 2-ethyl | 1.29 | 79 | Carbon dioxide | 240 | 240 |
| | | | hexanoate | | | laser | | |
| Comp. | None | S-1 | Zinc 2-ethyl | 1.36 | 76 | Carbon dioxide | 180 | 180 |
| Ex 40 | | | hexanoate | | | laser | | |
| Comp. | None | S-2 | Zinc 2-ethyl | 1.45 | 79 | Carbon dioxide | 205 | 205 |
| Ex 41 | | | hexanoate | | | laser | | |
| Comp. | None | S-3 | Zinc 2-ethyl | 1.33 | 73 | Carbon dioxide | 170 | 170 |
| Ex 42 | | | hexanoate | | | laser | | |
| Comp. | None | S-4 | Zinc 2-ethyl | 1.31 | 71 | Carbon dioxide | 160 | 160 |
| Ex 43 | | | hexanoate | | | laser | | |
| Comp. | None | S-5 | Zinc 2-ethyl | 1.25 | 77 | Carbon dioxide | 170 | 170 |
| Ex 44 | | | hexanoate | | | laser | | |
| Comp. | None | S-6 | Zinc 2-ethyl | 1.35 | 72 | Carbon dioxide | 155 | 155 |
| Ex 45 | | | hexanoate | | | laser | | |
| Comp. | None | S-7 | Zinc 2-ethyl | 1.36 | 73 | Carbon dioxide | 160 | 160 |
| Ex 46 | | | hexanoate | | | laser | | |

As is understood from the results shown in Tables 7-8, in the printing plate precursors of the invention, excellent engraving sensitivity is exhibited compared to those of the Comparative Examples not including (A) a peroxide in the resin composition for forming a relief forming layer, and lowering of the sensitivity after aging is suppressed, even when the kind of the crosslinking agent is changed and further a metal compound is used together, and even when image formation is carried out by a carbon dioxide laser in place of a semiconductor laser.

All publications, patent applications, and technical standards mentioned in this specification are herein incorporated by reference to the same extent as if each individual publication, patent application, or technical standard was specifically and individually indicated to be incorporated by reference.

What is claimed is:

1. A relief printing plate precursor for laser engraving, comprising a relief forming layer that comprises a peroxide and a binder polymer, and comprises a crosslinked structure.

2. The relief printing plate precursor of claim 1, wherein the content of the peroxide is from 0.01% to 20% by mass based on the total mass of the relief forming layer.

3. The relief printing plate precursor of claim 1, wherein the peroxide includes at least one organic peroxide.

4. The relief printing plate precursor of claim 1, wherein the peroxide includes at least one selected from the group consisting of a ketone peroxide, a diacyl peroxide, a dialkyl peroxide, a hydroperoxide, a peroxy ketal, a peroxy ester, and a peroxy dicarbonate.

5. The relief printing plate precursor of claim 1, wherein the 10-hour half-life temperature of the peroxide is 100° C. or more.

6. The relief printing plate precursor of claim 1, wherein the crosslinked structure of the relief forming layer is formed by at least light exposure or heating.

7. The relief printing plate precursor of claim 6, wherein the crosslinked structure of the relief forming layer is formed by heating.

8. The relief printing plate precursor of claim 7, wherein the 10-hour half-life temperature of the peroxide is higher, by 5° C. or more, than the heating temperature for forming the crosslinked structure of the relief forming layer.

9. The relief printing plate precursor of claim 1, wherein the thickness of the relief forming layer is from 0.05 mm to 10 mm.

10. The relief printing plate precursor of claim 1, wherein the shore A hardness of the relief forming layer is from 50° to 90°.

11. A method of producing the relief printing plate precursor of claim 1, the method comprising:
forming a layer of a resin composition comprising a peroxide, a binder polymer, and a crosslinking agent;
drying the layer of the resin composition; and
forming a crosslinked structure in the dried layer of the resin composition by at least light exposure or heating.

12. A relief printing plate precursor for laser engraving produced by the method of claim 11.

13. A method of producing a relief printing plate, comprising forming a relief layer by laser engraving the relief forming layer in the relief printing plate precursor of claim 12.

14. A relief printing plate produced by the method of claim 13.
